(19) United States
(12) Patent Application Publication
(10) Pub. No.: US 2016/0013773 A1
(43) Pub. Date: Jan. 14, 2016

(54) METHOD AND APPARATUS FOR FAST DIGITAL FILTERING AND SIGNAL PROCESSING

(71) Applicant: Pavel DOURBAL, Plainsboro, NJ (US)

(72) Inventor: Pavel DOURBAL, Plainsboro, NJ (US)

(21) Appl. No.: 14/748,541

(22) Filed: Jun. 24, 2015

Related U.S. Application Data
(63) Continuation-in-part of application No. 13/726,326, filed on Dec. 24, 2012, now Pat. No. 8,597,989.
(60) Provisional application No. 61/723,103, filed on Nov. 6, 2012.

(51) Int. Cl. H03H 17/02; G06F 17/16

(52) U.S. Cl. CPC H03H 17/0248; G06F 17/16

(57) ABSTRACT

A method and a system for digital filtering comprising fast tensor-vector multiplication provide factoring an original tensor into a kernel and a commutator, multiplying the kernel obtained by the factoring of the original tensor, by the vector and thereby obtaining a matrix, and summating elements and sums of elements of the matrix as defined by the commutator obtained by the factoring of the original tensor, and thereby obtaining a resulting tensor which corresponds to a product of the original tensor and the vector.

### CROSS-REFERENCE TO A RELATED APPLICATION

This patent application contains the subject matter of my U.S. patent application Ser. No. 13/726,367 filed on Dec. 24, 2012, which in turn claims priority of U.S. provisional application 61/723,103 filed November, 6th 2012 for method and system for fast calculation of tensor-vector multiplication, from which this patent application claims its priority under 35 USC 119(a)-(d).

### BACKGROUND OF THE INVENTION

1. Technical Field

The present invention relates to improved methods and systems for digital filtering or signal filtering with a digital component by employing novel tensor-vector multiplication methods. The tensor-vector multiplication technique is also employed for determination of correlation of signals in electronic systems, for forming control signals in automated control systems, etc.

2. Background Art

Digital Filtering

A digital filter is an apparatus that receives a digital signal and provides as output a corresponding signal from which certain signal frequency components have been removed or blocked. Various digital filters have different resolution accuracies and remove different frequency components to accomplish different purposes. Some digital filters simply block out entire frequency ranges. Examples are high pass filters and low pass filters. Others target particular problems such as noise spectra or try to clean up signals by relating the frequencies to previously received signals. Examples are Wiener and Kalman filters.

Methods and systems for tensor-vector multiplications are known in the art. One of such methods and systems is disclosed in U.S. Pat. No. 8,316,072. In this patent a method (and structure) of executing a matrix operation is disclosed, which includes, for a matrix A, separating the matrix A into blocks, each block having a size p-by-q. The blocks of size p-by-q are then stored in a cache or memory in at least one of the two following ways. The elements in at least one of the blocks are stored in a format in which elements of the block occupy a location different from an original location in the block, and/or the blocks of size p-by-q are stored in a format in which at least one block occupies a position different relative to its original position in the matrix A.

U.S. Pat. No. 8,250,130 discloses a block matrix multiplication mechanism is provided for reversing the visitation order of blocks at corner turns when performing a block matrix multiplication operation in a data processing system. The mechanism increases block size and divides each block into sub-blocks. By reversing the visitation order, the mechanism eliminates a sub-block load at the corner turns. The mechanism performs sub-block matrix multiplication for each sub-block in a given block, and then repeats operation for a next block until all blocks are computed. The mechanism may determine block size and sub-block size to optimize load balancing and memory bandwidth. Therefore, the mechanism reduces maximum throughput and increases performance. In addition, the mechanism also reduces the number of multi-buffered local store buffers.

U.S. Pat. No. 8,237,638 discloses a method of driving an electro-optic display, the display having a plurality of pixels each addressable by a row electrode and a column electrode, the method including: receiving image data for display, the image data defining an image matrix; factorizing the image matrix into a product of at least first and second factor matrices, the first factor matrix defining row drive signals for the display, the second factor matrix defining column drive signals for the display; and driving the display row and column electrodes using the row and column drive signals respectively defined by the first and second factor matrices.

U.S. Pat. No. 8,223,872 discloses an equalizer applied to a signal to be transmitted via at least one multiple input, multiple output (MIMO) channel or received via at least one MIMO channel using a matrix equalizer computational device. Channel state information (CSI) is received, and the CSI is provided to the matrix equalizer computational device when the matrix equalizer computational device is not needed for matrix equalization. One or more transmit beam steering code words are selected from a transmit beam steering codebook based on output generated by the matrix equalizer computational device in response to the CSI provided to the matrix equalizer computational device.

U.S. Pat. No. 8,211,634 discloses compositions, kits, and methods for detecting, characterizing, preventing, and treating human cancer. A variety of chromosomal regions (MCRs) and markers corresponding thereto, are provided, wherein alterations in the copy number of one or more of the MCRs and/or alterations in the amount, structure, and/or activity of one or more of the markers is correlated with the presence of cancer.

U.S. Pat. No. 8,209,138 discloses methods and apparatus for analysis and design of radiation and scattering objects. In one embodiment, unknown sources are spatially grouped to produce a system interaction matrix with block factors of low rank within a given error tolerance and the unknown sources are determined from compressed forms of the factors.

U.S. Pat. No. 8,204,842 discloses systems and methods for multi-modal or multimedia image retrieval. Automatic image annotation is achieved based on a probabilistic semantic model in which visual features and textual words are connected via a hidden layer comprising the semantic concepts to be discovered, to explicitly exploit the synergy between the two modalities. The association of visual features and textual words is determined in a Bayesian framework to provide confidence of the association. A hidden concept layer which connects the visual feature(s) and the words is discovered by fitting a generative model to the training image and annotation words. An Expectation-Maximization (EM) based iterative learning procedure determines the conditional probabilities of the visual features and the textual words given a hidden concept class. Based on the discovered hidden concept layer and the corresponding conditional probabilities, the image annotation and the text-to-image retrieval are performed using the Bayesian framework.

U.S. Pat. No. 8,200,470 discloses how improved performance of simulation analysis of a circuit with some non-linear elements and a relatively large network of linear elements may be achieved by systems and methods that partition the circuit so that simulation may be performed on a non-linear part of the circuit in pseudo-isolation of a linear part of the circuit. The non-linear part may include one or more transistors of the circuit and the linear part may comprise an RC network of the circuit. By separating the linear part from the simulation on the non-linear part, the size of a matrix for simulation on the non-linear part may be reduced. Also, a number of factorizations of a matrix for simulation on the linear part may be reduced. Thus, such systems and methods may be used, for example, to determine current in circuits including relatively large RC networks, which may otherwise be computationally prohibitive using standard simulation techniques.

U.S. Pat. No. 8,195,734 discloses methods of combining multiple clusters arising in various important data mining scenarios based on soft correspondence to directly address the correspondence problem in combining multiple clusters. An algorithm iteratively computes the consensus clustering and correspondence matrices using multiplicative updating rules. This algorithm provides a final consensus clustering as well as correspondence matrices that gives intuitive interpretation of the relations between the consensus clustering and each clustering from clustering ensembles. Extensive experimental evaluations demonstrate the effectiveness and potential of this framework as well as the algorithm for discovering a consensus clustering from multiple clusters.

U.S. Pat. No. 8,195,730 discloses apparatus and method for converting first and second blocks of discrete values into a transformed representation, the first block is transformed according to a first transformation rule and then rounded. Then, the rounded transformed values are summed with the second block of original discrete values, to then process the summation result according to a second transformation rule. The output values of the transformation via the second transformation rule are again rounded and then subtracted from the original discrete values of the first block of discrete values to obtain a block of integer output values of the transformed representation. By this multi-dimensional lifting scheme, a lossless integer transformation is obtained, which can be reversed by applying the same transformation rule, but with different signs in summation and subtraction, respectively, so that an inverse integer transformation can also be obtained. Compared to a separation of a transformation in rotations, on the one hand, a significantly reduced computing complexity is achieved and, on the other hand, an accumulation of approximation errors is prevented.

U.S. Pat. No. 8,194,080 discloses a computer-implemented method for generating a surface representation of an item includes identifying, for a point on an item in an animation process, at least first and second transformation points corresponding to respective first and second transformations of the point. Each of the first and second transformations represents an influence on a location of the point of respective first and second joints associated with the item. The method includes determining an axis for a cylindrical coordinate system using the first and second transformations. The method includes performing an interpolation of the first and second transformation points in the cylindrical coordinate system to obtain an interpolated point. The method includes recording the interpolated point in a surface representation of the item in the animation process.

U.S. Pat. No. 8,190,549 discloses an online sparse matrix Gaussian process (OSMGP) which is using online updates to provide an accurate and efficient regression for applications such as pose estimation and object tracking. A regression calculation module calculates a regression on a sequence of input images to generate output predictions based on a learned regression model. The regression model is efficiently updated by representing a covariance matrix of the regression model using a sparse matrix factor (e.g., a Cholesky factor). The sparse matrix factor is maintained and updated in real-time based on the output predictions. Hyperparameter optimization, variable reordering, and matrix downdating techniques can also be applied to further improve the accuracy and/or efficiency of the regression process.

U.S. Pat. No. 8,190,094 discloses a method for reducing inter-cell interference and a method for transmitting a signal by a collaborative MIMO scheme, in a communication system having a multi-cell environment are disclosed. An example of a method for transmitting, by a mobile station, precoding information in a collaborative MIMO communication system includes determining a precoding matrix set including precoding matrices of one more base stations including a serving base station, based on signal strength of the serving base station, and transmitting information about the precoding matrix set to the serving base station. A mobile station in an edge of a cell performs a collaborative MIMO mode or inter-cell interference mitigation mode using the information about the precoding matrix set collaboratively with neighboring base stations.

U.S. Pat. No. 8,185,535 discloses methods and systems for determining unknowns in rating matrices. In one embodiment, a method comprises forming a rating matrix, where each matrix element corresponds to a known favorable user rating associated with an item or an unknown user rating associated with an item. The method includes determining a weight matrix configured to assign a weight value to each of the unknown matrix elements, and sampling the rating matrix to generate an ensemble of training matrices. Weighted maximum-margin matrix factorization is applied to each training matrix to obtain corresponding sub-rating matrix, the weights based on the weight matrix. The sub-rating matrices are combined to obtain an approximate rating matrix that can be used to recommend items to users based on the rank ordering of the corresponding matrix elements.

U.S. Pat. No. 8,175,853 discloses systems and methods for combined matrix-vector and matrix-transpose vector multiply for block sparse matrices. Exemplary embodiments include a method of updating a simulation of physical objects in an interactive computer, including generating a set of representations of objects in the interactive computer environment, partitioning the set of representations into a plurality of subsets such that objects in any given set interact only with other objects in that set, generating a vector b describing an expected position of each object at the end of a time interval h, applying a biconjugate gradient algorithm to solve A*.DELTA.v=b for the vector.DELTA.v of position and velocity changes to be applied to each object wherein the q=Ap and qt=A.sup.T(pt) calculations are combined so that A only has to be read once, integrating the updated motion vectors to determine a next state of the simulated objects, and converting the simulated objects to a visual.

U.S. Pat. No. 8,160,182 discloses a symbol detector with a sphere decoding method. A baseband signal is received to determine a maximum likelihood solution using the sphere decoding algorithm. A QR decomposer performs a QR decomposition process on a channel response matrix to generate a Q matrix and an R matrix. A matrix transformer generates an inner product matrix of the Q matrix and the received signal. A scheduler reorganizes a search tree, and takes a search mission apart into a plurality of independent branch missions. A plurality of Euclidean distance calculators are controlled by the scheduler to operate in parallel, wherein each has a plurality of calculation units cascaded in a pipeline structure to search for the maximum likelihood solution based on the R matrix and the inner product matrix.

U.S. Pat. No. 8,068,560 discloses a QR decomposition apparatus and method that can reduce the number of computers by sharing hardware in an MIMO system employing OFDM technology to simplify a structure of hardware. The QR decomposition apparatus includes a norm multiplier for calculating a norm; a Q column multiplier for calculating a column value of a unitary Q matrix to thereby produce a Q matrix vector; a first storage for storing the Q matrix vector calculated in the Q column multiplier; an R row multiplier for calculating a value of an upper triangular R matrix by multiplying the Q matrix vector by a reception signal vector; and a Q update multiplier for receiving the reception signal vector and an output of the R row multiplier, calculating an Q update value through an accumulation operation, and providing the Q update value to the Q column multiplier to calculate a next Q matrix vector.

U.S. Pat. No. 8,051,124 discloses a matrix multiplication module and matrix multiplication method are provided that use a variable number of multiplier-accumulator units based on the amount of data elements of the matrices are available or needed for processing at a particular point or stage in the computation process. As more data elements become available or are needed, more multiplier-accumulator units are used to perform the necessary multiplication and addition operations. Very large matrices are partitioned into smaller blocks to fit in the FPGA resources. Results from the multiplication of sub-matrices are combined to form the final result of the large matrices.

U.S. Pat. No. 8,185,481 discloses a general model which provides collective factorization on related matrices, for multi-type relational data clustering. The model is applicable to relational data with various structures. Under this model, a spectral relational clustering algorithm is provided to cluster multiple types of interrelated data objects simultaneously. The algorithm iteratively embeds each type of data objects into low dimensional spaces and benefits from the interactions among the hidden structures of different types of data objects.

U.S. Pat. No. 8,176,046 discloses systems and methods for identifying trends in web feeds collected from various content servers. One embodiment includes, selecting a candidate phrase indicative of potential trends in the web feeds, assigning the candidate phrase to trend analysis agents, analyzing the candidate phrase, by each of the one or more trend analysis agents, respectively using the configured type of trending parameter, and/or determining, by each of the trend analysis agents, whether the candidate phrase meets an associated threshold to qualify as a potential trended phrase.

U.S. Pat. No. 8,175,872 discloses enhancing noisy speech recognition accuracy by receiving geotagged audio signals that correspond to environmental audio recorded by multiple mobile devices in multiple geographic locations, receiving an audio signal that corresponds to an utterance recorded by a particular mobile device, determining a particular geographic location associated with the particular mobile device, selecting a subset of geotagged audio signals and weighting each geotagged audio signal of the subset based on whether the respective audio signal was manually uploaded or automatically updated, generating a noise model for the particular geographic location using the subset of weighted geotagged audio signals, where noise compensation is performed on the audio signal that corresponds to the utterance using the noise model that has been generated for the particular geographic location.

U.S. Pat. No. 8,165,373 discloses a computer-implemented data processing system for blind extraction of more pure components than mixtures recorded in 1D or 2D NMR spectroscopy and mass spectrometry. Sparse component analysis is combined with single component points (SCPs) to blind decomposition of mixtures data X into pure components S and concentration matrix A, whereas the number of pure components S is greater than number of mixtures X. NMR mixtures are transformed into wavelet domain, where pure components are sparser than in time domain and where SCPs are detected. Mass spectrometry (MS) mixtures are extended to analytical continuation in order to detect SCPs. SCPs are used to estimate number of pure components and concentration matrix. Pure components are estimated in frequency domain (NMR data) or m/z domain (MS data) by means of constrained convex programming methods. Estimated pure components are ranked using negentropy-based criterion.

U.S. Pat. No. 8,140,272 discloses systems and methods for unmixing spectroscopic data using nonnegative matrix factorization during spectrographic data processing. In an embodiment, a method of processing spectrographic data may include receiving optical absorbance data associated with a sample and iteratively computing values for component spectra using nonnegative matrix factorization. The values for component spectra may be iteratively computed until optical absorbance data is approximately equal to a Hadamard product of a path length matrix and a matrix product of a concentration matrix and a component spectra matrix. The method may also include iteratively computing values for path length using nonnegative matrix factorization, in which path length values may be iteratively computed until optical absorbance data is approximately equal to a Hadamard product of the path length matrix and the matrix product of the concentration matrix and the component spectra matrix.

U.S. Pat. No. 8,139,900 discloses an embodiment for retrieval of a collection of captured images that form at least a portion of a library of images. For each image in the collection, a captured image may be analyzed to recognize information from image data contained in the captured image, and an index may be generated, where the index data is based on the recognized information. Using the index, functionality such as search and retrieval is enabled. Various recognition techniques, including those that use the face, clothing, apparel, and combinations of characteristics may be utilized. Recognition may be performed on, among other things, persons and text carried on objects.

U.S. Pat. No. 8,135,187 discloses techniques for removing image autoflourescence from fluorescently stained biological images. The techniques utilize non-negative matrix factorization that may constrain mixing coefficients to be non-negative. The probability of convergence to local minima is reduced by using smoothness constraints. The non-negative matrix factorization algorithm provides the advantage of removing both dark current and autofluorescence.

U.S. Pat. No. 8,131,732 discloses a system with a collaborative filtering engine to predict an active user's ratings/interests/preferences on a set of new products/items. The predictions are based on an analysis the database containing the historical data of many users' ratings/interests/preferences on a large set of products/items.

U.S. Pat. No. 8,126,951 discloses a method for transforming a digital signal from the time domain into the frequency domain and vice versa using a transformation function comprising a transformation matrix, the digital signal comprising data symbols which are grouped into a plurality of blocks, each block comprising a predefined number of the data symbols. The method includes the process of transforming two blocks of the digital signal by one transforming element, wherein the transforming element corresponds to a block-diagonal matrix comprising two sub matrices, wherein each sub-matrix comprises the transformation matrix and the transforming element comprises a plurality of lifting stages and wherein each lifting stage comprises the processing of blocks of the digital signal by an auxiliary transformation and by a rounding unit.

U.S. Pat. No. 8,126,950 discloses a method for performing a domain transformation of a digital signal from the time domain into the frequency domain and vice versa, the method including performing the transformation by a transforming element, the transformation element comprising a plurality of lifting stages, wherein the transformation corresponds to a transformation matrix and wherein at least one lifting stage of the plurality of lifting stages comprises at least one auxiliary transformation matrix and a rounding unit, the auxiliary transformation matrix comprising the transformation matrix itself or the corresponding transformation matrix of lower dimension. The method further comprising performing a rounding operation of the signal by the rounding unit after the transformation by the auxiliary transformation matrix.

U.S. Pat. No. 8,107,145 discloses a reproducing device for performing reproduction regarding a hologram recording medium where a hologram page is recorded in accordance with signal light, by interference between the signal light where bit data is arrayed with the information of light intensity difference in pixel increments, and reference light, includes, a reference light generating unit to generate reference light irradiated when obtaining a reproduced image; a coherent light generating unit to generate coherent light of which the intensity is greater than the absolute value of the minimum amplitude of the reproduced image, with the same phase as the reference phase within the reproduced image; an image sensor to receive an input image in pixel increments; and an optical system to guide the reference light to the hologram recording medium, and also guide the obtained reproduced image according to the irradiation of the reference light, and the coherent light to the image sensor.

U.S. Pat. No. 8,099,381 discloses systems and methods for factorizing high-dimensional data by simultaneously capturing factors for all data dimensions and their correlations in a factor model, wherein the factor model provides a parsimonious description of the data; and generating a corresponding loss function to evaluate the factor model.

U.S. Pat. No. 8,090,665 discloses systems and methods to find dynamic social networks by applying a dynamic stochastic block model to generate one or more dynamic social networks, wherein the model simultaneously captures communities and their evolutions, and inferring best-fit parameters for the dynamic stochastic model with online learning and offline learning.

U.S. Pat. No. 8,077,785 discloses a method for determining a phase of each of a plurality of transmitting antennas in a multiple input and multiple output (MIMO) communication system includes: calculating, for first and second ones of the plurality of transmitting antennas, a value based on first and second groups of channel gains, the first group including channel gains between the first transmitting antenna and each of a plurality of receiving antennas, the second group including channel gains between the second transmitting antenna and each of the plurality of receiving antennas; and determining the phase of each of the plurality of transmitting antennas based on at least the value.

U.S. Pat. No. 8,060,512 discloses a system and method for analyzing multi-dimensional cluster data sets to identify clusters of related documents in an electronic document storage system. Digital documents, for which multi-dimensional probabilistic relationships are to be determined, are received and then parsed to identify multi-dimensional count data with at least three dimensions. Multi-dimensional tensors representing the count data and estimated cluster membership probabilities are created. The tensors are then iteratively processed using a first and a complementary second tensor factorization model to refine the cluster definition matrices until a convergence criteria has been satisfied. Likely cluster memberships for the count data are determined based upon the refinements made to the cluster definition matrices by the alternating tensor factorization models. The present method advantageously extends to the field of tensor analysis a combination of Non-negative Matrix Factorization and Probabilistic Latent Semantic Analysis to decompose non-negative data.

U.S. Pat. No. 8,046,214 discloses a multi-channel audio decoder providing a reduced complexity processing to reconstruct multi-channel audio from an encoded bitstream in which the multi-channel audio is represented as a coded subset of the channels along with a complex channel correlation matrix parameterization. The decoder translates the complex channel correlation matrix parameterization to a real transform that satisfies the magnitude of the complex channel correlation matrix. The multi-channel audio is derived from the coded subset of channels via channel extension processing using a real value effect signal and real number scaling.

U.S. Pat. No. 8,045,810 discloses a method and system for reducing the number of mathematical operations required in the JPEG decoding process without substantially impacting the quality of the image displayed. Embodiments provide an efficient JPEG decoding process for the purposes of displaying an image on a display smaller than the source image, for example, the screen of a handheld device. According to one aspect of the invention, this is accomplished by reducing the amount of processing required for dequantization and inverse DCT (IDCT) by effectively reducing the size of the image in the quantized, DCT domain prior to dequantization and IDCT. This can be done, for example, by discarding unnecessary DCT index rows and columns prior to dequantization and IDCT. In one embodiment, columns from the right, and rows from the bottom are discarded such that only the top left portion of the block of quantized, and DCT coefficients are processed.

U.S. Pat. No. 8,037,080 discloses example collaborative filtering techniques providing improved recommendation prediction accuracy by capitalizing on the advantages of both neighborhood and latent factor approaches. One example collaborative filtering technique is based on an optimization framework that allows smooth integration of a neighborhood model with latent factor models, and which provides for the inclusion of implicit user feedback. A disclosed example Singular Value Decomposition (SVD)-based latent factor model facilitates the explanation or disclosure of the reasoning behind recommendations. Another example collaborative filtering model integrates neighborhood modeling and SVD-based latent factor modeling into a single modeling framework. These collaborative filtering techniques can be advantageously deployed in, for example, a multimedia content distribution system of a networked service provider.

U.S. Pat. No. 8,024,193 discloses methods and apparatus for automatic identification of near-redundant units in a large TTS voice table, identifying which units are distinctive enough to keep and which units are sufficiently redundant to discard. According to an aspect of the invention, pruning is treated as a clustering problem in a suitable feature space. All instances of a given unit (e.g. word or characters expressed as Unicode strings) are mapped onto the feature space, and cluster units in that space using a suitable similarity measure. Since all units in a given cluster are, by construction, closely related from the point of view of the measure used, they are suitably redundant and can be replaced by a single instance. The disclosed method can detect near-redundancy in TTS units in a completely unsupervised manner, based on an original feature extraction and clustering strategy. Each unit can be processed in parallel, and the algorithm is totally scalable, with a pruning factor determinable by a user through the near-redundancy criterion. In an exemplary implementation, a matrix-style modal analysis via Singular Value Decomposition (SVD) is performed on the matrix of the observed instances for the given word unit, resulting in each row of the matrix associated with a feature vector, which can then be clustered using an appropriate closeness measure. Pruning results by mapping each instance to the centroid of its cluster.

U.S. Pat. No. 8,019,539 discloses a navigation system for a vehicle having a receiver operable to receive a plurality of signals from a plurality of transmitters includes a processor and a memory device. The memory device has stored thereon machine-readable instructions that, when executed by the processor, enable the processor to determine a set of error estimates corresponding to pseudo-range measurements derived from the plurality of signals, determine an error covariance matrix for a main navigation solution using ionospheric-delay data, and, using a parity space technique, determine at least one protection level value based on the error covariance matrix.

U.S. Pat. No. 8,015,003 discloses a method and system for denoising a mixed signal. A constrained non-negative matrix factorization (NMF) is applied to the mixed signal. The NMF is constrained by a denoising model, in which the denoising model includes training basis matrices of a training acoustic signal and a training noise signal, and statistics of weights of the training basis matrices. The applying produces weight of a basis matrix of the acoustic signal of the mixed signal. A product of the weights of the basis matrix of the acoustic signal and the training basis matrices of the training acoustic signal and the training noise signal is taken to reconstruct the acoustic signal. The mixed signal can be speech and noise.

U.S. Pat. No. 8,005,121 discloses the embodiments relate to an apparatus and a method for re-synthesizing signals. The apparatus includes a receiver for receiving a plurality of digitally multiplexed signals, each digitally multiplexed signal associated with a different physical transmission channel, and for simultaneously recovering from at least two of the digital multiplexes a plurality of bit streams. The apparatus also includes a transmitter for inserting the plurality of bit streams into different digital multiplexes and for modulating the different digital multiplexes for transmission on different transmission channels. The method involves receiving a first signal having a plurality of different program streams in different frequency channels, selecting a set of program streams from the plurality of different frequency channels, combining the set of program streams to form a second signal, and transmitting the second signal.

U.S. Pat. No. 8,001,132 discloses systems and techniques for estimation of item ratings for a user. A set of item ratings by multiple users is maintained, and similarity measures for all items are precomputed, as well as values used to generate interpolation weights for ratings neighboring a rating of interest to be estimated. A predetermined number of neighbors are selected for an item whose rating is to be estimated, the neighbors being those with the highest similarity measures. Global effects are removed, and interpolation weights for the neighbors are computed simultaneously. The interpolation weights are used to estimate a rating for the item based on the neighboring ratings, Suitably, ratings are estimated for all items in a predetermined dataset that have not yet been rated by the user, and recommendations are made of the user by selecting a predetermined number of items in the dataset having the highest estimated ratings.

U.S. Pat. No. 7,996,193 discloses a method for reducing the order of system models exploiting sparsity. According to one embodiment, a computer-implemented method receives a system model having a first system order. The system model contains a plurality of system nodes, a plurality of system matrices. The system nodes are reordered and a reduced order system is constructed by a matrix decomposition (e.g., Cholesky or LU decomposition) on an expansion frequency without calculating a projection matrix. The reduced order system model has a lower system order than the original system model.

U.S. Pat. No. 7,991,717 discloses a system, method, and process for configuring iterative, self-correcting algorithms, such as neural networks, so that the weights or characteristics to which the algorithm converge to do not require the use of test or validation sets, and the maximum error in failing to achieve optimal cessation of training can be calculated. In addition, a method for internally validating the correctness, i.e. determining the degree of accuracy of the predictions derived from the system, method, and process of the present invention is disclosed.

U.S. Pat. No. 7,991,550 discloses a method for simultaneously tracking a plurality of objects and registering a plurality of object-locating sensors mounted on a vehicle relative to the vehicle is based upon collected sensor data, historical sensor registration data, historical object trajectories, and a weighted algorithm based upon geometric proximity to the vehicle and sensor data variance.

U.S. Pat. No. 7,970,727 discloses a method for modeling data affinities and data structures. In one implementation, a contextual distance may be calculated between a selected data point in a data sample and a data point in a contextual set of the selected data point. The contextual set may include the selected data point and one or more data points in the neighborhood of the selected data point. The contextual distance may be the difference between the selected data point's contribution to the integrity of the geometric structure of the contextual set and the data point's contribution to the integrity of the geometric structure of the contextual set. The process may be repeated for each data point in the contextual set of the selected data point. The process may be repeated for each selected data point in the data sample. A digraph may be created using a plurality of contextual distances generated by the process.

U.S. Pat. No. 7,953,682 discloses methods, apparatus and computer program code processing digital data using non-negative matrix factorization. A method of digitally processing data in a data array defining a target matrix (X) using non-negative matrix factorization to determine a pair of matrices (F, G), a first matrix of said pair determining a set of features for representing said data, a second matrix of said pair determining weights of said features, such that a product of said first and second matrices approximates said target matrix, the method comprising: inputting said target matrix data (X); selecting a row of said one of said first and second matrices and a column of the other of said first and second matrices; determining a target contribution (R) of said selected row and column to said target matrix; determining, subject to a non-negativity constraint, updated values for said selected row and column from said target contribution; and repeating said selecting and determining for the other rows and columns of said first and second matrices until all said rows and columns have been updated.

U.S. Pat. No. 7,953,676 discloses a method for predicting future responses from large sets of dyadic data including measuring a dyadic response variable associated with a dyad from two different sets of data; measuring a vector of covariates that captures the characteristics of the dyad; determining one or more latent, unmeasured characteristics that are not determined by the vector of covariates and which induce local structures in a dyadic space defined by the two different sets of data; and modeling a predictive response of the measurements as a function of both the vector of covariates and the one or more latent characteristics, wherein modeling includes employing a combination of regression and matrix co-clustering techniques, and wherein the one or more latent characteristics provide a smoothing effect to the function that produces a more accurate and interpretable predictive model of the dyadic space that predicts future dyadic interaction based on the two different sets of data.

U.S. Pat. No. 7,949,931 discloses a method for error detection in a memory system. The method includes calculating one or more signatures associated with data that contains an error. It is determined if the error is a potential correctable error. If the error is a potential correctable error, then the calculated signatures are compared to one or more signatures in a trapping set. The trapping set includes signatures associated with uncorrectable errors. An uncorrectable error flag is set in response to determining that at least one of the calculated signatures is equal to a signature in the trapping set.

U.S. Pat. No. 7,912,140 discloses a method and a system for reducing computational complexity in a maximum-likelihood MIMO decoder, while maintaining its high performance. A factorization operation is applied on the channel Matrix H. The decomposition creates two matrixes: an upper triangular with only real-numbers on the diagonal and a unitary matrix. The decomposition simplifies the representation of the distance calculation needed for constellation points search. An exhaustive search for all the points in the constellation for two spatial streams t(1), t(2) is performed, searching all possible transmit points of (t2), wherein each point generates a SISO slicing problem in terms of transmit points of (t1); Then, decomposing x,y components of t(1), thus turning a two-dimensional problem into two one-dimensional problems. Finally searching the remaining points of t(1) and using Gray coding in the constellation points arrangement and the symmetry deriving from it to further reduce the number of constellation points that have to be searched.

U.S. Pat. No. 7,899,087 discloses an apparatus and method for performing frequency translation. The apparatus includes a receiver for receiving and digitizing a plurality of first signals, each signal containing channels and for simultaneously recovering a set of selected channels from the plurality of first signals. The apparatus also includes a transmitter for combining the set of selected channels to produce a second signal. The method of the present invention includes receiving a first signal containing a plurality of different channels, selecting a set of selected channels from the plurality of different channels, combining the set of selected channels to form a second signal and transmitting the second signal.

U.S. Pat. No. 7,885,792 discloses a method combining functionality from a matrix language programming environment, a state chart programming environment and a block diagram programming environment into an integrated programming environment. The method can also include generating computer instructions from the integrated programming environment in a single user action. The integrated programming environment can support fixed-point arithmetic.

U.S. Pat. No. 7,875,787 discloses a system and method for visualization of music and other sounds using note extraction. In one embodiment, the twelve notes of an octave are labeled around a circle. Raw audio information is fed into the system, whereby the system applies note extraction techniques to isolate the musical notes in a particular passage. The intervals between the notes are then visualized by displaying a line between the labels corresponding to the note labels on the circle. In some embodiments, the lines representing the intervals are color coded with a different color for each of the six intervals. In other embodiments, the music and other sounds are visualized upon a helix that allows an indication of absolute frequency to be displayed for each note or sound.

U.S. Pat. No. 7,873,127 discloses techniques where sample vectors of a signal received simultaneously by an array of antennas are processed to estimate a weight for each sample vector that maximizes the energy of the individual sample vector that resulted from propagation of the signal from a known source and/or minimizes the energy of the sample vector that resulted from interference with propagation of the signal from the known source. Each sample vector is combined with the weight that is estimated for the respective sample vector to provide a plurality of weighted sample vectors. The plurality of weighted sample vectors are summed to provide a resultant weighted sample vector for the received signal. The weight for each sample vector is estimated by processing the sample vector which includes a step of calculating a pseudoinverse by a simplified method.

U.S. Pat. No. 7,849,126 discloses a system and method for fast computing the Cholesky factorization of a positive definite matrix. In order to reduce the computation time of matrix factorizations, the present invention uses three atomic components, namely MA atoms, M atoms, and an S atom. The three kinds of components are arranged in a configuration that returns the Cholesky factorization of the input matrix.

U.S. Pat. No. 7,844,117 discloses an image digest based search approach allowing images within an image repository related to a query image to be located despite cropping, rotating, localized changes in image content, compression formats and/or an unlimited variety of other distortions. In particular, the approach allows potential distortion types to be characterized and to be fitted to an exponential family of equations matched to a Bregman distance. Image digests matched to the identified distortion types may then be generated for stored images using the matched Bregman distances, thereby allowing searches to be conducted of the image repository that explicitly account for the statistical nature of distortions on the image. Processing associated with characterizing image noise, generating matched Bregman distances, and generating image digests for images within an image repository based on a wide range of distortion types and processing parameters may be performed offline and stored for later use, thereby improving search response times.

U.S. Pat. No. 7,454,453 discloses a fast correlator transform (FCT) algorithm and methods and systems for implementing same, correlate an encoded data word with encoding coefficients, wherein each coefficient has k possible states. The results are grouped into groups. Members of each group are added to one another, thereby generating a first layer of correlation results. The first layer of results is grouped and the members of each group are summed with one another to generate a second layer of results. This process is repeated until a final layer of results is generated. The final layer of results includes a separate correlation output for each possible state of the complete set of coefficients.

Our inventor's certificate of USSR SU1319013 discloses a generator of basis functions generating basis function systems in form of sets of components of scarcely populated matrices, product of which is a matrix of a corresponding linear orthogonal transform. The generated sets of components serve as parameters of fast linear orthogonal transformation systems.

Finally, our inventor's certificate of USSR SU1413615 discloses another generator of basis functions generating wider class of basis function systems in form of sets of components of scarcely populated matrices, product of which is a matrix of a corresponding linear orthogonal transform.

It is believed that tensor-vector multiplications can be further accelerated, the methods of multiplication can be construed to become faster, and the systems for multiplication can be designed with smaller number of components.

### SUMMARY OF THE INVENTION

Digital data often arises from the sampling of an analogue signal, for example by determining the amplitude of an analogue signal at specified times. The particular values derived from the sampling can constitute the components of a vector.

The linear operation upon the data can then be represented by the operation of a tensor upon the vector to produce a tensor of lower rank. Ordinarily tensors of higher than 2d order are not necessary, but are useful where the resulting signal may comprise multiple channels in form of a matrix or a tensor.

The operation of a digital filters comprises, or can be approximated by, the operation of a linear operator on a representation of the digital signal. In that case, the digital filter can be implemented by the operation of a tensor upon a vector. The present invention applies to both linear, time-invariant digital filters and adaptive filters whose coefficients are calculated and changed according to the system goal of optimization.

For a causal discrete-time multichannel (M-channel) direct-form FIR filter of order “N”, each value of the output sequence of each channel is a weighted sum of the most recent input values:

$${y}_{0 , n} = {b}_{0 , 0} {x}_{n} + {b}_{0 , 1} {x}_{n - 1} + {b}_{0 , 2} {x}_{n - 2} + … + {b}_{0 , N - 1} {x}_{n - ( N - 1 )} + {b}_{0 , N} {x}_{n - N}$$

$${y}_{1 , n} = {b}_{1 , 0} {x}_{n} + {b}_{1 , 1} {x}_{n - 1} + {b}_{1 , 2} {x}_{n - 2} + … + {b}_{1 , N - 1} {x}_{n - ( N - 1 )} + {b}_{1 , N} {x}_{n - N}$$

$${y}_{2 , n} = {b}_{2 , 0} {x}_{n} + {b}_{2 , 1} {x}_{n - 1} + {b}_{2 , 2} {x}_{n - 2} + … + {b}_{2 , N - 1} {x}_{n - ( N - 1 )} + {b}_{2 , N} {x}_{n - N}$$

$$…$$

$${Y}_{M - 2 , n} = {b}_{M - 2 , 0} {x}_{n} + {b}_{M - 2 , 1} {x}_{n - 1} + {b}_{M - 2 , 2} {x}_{n - 2} + … + {b}_{M - 2 , N - 1} {x}_{n - ( N - 1 )} + {b}_{M - 2 , N} {x}_{n - N}$$

$${Y}_{M - 1 , n} = {b}_{M - 1 , 0} {x}_{n} + {b}_{M - 1 , 1} {x}_{n - 1} + {b}_{M - 1 , 2} {x}_{n - 2} + … + {b}_{M - 1 , N - 1} {x}_{n - ( N - 1 )} + {b}_{M - 1 , N} {x}_{n - N}$$

Here X_{n,}^{y-,n} is a signal in an n^{th} time slot. X denotes input, y denotes output to and from the filter.

In other words the output of m-th channel is described as:

$${y}_{m , n} = {b}_{m , 0} {x}_{n} + {b}_{m , 1} {x}_{n - 1} + {b}_{m , 2} {x}_{n - 2} + … + {b}_{m , N - 1} {x}_{n - 2} + {b}_{m , N} {x}_{n - 1} = {\sum }_{i = 0}^{N} {b}_{m , i} {x}_{n - i} = [ \begin{matrix}{b}_{2 , 0} & {b}_{2 , 1} & {b}_{2 , 2} & … & {b}_{2 , N - 1} & {b}_{2 , N}\end{matrix} ] \cdot [ \begin{matrix}{x}_{n} \\ {x}_{n - 1} \\ {x}_{n - 2} \\ … \\ {x}_{n - ( N - 1 )} \\ {x}_{n - N}\end{matrix} ]$$

which in matrix product notation is:

$$[ \begin{matrix}{y}_{0 , n} \\ {y}_{1 , n} \\ {y}_{2 , n} \\ … \\ {y}_{M - 2 , n} \\ {y}_{M - 1 , n}\end{matrix} ] = [ \begin{matrix}{b}_{0 , 0} & {b}_{0 , 1} & {b}_{0 , 2} & … & {b}_{0 , N - 1} & {b}_{0 , N} \\ {b}_{1 , 0} & {b}_{1 , 1} & {b}_{1 , 2} & … & {b}_{1 , N - 1} & {b}_{1 , N} \\ {b}_{2 , 0} & {b}_{2 , 1} & {b}_{2 , 2} & … & {b}_{2 , N - 1} & {b}_{2 , N} \\ & & & … & & \\ & & & … & & \\ & & & … & & \\ {b}_{M - 2 , 0} & {b}_{M - 2 , 1} & {b}_{M - 2 , 2} & … & {b}_{M - 2 , N - 1} & {b}_{M - 2 , N} \\ {b}_{M - 1 , 0} & {b}_{M - 1 , 1} & {b}_{M - 1 , 2} & … & {b}_{M - 1 , N - 1} & {b}_{M - 1 , N}\end{matrix} ] \cdot [ \begin{matrix}{x}_{n} \\ {x}_{n - 1} \\ {x}_{n - 2} \\ … \\ {x}_{n - ( N - 1 )} \\ {x}_{n - N}\end{matrix} ]$$

Here:

N—is filter order;

M—number of channels;

xₙ—is the input signal during the n^{th} time slot,

$$[ \begin{matrix}{y}_{0 , n} \\ {y}_{1 , n} \\ {y}_{2 , n} \\ … \\ {y}_{M - 2 , n} \\ {y}_{M - 1 , n}\end{matrix} ]$$

—is the vector of output values of filters (or channels) number from 0 to M−1, or −y_{m,n} —is the output value of filter number m during the n^{th} time slot.

$$[ \begin{matrix}{b}_{0 , 0} & {b}_{0 , 1} & {b}_{0 , 2} & … & {b}_{0 , N - 1} & {b}_{0 , N} \\ {b}_{1 , 0} & {b}_{1 , 1} & {b}_{1 , 2} & … & {b}_{1 , N - 1} & {b}_{1 , N} \\ {b}_{2 , 0} & {b}_{2 , 1} & {b}_{2 , 2} & … & {b}_{2 , N - 1} & {b}_{2 , N} \\ & & & … & & \\ & & & … & & \\ & & & … & & \\ {b}_{M - 2 , 0} & {b}_{M - 2 , 1} & {b}_{M - 2 , 2} & … & {b}_{M - 2 , N - 1} & {b}_{M - 2 , N} \\ {b}_{M - 1 , 0} & {b}_{M - 1 , 1} & {b}_{M - 1 , 2} & … & {b}_{M - 1 , N - 1} & {b}_{M - 1 , N}\end{matrix} ]$$

—is the matrix of filter coefficients and which is factored into a product of a commutator and a kernel, and b_{m,i}—is the value of the impulse response at the i'th instant for 0<=i<=N of N-th order FIR filter number m for 0<=m<M. Since each filter channel is a direct form FIR filter then b_{m,i} is also a coefficient of the filter.

The Hardware

The construction of the digital filter proceeds by building a network of dedicated modular filter components designed to implement various repetitive steps involved in progressively obtaining the result of operating upon the data vector. One benefit of the present invention is a significant reduction in the number of such modules. Those modules are preferably constructed in an integrated chip design primarily dedicated to the filtering function.

In particular several examples will be provided where the number of such modules is greatly reduced due to an improved logical structure. In particular, the burdensome task of calculating the action of the tensor upon a sequence of vectors is simplified by reorganizing the tensor into a commutator and a kernel. The commutator is a tensor of one degree higher order, but whose elements are simplified so that they are simply pointers to elements of the kernel. The kernel is a simple vector which contains only unique elements corresponding to the nonzero values present in the original tensor.

The multiplication proceeds by forming a matrix product of the kernel by the vector. All the non-trivial multiplication takes place during the formation of that matrix product. Subsequently the matrix product is contracted by the commutator to form the output vector.

In this manner, the present invention provides a significant improvement of the operation of any digital device constructed to execute the filtering function.

Accordingly within the present invention I provide a method and a system for tensor-vector multiplication, which is a further improvement of the existing methods and systems of this type.

In keeping with these objects and with others which will become apparent hereinafter, one feature of the present invention resides, briefly stated, in a method of tensor-vector multiplication, comprising the steps of factoring an original tensor into a kernel and a commutator; multiplying the kernel obtained by the factoring of the original tensor, by the vector and thereby obtaining a matrix; and summating elements and sums of elements of the matrix as defined by the commutator obtained by the factoring of the original tensor, and thereby obtaining a resulting tensor which corresponds to a product of the original tensor and the vector.

In accordance with another feature of the present invention, the method further comprises rounding elements of the original tensor to a desired precision and obtaining the original tensor with the rounded elements, wherein the factoring includes factoring the original tensor with the rounded elements into the kernel and the commutator.

Still another feature of the present invention resides in that the factoring of the original tensor includes factoring into the kernel which contains kernel elements that are different from one another, and the multiplying includes multiplying the kernel which contains the different kernel elements.

Still another feature of the present invention resides in that the method also comprises using as the commutator a commutator image in which indices of elements of the kernel are located at positions of corresponding elements of the original tensor.

In accordance with the further feature of the present invention, the summating includes summating on a priority basis of those pairs of elements whose indices in the commutator image are encountered most often and thereby producing the sums when the pair is encountered for the first time, and using the obtained sum for all remaining similar pairs of elements.

In accordance with still a further feature of the present invention, the method also includes using a plurality of consecutive vectors shifted in a manner selected from the group consisting of cyclically and linearly; and, for the cyclic shift, carrying out the multiplying by a first of the consecutive vectors and cyclic shift of the matrix for all subsequent shift positions, while, for the linear shift, carrying out the multiplying by a last appeared element of each of the consecutive vectors and linear shift of the matrix.

The inventive method further comprises using as the original tensor a tensor which is either a matrix or a vector.

In the inventive method, elements of the tensor and the vector can be elements selected from the group consisting of single bit values, integer numbers, fixed point numbers, floating point numbers, non-numeric literals, real numbers, imaginary numbers, complex numbers represented by pairs having one real and one imaginary components, complex numbers represented by pairs having one magnitude and one angle components, quaternion numbers, and combinations thereof.

Also in the inventive method, operations with the tensor and the vector with elements being non-numeric literals can be string operations selected from the group consisting of concatenation operations, string replacement operations, and combinations thereof.

Finally, in the inventive method, operations with the tensor and the vector with elements being single bit values can be logical operations and their logical inversions selected from the group consisting of logic conjunction operations, logic disjunction operations, modulo two addition operations, and combinations thereof.

The present invention also deals with a system for fast tensor-vector multiplication. The inventive system comprises means for factoring an original tensor into a kernel and a commutator; means for multiplying the kernel obtained by the factoring of the original tensor, by the vector and thereby obtaining a matrix; and means for summating elements and sums of elements of the matrix as defined by the commutator obtained by the factoring of the original tensor, and thereby obtaining a resulting tensor which corresponds to a product of the original tensor and the vector.

In the system in accordance with the present invention, the means for factoring the original tensor into the kernel and the commutator can comprise a precision converter converting tensor elements to desired precision and a factorizing unit building the kernel and the commutator; the means for multiplying the kernel by the vector can comprise a multiplier set performing all component multiplication operations and a recirculator storing and moving results of the component multiplication operations; and the means for summating the elements and the sums of the elements of the matrix can comprise a reducer which builds a pattern set and adjusts pattern delays and number of channels, a summator set which performs all summating operations, an indexer and a positioner which define indices and positions of the elements or the sums of elements utilized in composing the resulting tensor, the recirculator storing and moving results of the summation operations, and a result extractor forming the resulting tensor.

The novel features of the present invention are set forth in particular in the appended claims. The invention itself, however, will be best understood from the following description of the preferred embodiments, which is accompanied by the following drawings.

### BRIEF DESCRIPTION OF THE DRAWINGS

FIG. 1 is a general view of a system for tensor-vector multiplication in accordance with the presented invention, in which a method for tensor-vector multiplication according to the present invention is implemented.

FIG. 2 is a detailed view of the system for tensor-vector multiplication in accordance with the presented invention, in which a method for tensor-vector multiplication according to the present invention is implemented.

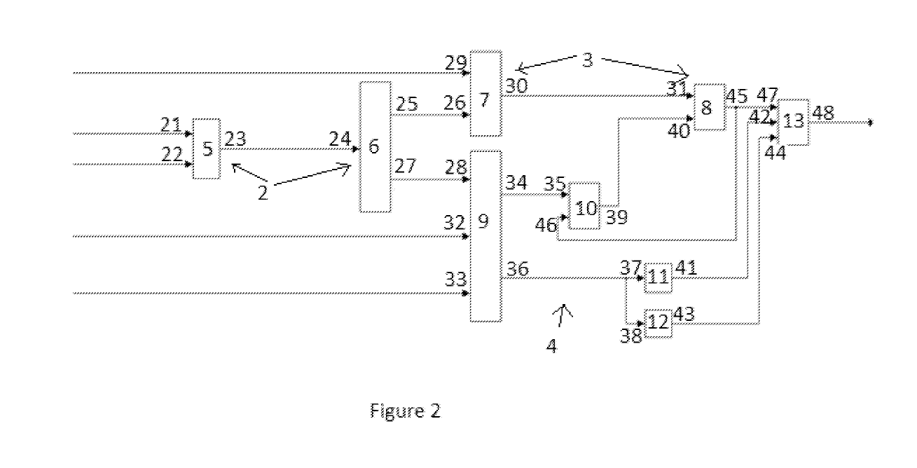

FIG. 3 is internal architecture of reducer of the inventive system.

FIG. 4 is functional block-diagram of precision converter of the inventive system.

FIG. 5 is functional block-diagram of factorizing unit of the inventive system.

FIG. 6 is functional block-diagram of multiplier set of the inventive system.

FIG. 7 is functional block-diagram of summator set of the inventive system.

FIG. 8 is functional block-diagram of indexer of the inventive system.

FIG. 9 is functional block-diagram of positioner of the inventive system.

FIG. 10 is functional block-diagram of recirculator of the inventive system.

FIG. 11 is functional block-diagram of result extractor of the inventive system.

FIG. 12 is functional block-diagram of pattern set builder of the inventive system.

FIG. 13 is functional block-diagram of delay adjuster of the inventive system.

FIG. 14 is functional block-diagram of number of channels adjuster of the inventive system.

FIG. 15 is an example of a filter bank for a 20×32 matrix.

FIG. 16 is an example of the internal structure of blocks in FIG. 15.

FIG. 17 is an alternate example of a filter bank.

FIG. 18 is an example of a filter bank for a 28×128 matric and a 1×λ8 vector.

FIG. 19 is an example of a filter bank for a 44×2048 matrix and a 1×44 vector.

### DESCRIPTION OF PREFERRED EMBODIMENTS

Digital filters may be utilized in audio or video systems where a signal originates in analog signals that are sampled to provide on incoming signal. An analog to digital converter produces the digital signal that is then operated upon, i.e. filtered, and typically sent to one or more digital to analog converters to be fed to various transducers. In many cases, the filter may operate upon signals that originate in a digital format, for example signals received from digital communication systems such as computers, cell phones or the like. The digital signal is operated upon in a system that employs a microprocessor and some memory to store data and filter coefficients. The system is integrated into specialized computers controlled by software.

Configurable Filter Bank

Time varying signal from a sensor such as microphone, vibration sensor, electromagnetic sensor, etc. is digitized to digital samples produced at a constant time rate.

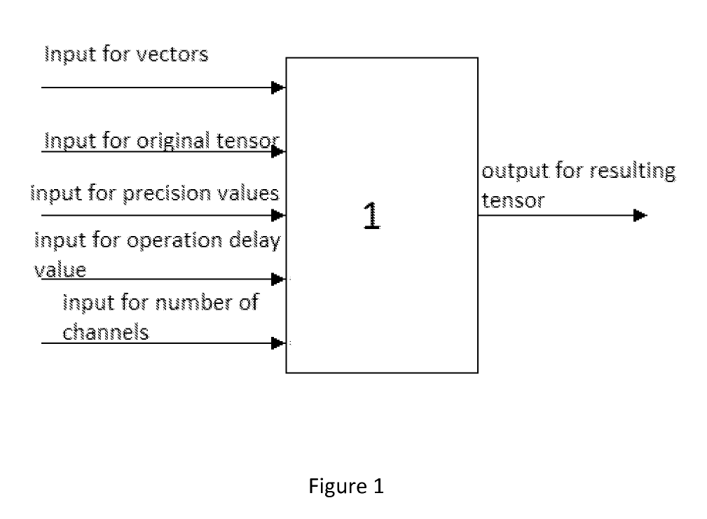

Each new sample is passed to “input for vectors” of a block 1 (FIG. 1) which is also input 29 of block 7. The resulting filtered signals are produced in the system 1.

Each new sample of each filter in the filter bank is produced in the system 1 and sequentially conveyed to a multichannel output marked as “output for resulting tensor” on FIG. 1. The number of filters in the filter bank defines the number of channels in this output. These output samples are converted to analog form by digital to analog converters connected to corresponding channels of the output of block 1, or can be used in digital form.

The numerical precision of the filter bank is defined by a value present at the input marked as “input for precision values” on FIG. 1.

The impulse response of each filter of the filter bank is defined by values simultaneously present at the input marked “input for original tensor”. The size of this input is equal to the impulse response size of the longest filter of the filter bank and the number of filters on the bank.

Additionally, the input signal can be interchangeably sampled from more than one sensor. In this case the number of physical channels multiplexed to a single “input for vectors” is more than one. In this case the output samples present at the “output for resulting tensor” belong to different physical inputs and are interleaved similarly to input samples. The number of such channels is provided as a value present at the input marked as “input for number of channels”.

In these examples, the system 1 includes means 2 for factoring an original tensor into a kernel and a commutator, means 3 for multiplying the kernel obtained by the factoring of the original tensor, by the vector and thereby obtaining a matrix, and means 4 for summating elements and sums of elements of the matrix as defined by the commutator obtained by the factoring of the original tensor, and thereby obtaining a resulting tensor which corresponds to a product of the original tensor and the vector.

In the system in accordance with the present invention, the means 2 for factoring the original tensor into the kernel and the commutator can comprise a precision converter 5 converting tensor elements to desired precision and a factorizing unit 6 building the kernel and the commutator. The precision converter can be a digital circuit comprising bitwise logical AND operation on the input values of the tensor and the desired precision value in form of a bit mask with the number of bits in it similar to the number of bits in the tensor elements. For full precision all precision value bits must be logical ones. In this case the logical AND operation preserves all bits in the tensor elements. If least significant bit of the mask is set to logical zero, the precision of the resulting tensor elements decreases 2 times since their least significant bit becomes zero. If several least significant bits of the mask are set to logical zero, the precision of the resulting tensor elements decreases by 2 times per each zeroed bit.

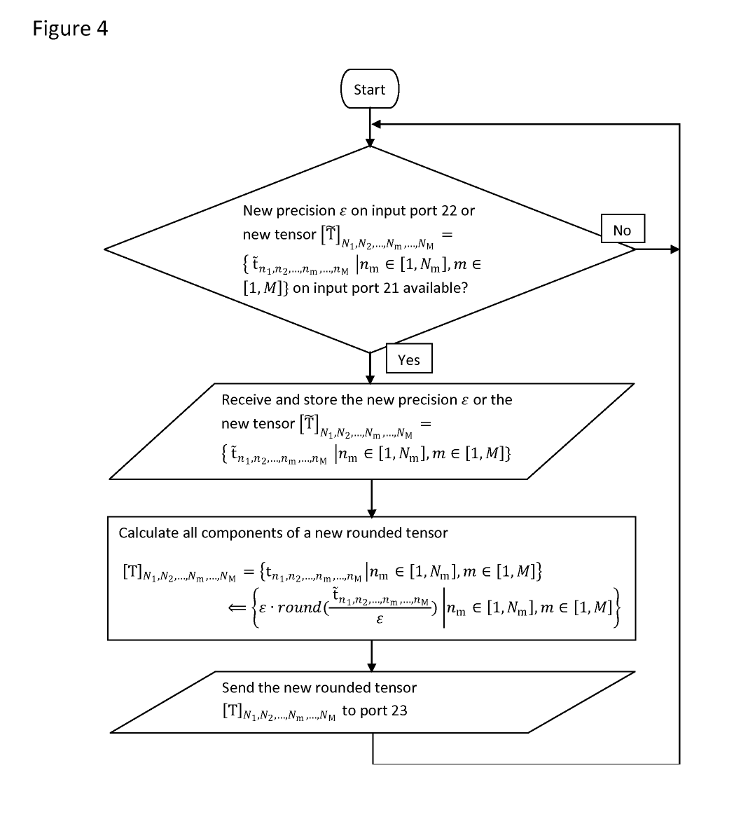

FIG. 4 is functional block-diagram of precision converter of the inventive system.

The factoring unit 6 may be implemented as a processor controlled circuit performing the below algorithm.

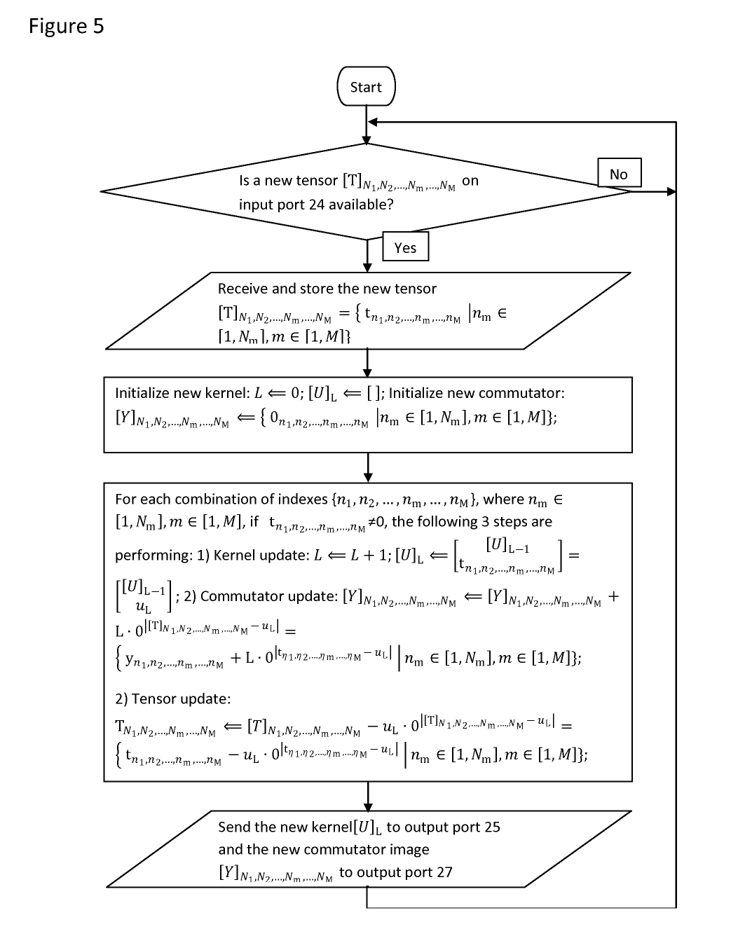

FIG. 5 is functional block-diagram of factorizing unit of the inventive system.

The means 3 for multiplying the kernel by the vector can comprise a multiplier set 7 performing all component multiplication operations and a recirculator 8 storing and moving results of the component multiplication operations. The means 4 for summating the elements and the sums of the elements of the matrix can comprise a reducer 9 which builds a pattern set and adjusts pattern delays and number of channels, a summator set 10 which performs all summating operations, an indexer 11 and a positioner 12 which together define indices and positions of the elements or the sums of elements utilized in composing the resulting tensor. The recirculator 8 stores and moves results of the summation operations. A result extractor 13 forms the resulting tensor.

The multiplier set 7 can comprise of several amplifiers with their gain being controlled by the values of the corresponding elements of kernel. For digital implementation the multiplier set can comprise of the number of multipliers corresponding to the number of elements of kernel. Each multiplier takes the same input signal and multiplies it to the kernel element corresponding to this multiplier.

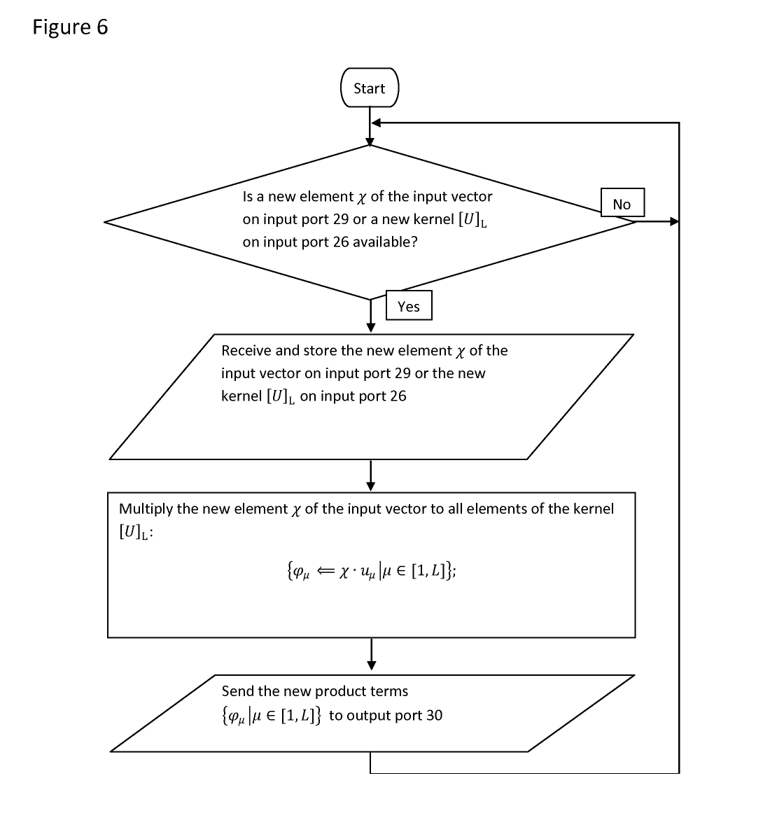

FIG. 6 is functional block-diagram of multiplier set of the inventive system.

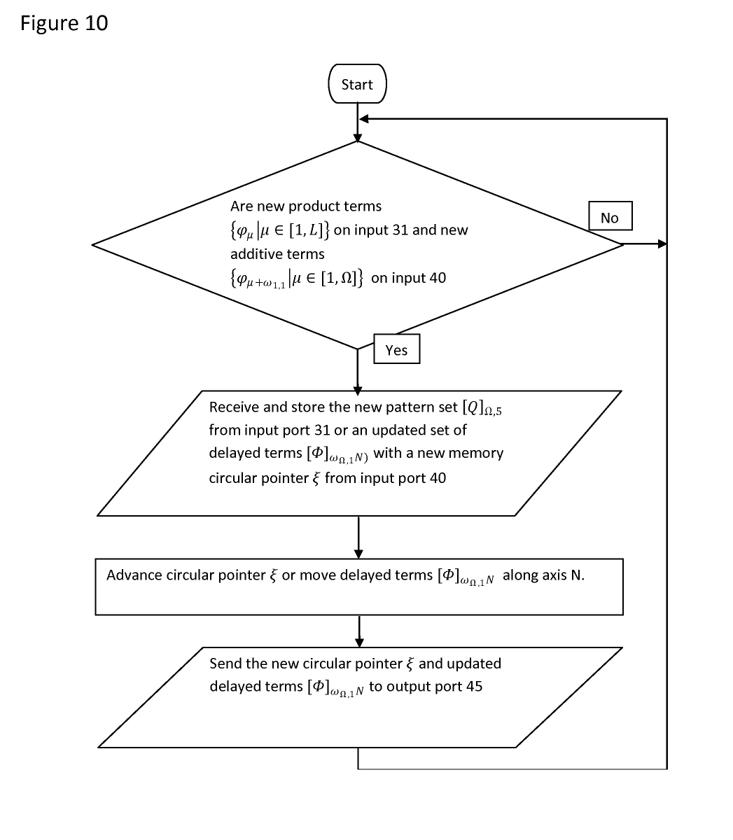

FIG. 10 is functional block-diagram of recirculator of the inventive system.

Recirculator 8 can comprise of a number of separate tapped delay lines (in digital implementation each delay line is a chain of N digital registers connected so that for every clock cycle the data from register n−1 is passed to the register n where n is 2 to N). The number of delay lines is corresponding to the number of kernel elements and the number of elements of the output tensor and the number of intermediate terms obtained in the system. All the resulting values produced by multiplier set and summator set are directed to the inputs of the corresponding delay lines. The previously calculated values propagate along the delay lines until they reach the end of the delay lines and disappear.

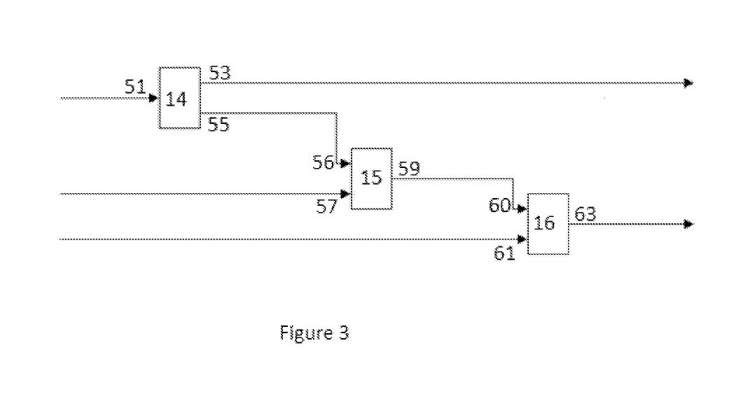

The reducer 9 is presented in FIG. 3 and can comprise of a pattern set builder 14, a delay adjuster 15, and a number of channels adjuster 16.

A reducer may be implemented as a processor controlled circuit performing decomposition of the operation defined by commutator to the number of individual 2-argument summation operations performed by summator set. It also provides control information to the indexer, positioner, and result extractor.

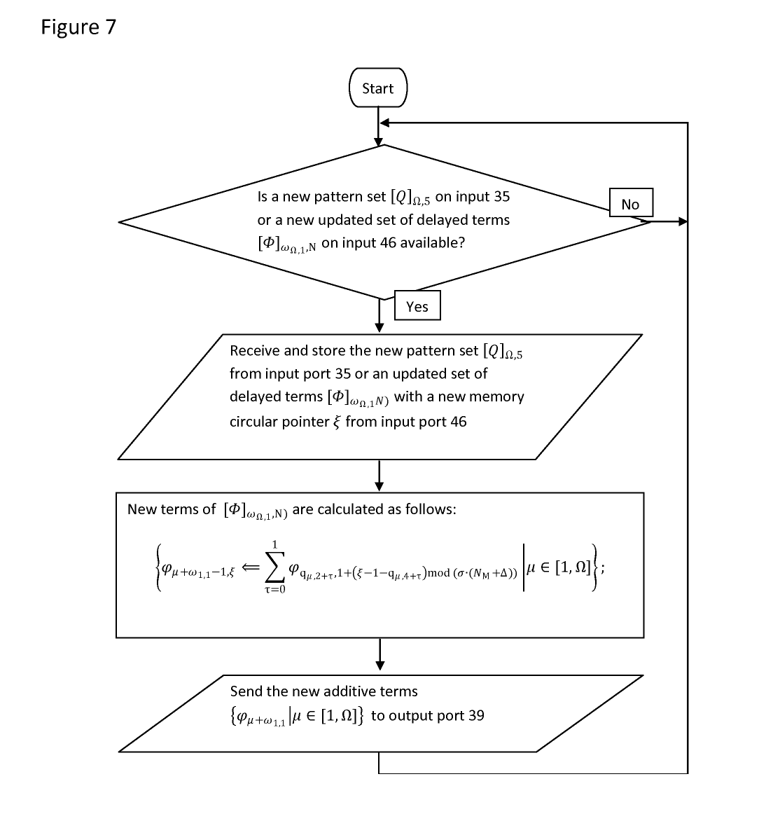

FIG. 7 is functional block-diagram of summator set of the inventive system.

The summator set consists of several digital 2-imput addition units with their inputs connected through multiplexers to taps of the delay lines of the recirculator in according to the nonzero value positions of the commutator and defined by the reducer. The outputs of the addition units are connected to the inputs of corresponding delay lines of the recirculator as defined by the reducer.

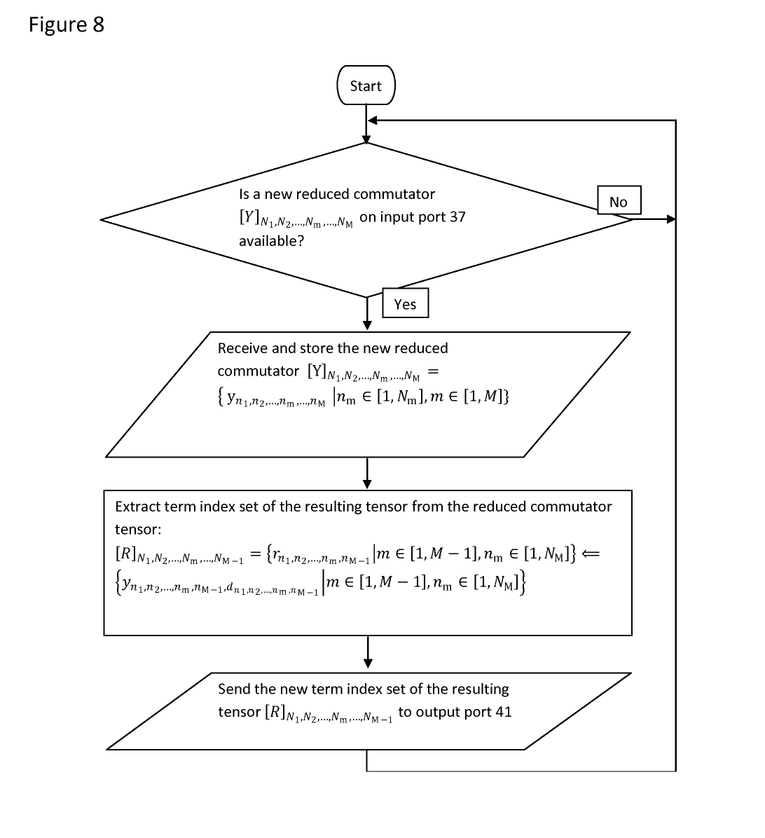

FIG. 8 is functional block-diagram of indexer of the inventive system.

Indexer is a set of hardware multiplexers that connect outputs of delay lines of the recirculator to inputs of delay lines of the result extractor. The configuration of the multiplexers is defined by reducer.

Positioner 12 can comprise a set of hardware multiplexers that connect outputs of the result extractor to corresponding taps of result extractor delay lines. The configuration of the multiplexers is defined by a reducer.

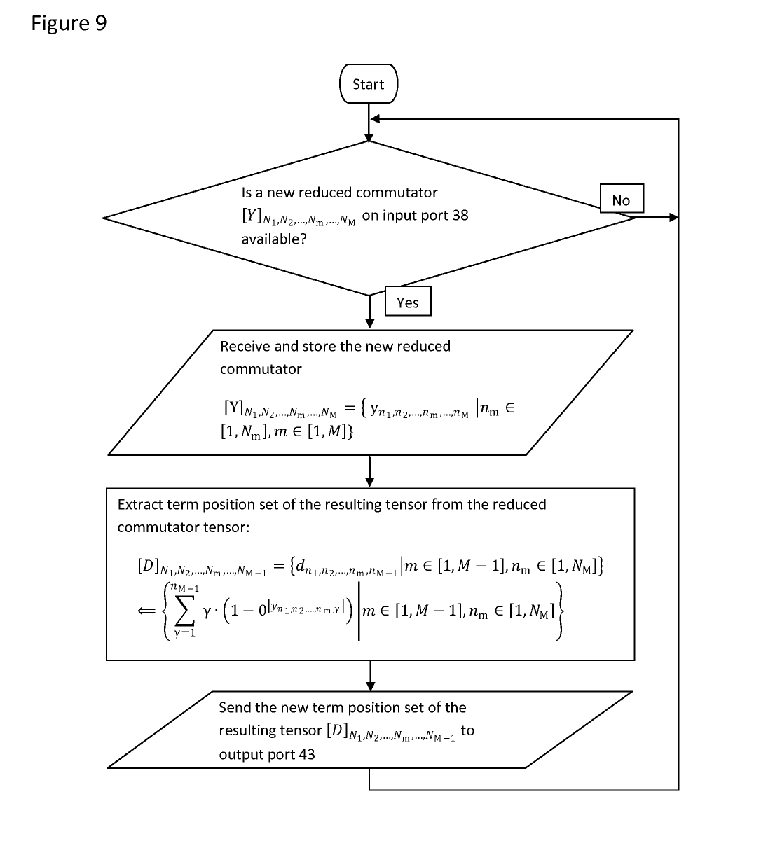

FIG. 9 is functional block-diagram of positioner of the inventive system.

Result extractor 13 is a set of tapped delay lines that is controlled and used by indexer and positioner.

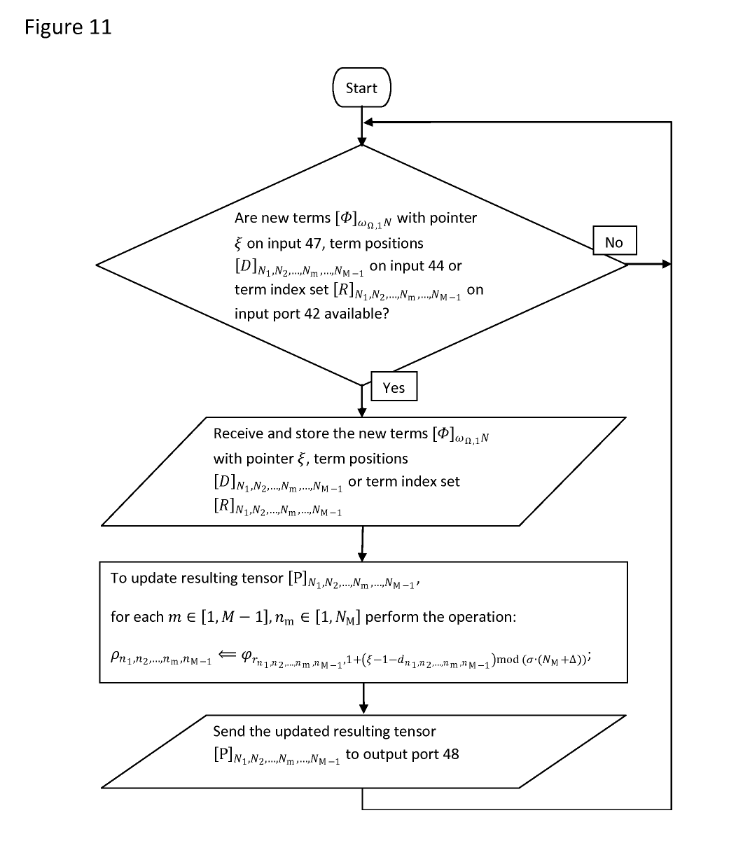

FIG. 11 is functional block-diagram of result extractor of the inventive system.

The components described above are connected in the following way. Input 21 of the precision converter 5 is the input for the original tensor of the system 1. It contains the transformation tensor [\tilde{T}]_{N}_{₁}_{,N}_{₂}_{, . . . ,N}_{ₘ}_{, . . . ,N}_{_{M}}. Input 22 of the precision converter 5 is the input for precision values of the system 1. It contains current value of the rounding precision E. Output 23 of precision converter 5 contains the rounded tensor [T]_{N}_{₁}_{,N}_{₂}_{, . . . ,N}_{ₘ}_{, . . . ,N}_{_{M}} and is connected to input 24 of the factorizing unit 6. Output 25 of the factorizing unit 6 contains the entirety of the obtained kernel vector [U]_{L} and is connected to input 26 of the multiplier set 7. Output 27 of the factorizing unit 6 contains the entirety of the obtained commutator image [Y]_{N}_{₁}_{,N}_{₂}_{, . . . ,N}_{ₘ}_{, . . . ,N}_{_{M}} and is connected to input 28 of the reducer 9. Input 29 of the multiplier set 7 is input for vectors of the system 1. It contains the elements χ of the input vectors of each channel. Output 30 of the multiplier set 7 contains elements φ_{μ,ξ} that are the results of multiplication of the elements of the kernel and the most recently received element χ of the input vector of one of the channels, and is connected to input 31 of the Recirculator 8. Input 32 of the reducer 9 is the input for operational delay value of the system 1. It contains the operational delay δ. Input 33 of the reducer 9 is the input for number of channels of the system 1. It contains the number of channels σ. Output 34 of the reducer 9 contains the entirety of the obtained matrix of combinations [Q]ₚ_{₁}_{-L,5} and is connected to input 35 of the summator set 10. Output 36 of the reducer 9 contains the tensor representing the reduced commutator and is connected to input 37 of the indexer 11 and to input 38 of the positioner 12. Output 39 of the summator set 10 contains the new values of the sums of the combinations φ_{μ+ω}_{_{1,1}}_{-1,ξ} and is connected to input 40 of the recirculator 8. Output 41 of the indexer 11 contains the indices [R]_{N}_{₁}_{,N}_{₂}_{, . . . ,N}_{ₘ}_{, . . . ,N}_{_{M−1}} of the sums of the combinations comprising the resultant tensor [P]_{N}_{₁}_{,N}_{₂}_{, . . . ,N}_{ₘ}_{, . . . ,N}_{_{M−1}} and is connected to input 42 of the result extractor 13. Output 43 of the positioner 12 contains the positions [D]_{N}_{₁}_{,N}_{₂}_{, . . . ,N}_{ₘ}_{, . . . ,N}_{_{M−1}} of the sums of the combinations comprising the resultant tensor [P]_{N}_{₁}_{,N}_{₂}_{, . . . ,N}_{ₘ}_{, . . . ,N}_{_{M−1}} and is connected to input 44 of the result extractor 13. Output 45 of the recirculator 8 contains all the relevant values φ_{μ,ξ}, calculated previously as the products of the elements of the kernel by the elements χ of the input vectors and the sums of the combinations φ_{μ+ω}_{_{1,1}}_{-1,ξ}. This output is connected to input 46 of the summator set 10 and to input 47 of the result extractor 13. Output 48 of the result extractor 13 is the output for the resulting tensor of the system 1. It contains the resultant tensor [P]_{N}_{₁}_{,N}_{₂}_{, . . . ,N}_{ₘ}_{, . . . ,N}_{_{M−1}}.

The reducer 9 is presented in FIG. 3 and consists of a pattern set builder 14, a delay adjuster 15, and a number of channels adjuster 16.

The components of the reducer 9 are connected in the following way. Input 51 of the pattern set builder 14 is the input 28 of the reducer 9. It contains the entirety of the obtained commutator image [Y]_{N}_{₁}_{,N}_{₂}_{, . . . ,N}_{ₘ}_{, . . . ,N}_{_{M}}. Output 53 of the pattern set builder 14 is the output 34 of the reducer 9. It contains the tensor representing the reduced commutator. Output 55 of the pattern set builder 14 contains the entirety of the obtained preliminary matrix of combinations [Q]ₚ_{₁}_{-L,4} and is connected to input 56 of the delay adjuster 15. Input 57 of the delay adjuster 15 is the input 32 of the reducer 9. It contains current value of the operational delay S. Output 59 of the delay adjuster 15 contains delay adjusted matrix of combinations [Q]ₚ_{₁}_{-L,5} and is connected to input 60 of the number of channels adjuster 16. Input 61 of the number of channels adjuster 16 is the input 33 of the reducer 9. It contains current value of the number of channels σ. Output 63 of the number of channels adjuster 16 is the output 36 of the reducer 9. It contains channel number adjusted matrix of combinations [Q]ₚ_{₁}_{-L,5}.

In the embodiment, the delay adjuster 15 operates first and its output is supplied to the input of the number of channels adjuster 16. Alternatively, it is also possible to arrange the above components so that the number of channels adjuster 16 operates first and its output is supplied to the input of the delay adjuster 15.

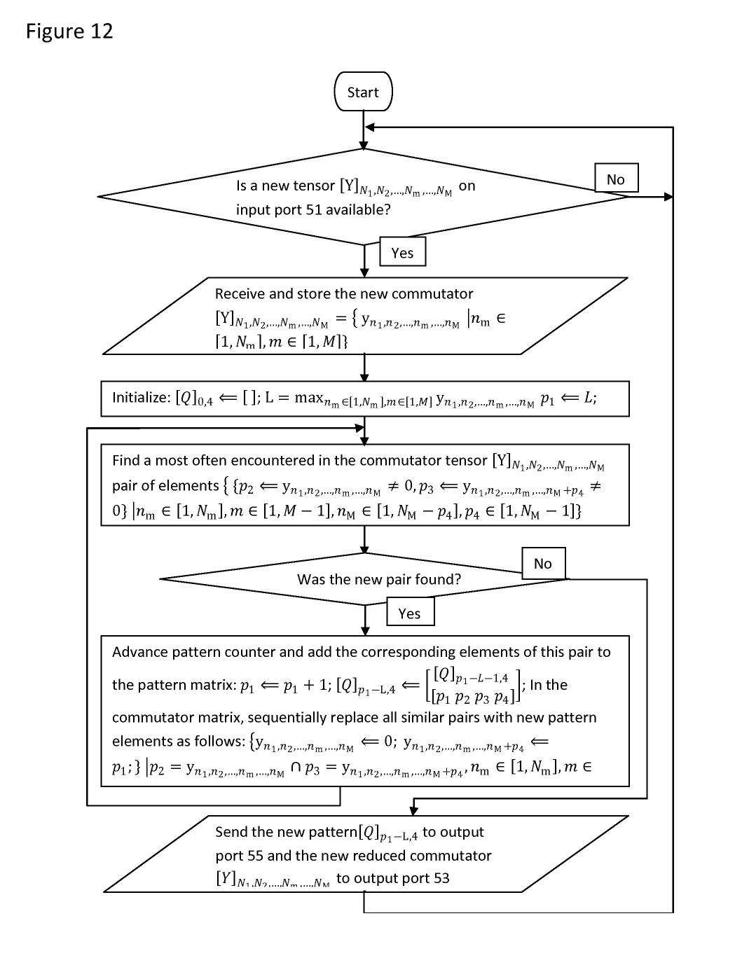

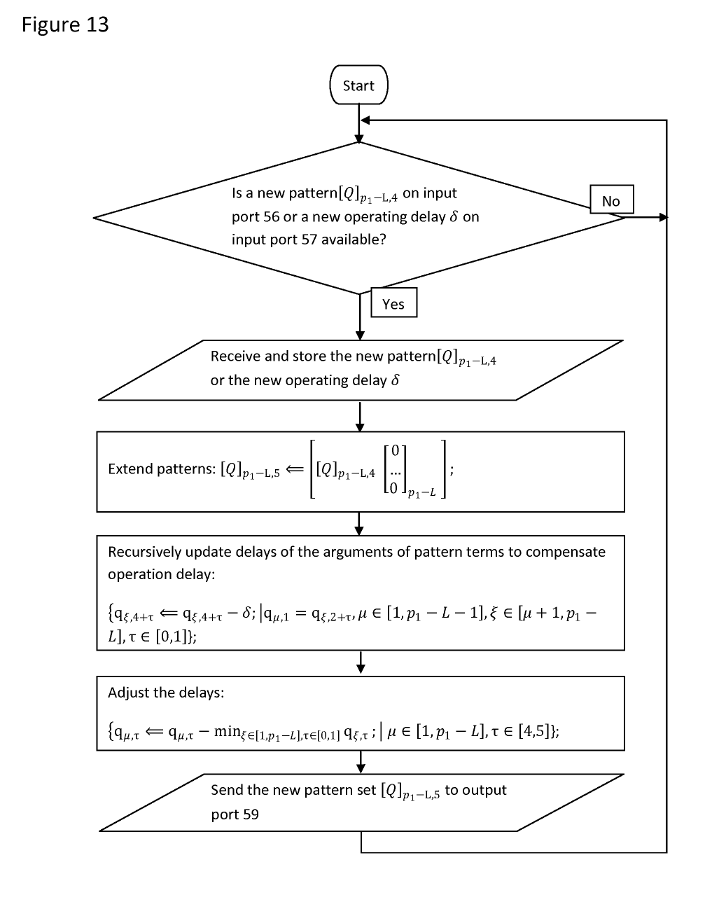

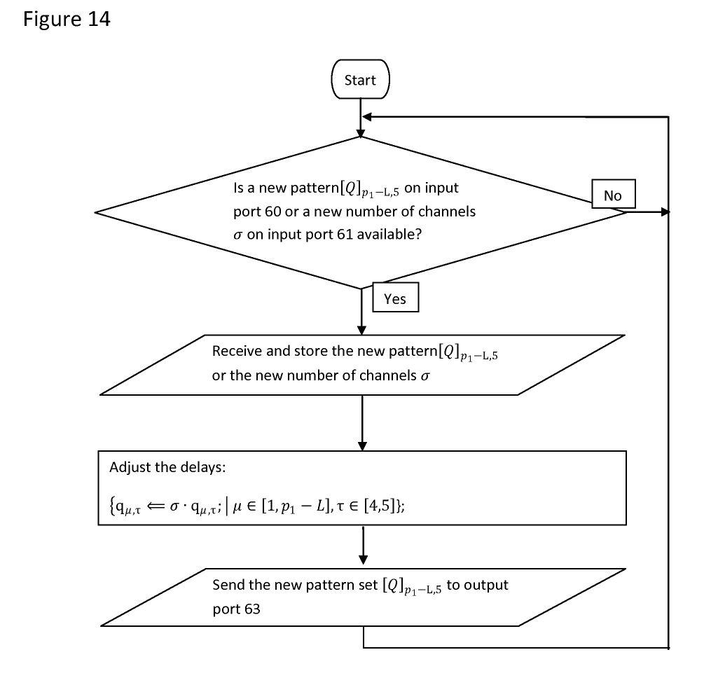

Functional algorithmic block-diagrams of the precision converter 5, the factorizing unit 6, the multiplier set 7, the summator set 10, the indexer 11, the positioner 12, the recirculator 8, the result extractor 13, the pattern set builder 14, the delay adjuster 15, and the number of channels adjuster 16 are present in FIGS. 4-14.

Fast Tensor Vector Multiplication

In accordance with the present invention the method for fast tensor-vector multiplication includes factoring an original tensor into a kernel and a commutator. The process of factorization of a tensor consists of the operations described below. A tensor is

[T]_{N}_{₁}_{,N}_{₂}_{, . . . ,N}_{ₘ}_{, . . . ,N}_{_{M}}={tₙ_{₁}_{,n}_{₂}_{, . . . n}_{ₘ}_{, . . . ,n}_{_{M}}|nₘε[1,Nₘ],mε[1,M]}

To obtain the kernel and the commutator, the tensor [T]_{N}_{₁}_{,N}_{₂}_{, . . . ,N}_{ₘ}_{, . . . ,N}_{_{M}} is factored according to the algorithm described below. The initial conditions are as follows.

The length of the kernel is set to 0:

L [symbol] 0;

Initially the kernel is an empty vector of length zero:

[U]_{L} [symbol] [ ];

The commutator image is the tensor [Y]_{N}_{₁}_{,N}_{₂}_{, . . . ,N}_{ₘ}_{, . . . ,N}_{_{M}} of dimensions equal to the dimensions of the tensor [T]_{N}_{₁}_{,N}_{₂}_{, . . . ,N}_{ₘ}_{, . . . ,N}_{_{M}}, all of whose elements are initially set equal to 0:

[Y]_{N}_{₁}_{,N}_{₂}_{, . . . ,N}_{ₘ}_{, . . . ,N}_{_{M}} [symbol] {0ₙ_{₁}_{,n}_{₂}_{, . . . n}_{ₘ}_{, . . . ,n}_{_{M}}|nₘε[1,Nₘ],mε[1,M]}

The indices n₁, n₂, . . . , nₘ, . . . , nₘ are initially set to 1:

n₁ [symbol] 1;n₂ [symbol] 1; . . . ;nₘ [symbol] 1; . . . ;n_{M} [symbol] 1;

n₁,n₂, . . . ,nₘ, . . . ,n_{M}nₘε[1,Nₘ],mε[1,M]

Then for each set of indices n₁, n₂, . . . , nₘ, . . . , n_{M}, where nₘ ε[1, Nₘ], mε[1, M], the following operations are carried out:

Step 1:

If the element tₙ_{₁}_{,n}_{₂}_{, . . . n}_{ₘ}_{, . . . ,n}_{_{M}} of the tensor [T]_{N}_{₁}_{,N}_{₂}_{, . . . ,N}_{ₘ}_{, . . . ,N}_{_{M}} is equal to 0, skip to step 3. Otherwise, go to step 2.

Step 2:

The length of the kernel is increased by 1:

L [symbol] L+1;

The element tₙ_{₁}_{,n}_{₂}_{, . . . ,n}_{ₘ}_{, . . . ,n}_{_{M}} of the tensor [T]_{N}_{₁}_{,N}_{₂}_{, . . . ,N}_{ₘ}_{, . . . ,N}_{_{M}} is added to the kernel:

$${[ U ]}_{L} [ \begin{matrix}{[ U ]}_{L - 1} \\ {t}_{{n}_{1} , {n}_{2} , … , {n}_{m} , … , {n}_{M}}\end{matrix} ] = [ \begin{matrix}{[ U ]}_{L - 1} \\ {u}_{L}\end{matrix} ] ;$$

The intermediate tensor [P]_{N}_{₁}_{,N}_{₂}_{, . . . ,N}_{ₘ}_{, . . . ,N}_{_{M}} is formed, containing values of 0 in those positions where elements of the tensor [T]_{N}_{₁}_{,N}_{₂}_{, . . . ,N}_{ₘ}_{, . . . ,N}_{_{M}} are not equal to the last obtained element of the kernel u_{L}, and in all other positions values of u_{L}:

[P]_{N}_{₁}_{,N}_{₂}_{, . . . ,N}_{ₘ}_{, . . . ,N}_{_{M}}={Pₙ_{₁}_{,n}_{₂}_{, . . . n}_{ₘ}_{, . . . ,n}_{_{M}}|nₘε[1,Nₘ],mε[1,M]} [symbol] u_{L}·0|[T]_{N}_{₁}_{,N}_{₂}_{, . . . ,N}_{ₘ}_{, . . . ,N}_{_{M}}−u_{L}|={u_{L}·0|t_{η}_{₁}_{,η}_{₂}_{, . . . η}_{ₘ}_{, . . . ,η}_{_{M}}−u_{L}∥nₘε[1,Nₘ],mε[1,M]}

All elements of the tensor [T]_{N}_{₁}_{,N}_{₂}_{, . . . ,N}_{ₘ}_{, . . . ,N}_{_{M}} equal to the newly obtained element of the kernel are set equal to 0:

[T]_{N}_{₁}_{,N}_{₂}_{, . . . ,N}_{ₘ}_{, . . . ,N}_{_{M}} [symbol] [T]_{N}_{₁}_{,N}_{₂}_{, . . . ,N}_{ₘ}_{, . . . ,N}_{_{M}}−[P]_{N}_{₁}_{,N}_{₂}_{, . . . ,N}_{ₘ}_{, . . . ,N}_{_{M}};

To the representation of the commutator, the tensor [Y]_{N}_{₁}_{,N}_{₂}_{, . . . ,N}_{ₘ}_{, . . . ,N}_{_{M}}, the tensor [P]_{N}_{₁}_{,N}_{₂}_{, . . . ,N}_{ₘ}_{, . . . ,N}_{_{M}} is added:

[Y]_{N}_{₁}_{,N}_{₂}_{, . . . ,N}_{ₘ}_{, . . . ,N}_{_{M}} [symbol] [Y]_{N}_{₁}_{,N}_{₂}_{, . . . ,N}_{ₘ}_{, . . . ,N}_{_{M}}+[P]_{N}_{₁}_{,N}_{₂}_{, . . . ,N}_{ₘ}_{, . . . ,N}_{_{M}}={yₙ_{₁}_{,n}_{₂}_{, . . . n}_{ₘ}_{, . . . ,n}_{_{M}}+pₙ_{₁}_{,n}_{₂}_{, . . . n}_{ₘ}_{, . . . ,b}_{_{M}}|nₘε[1,Nₘ],mε[1,M]};

Next go to step 3.

Step 3:

The index m is set equal to M:

m [symbol] M;

Next go to step 4.

Step 4:

The index nₘ is increased by 1:

nₘ [symbol] nₘ+1;

If nₘ≦Nₘ, go to step 1. Otherwise, go to step 5.

Step 5:

The index nₘ is set equal to 1:

nₘ [symbol] 1;

The index m is reduced by 1:

m [symbol] m−1;

If m≧1, go to step 4. Otherwise the process is terminated.

The results of the process described herein for the factorization of the tensor [T]_{N}_{₁}_{,N}_{₂}_{, . . . ,N}_{ₘ}_{, . . . ,N}_{_{M}} are the kernel [U]_{L} and the commutator image [Y]_{N}_{₁}_{,N}_{₂}_{, . . . ,N}_{ₘ}_{, . . . ,N}_{_{M}}, which is the tensor contraction of the commutator [Z]_{N}_{₁}_{,N}_{₂}_{, . . . ,N}_{ₘ}_{, . . . ,N}_{_{M}}^{,L} with the auxiliary vector

$${[ γ ]}_{L} = [ \begin{matrix}1 \\ 2 \\ … \\ 1 \\ … \\ L - 1 \\ L\end{matrix} ] {\text{:} [ Y ]}_{{N}_{1} , {N}_{2} , … {N}_{m} , … , {N}_{M}} = \{ {\sum }_{l = 1}^{L} {z}_{{n}_{1} , {n}_{2} , … , {n}_{m} , … , {n}_{M} , 1} \cdot l \vert {n}_{m} ∈ [ 1 , {N}_{m} ] , m ∈ [ 1 , M ] \}$$

Here, a tensor

[T]_{N}_{₁}_{,N}_{₂}_{, . . . ,N}_{ₘ}_{, . . . ,N}_{_{M}}={tₙ_{₁}_{,n}_{₂}_{, . . . n}_{ₘ}_{, . . . ,n}_{_{M}}|nₘε[1,Nₘ],mε[1,M]}

of dimensions Πₘ₌₁^{M}Nₘ containing L≦Πₘ₌₁^{M}Nₘ distinct nonzero elements. The kernel

$${[ U ]}_{L} = [ \begin{matrix}{u}_{1} \\ … \\ {u}_{1} \\ … \\ {u}_{L}\end{matrix} ]$$

is obtained, containing all the distinct nonzero elements of the tensor [T]_{N}_{₁}_{,N}_{₂}_{, . . . ,N}_{ₘ}_{, . . . ,N}_{_{M}}.

From the same tensor [T]_{N}_{₁}_{,N}_{₂}_{, . . . ,N}_{ₘ}_{, . . . ,N}_{_{M}} a new intermediate tensor

[Y]_{N}_{₁}_{,N}_{₂}_{, . . . ,N}_{ₘ}_{, . . . ,N}_{_{M}}={yₙ_{₁}_{,n}_{₂}_{, . . . n}_{ₘ}_{, . . . ,n}_{_{M}}|nₘε[1,Nₘ],mε[1,M]}

was generated, with the same dimensions Πₘ₌₁^{M}Nₘ as the original tensor [T]_{N}_{₁}_{,N}_{₂}_{, . . . ,N}_{ₘ}_{, . . . ,N}_{_{M}} and with each element equal either to 0, or to the index of that element of the kernel [U]_{L} which has the same value as this element of the tensor [T]_{N}_{₁}_{,N}_{₂}_{, . . . ,N}_{ₘ}_{, . . . ,N}_{_{M}}. The tensor [Y]_{N}_{₁}_{,N}_{₂}_{, . . . ,N}_{ₘ}_{, . . . ,N}_{_{M}} was obtained by replacing each nonzero element tₙ_{₁}_{,n}_{₂}_{, . . . ,n}_{ₘ}_{, . . . ,n}_{_{M}} of the tensor [T]_{N}_{₁}_{,N}_{₂}_{, . . . ,N}_{ₘ}_{, . . . ,N}_{_{M}} by the index 1 of the equivalent element uₗ of the vector [U]_{L}.

From the resulting intermediate tensor [Y]_{N}_{₁}_{,N}_{₂}_{, . . . ,N}_{ₘ}_{, . . . ,N}_{_{M}} the commutator

[Z]_{N}_{₁}_{,N}_{₂}_{, . . . ,N}_{ₘ}_{, . . . ,N}_{_{M}}={zₙ_{₁}_{,n}_{₂}_{, . . . n}_{ₘ}_{, . . . ,n}_{_{M}},l|nₘε[1,Nₘ],mε[1,M],lε[1,L]}

as a tensor of rank M+1, was obtained by replacing every nonzero element yₙ_{₁}_{,n}_{₂}_{, . . . n}_{ₘ}_{, . . . ,n}_{_{M}} of the tensor [Y]_{N}_{₁}_{,N}_{₂}_{, . . . ,N}_{ₘ}_{, . . . ,N}_{_{M}} by a vector of length L whose elements are all 0 if yₙ_{₁}_{,n}_{₂}_{, . . . n}_{ₘ}_{, . . . ,n}_{_{M}}=0, or which has one unity element in the position corresponding to the nonzero value yₙ_{₁}_{,n}_{₂}_{, . . . ,n}_{ₘ}_{, . . . ,n}_{_{M}} and L−1 zero elements in all other positions. The resulting commutator may be represented as:

$${[ Z ]}_{{N}_{1} , {N}_{2} , … , {N}_{m} , … , {N}_{M} , L} = \{ \{ \begin{matrix}{[ 0 … 0 ]}_{L} , & for {y}_{{n}_{1} , {n}_{2} , … , {n}_{m} , … , {n}_{M}} = 0 \\ \begin{matrix}{[ 0 … 0 ]}_{{y}_{{n}_{1} , {n}_{2} , … , {n}_{m} , … , {n}_{M}} - 1} \\ {1 [ 0 … 0 ]}_{L - {y}_{{n}_{1} , {n}_{2} , … , {n}_{m} , … , {n}_{M}}} ,\end{matrix} & for {y}_{{n}_{1} , {n}_{2} , … , {n}_{m} , … , {n}_{M}} > 0\end{matrix} \vert {n}_{m} ∈ [ 1 , {N}_{m} ] , m ∈ [ 1 , M ] \}$$

The tensor [T]_{N}_{₁}_{,N}_{₂}_{, . . . ,N}_{ₘ}_{, . . . ,N}_{_{M}} can now be obtained as a convolution of the commutator [Z]_{N}_{₁}_{,N}_{₂}_{, . . . ,N}_{ₘ}_{, . . . ,N}_{_{M}}^{,L} with the kernel [U]_{L}:

[T]_{N}_{₁}_{,N}_{₂}_{, . . . ,N}_{ₘ}_{, . . . ,N}_{_{M}}=[Z]_{N}_{₁}_{,N}_{₂}_{, . . . ,N}_{ₘ}_{, . . . ,N}_{_{M}},L·[U]_{L}={Σₗ₌₁^{l=L}zₙ_{₁}_{,n}_{₂}_{, . . . n}_{ₘ}_{, . . . ,n}_{_{M}},l·uₗ·|nₘε[1,Nₘ],mε[1,M]}

Further in the inventive method, the kernel [U]_{L} obtained by the factoring of the original tensor [T]_{N}_{₁}_{,N}_{₂}_{, . . . ,N}_{ₘ}_{, . . . ,N}_{_{M}}, is multiplied by the vector [V]_{N}_{ₘ}^{t}, and thereby a matrix [P]_{L,N} is obtained as follows. The tensor [T]_{N}_{₁}_{,N}_{₂}_{, . . . ,N}_{ₘ}_{, . . . ,N}_{_{M}} is written as the product of the commutator

[Z]_{N}_{₁}_{,N}_{₂}_{, . . . ,N}_{ₘ}_{, . . . ,N}_{_{M}},L={zₙ_{₁}_{,n}_{₂}_{, . . . n}_{ₘ}_{, . . . ,n}_{_{M}},l|nₘε[1,Nₘ],mε[1,M],mε[1,M],lε[1,L]}

and the kernel

$${[ U ]}_{L} = [ \begin{matrix}{u}_{1} \\ … \\ {u}_{1} \\ … \\ {u}_{L}\end{matrix} ] {\text{:} \\ [ T ]}_{{N}_{1} , {N}_{2} , … , {N}_{m} , … , {N}_{M}} = {[ Z ]}_{{N}_{1} , {N}_{2} , … , {N}_{m} , … , {N}_{M} , L} \cdot {[ U ]}_{L} = \{ {\sum }_{l = 1}^{l = L} {z}_{{n}_{1} , {n}_{2} , … , {n}_{m} , … , {n}_{M} , 1} \cdot {u}_{1} \vert {n}_{m} ∈ [ 1 , {N}_{m} ] , m ∈ [ 1 , M ] \}$$

Then the product of the tensor [T]_{N}_{₁}_{,N}_{₂}_{, . . . ,N}_{ₘ}_{, . . . ,N}_{_{M}} and the vector [V]_{N}_{ₘ} may be written as:

$${[ R ]}_{{N}_{1} , {N}_{2} , … , {N}_{m - 1} , {N}_{m + 1} , … , {N}_{M}} = {[ T ]}_{{N}_{1} , {N}_{2} , … , {N}_{m} , … , {N}_{M}} \cdot {[ V ]}_{{N}_{m}} = ( {[ Z ]}_{{N}_{1} , {N}_{2} , … , {N}_{m} , … , {N}_{M} , L} \cdot {[ U ]}_{L} ) \cdot {[ V ]}_{{N}_{m}} = \{ {\sum }_{n = 1}^{{N}_{m}} {v}_{n} \cdot {\sum }_{l = 1}^{L} {z}_{{n}_{1} , {n}_{2} , … , {n}_{m - 1} , n , {n}_{m + 1} , … , {n}_{M} , 1} \cdot {u}_{1} \vert {n}_{k} ∈ [ 1 , {N}_{k} ] , k ∈ \{ [ 1 , m - 1 ] , [ m + 1 , M ] \} \} = \{ {\sum }_{n = 1}^{{N}_{m}} ( {\sum }_{l = 1}^{L} {z}_{{n}_{1} , {n}_{2} , … , n , {n}_{m - 1} , {n}_{m + 1} , … , {n}_{M} , 1} \cdot {u}_{1} ) \cdot {v}_{n} \vert {n}_{k} ∈ [ 1 , {N}_{k} ] , k ∈ \{ [ 1 , m - 1 ] , [ m + 1 , M ] \} \} = \{ {\sum }_{n = 1}^{{N}_{m}} {\sum }_{l = 1}^{L} {z}_{{n}_{1} , {n}_{2} , … , n , {n}_{m + 1} , … , {n}_{M} , 1} \cdot {u}_{1} \cdot {v}_{n} \vert {n}_{k} ∈ [ 1 , {N}_{k} ] , k ∈ \{ [ 1 , m - 1 ] , [ m + 1 , M ] \} \} = \{ {\sum }_{n = 1}^{{N}_{m}} {\sum }_{l = 1}^{L} {z}_{{n}_{1} , {n}_{2} , … , {n}_{m - 1} , n , {n}_{m + 1} , … , {n}_{M} , 1} \cdot ( {u}_{1} \cdot {v}_{n} ) \vert {n}_{k} ∈ [ 1 , {N}_{k} ] , k ∈ \{ [ 1 , m - 1 ] , [ m + 1 , M ] \} \}$$

In this expression each nested sum contains the same coefficient (uₗ·vₙ) which is an element of the matrix [P]_{L,N} which is the product of the kernel [U]_{L} and the transposed vector [V]_{N}_{ₘ}:

[P]_{L,N}=[U]_{L}·[V]_{N}_{ₘ}^{t}

Then elements and sums of elements of the matrix as defined by the commutator are summated, and thereby a resulting tensor which corresponds to a product of the original tensor and the vector is obtained as follows.

The product of the tensor [T]_{N}_{₁}_{,N}_{₂}_{, . . . ,N}_{ₘ}_{, . . . ,N}_{_{M}} and the vector [V]_{N} may be written as:

[R]_{N}_{₁}_{,N}_{₂}_{, . . . ,N}_{_{m−1}}_{,N}_{ₘ₊₁}_{, . . . ,N}_{_{M}}=[T]_{N}_{₁}_{,N}_{₂}_{, . . . ,N}_{ₘ}_{, . . . ,N}_{_{M}}·[V]_{N}_{ₘ}={Σₙ₌₁^{N}^{ₘ}Σₗ₌₁^{L}zₙ_{₁}_{,n}_{₂}_{, . . . n}_{_{m−1}}_{,n,n}_{ₘ₊₁}_{, . . . ,n}_{_{M}}_{,l}·(uₗ·vₙ)|nₖε[1,Nₖ],kε{[1,m−1],[m+1,M]}}=Σₙ₌₁^{N}^{ₘ}Σₗ₌₁^{L}zₙ_{₁}_{,n}_{₂}_{, . . . ,n}_{_{m−1}}_{,n,n}_{ₘ₊₁}_{, . . . ,n}_{_{M}}_{,l}·p_{l,n}|nₖε[1,Nₖ],kε{[1,m−1],[m+1,M]}}

Thus the multiplication of a tensor by a vector of length Nₘ may be carried out in two steps. First, the matrix is obtained which contains the product of each element of the original vector and each element of the kernel [T]_{N}_{₁}_{,N}_{₂}_{, . . . ,N}_{ₘ}_{, . . . ,N}_{_{M}} of the initial tensor. Then each element of the resulting tensor [R]_{N}_{₁}_{,N}_{₂}_{, . . . ,N}_{_{m−1}}_{,N}_{ₘ₊₁}_{, . . . ,N}_{_{M}} calculated as the tensor contraction of the commutator with the matrix obtained in the first step. This sequence means that all multiplication operations are carried out in the first step, and their maximum number is equal to the product of the length Nₘ of the original vector and the number L of distinct nonzero elements of the original tensor [T]_{N}_{₁}_{,N}_{₂}_{, . . . ,N}_{ₘ}_{, . . . ,N}_{_{M}} rather than the number of elements of the original tensor [T]_{N}_{₁}_{,N}_{₂}_{, . . . ,N}_{ₘ}_{, . . . ,N}_{_{M}}, which is equal to Πₖ₌₁^{M}Nₖ, as in the case of multiplication without factorization of the tensor. All addition operations are carried out in the second step, and their maximal number is

$$\frac{{N}_{m} - 1}{{N}_{m}} \cdot {\prod }_{k = 1}^{M} {N}_{k} .$$

Thus the ratio of the number of operations with a method using the decomposition of the vector into a kernel and a commutator to the number of operations required with a method that does not include such a decomposition is

$${Cm}_{+} \leq \frac{\frac{{N}_{m} - 1}{{N}_{m}} {\prod }_{k = 1}^{M} {N}_{k}}{\frac{{N}_{m} - 1}{{N}_{m}} {\prod }_{k = 1}^{M} {N}_{k }} = 1$$

for addition and

$${Cm}_{*} \leq \frac{{N}_{m} \cdot L}{{\prod }_{k = 1}^{M} {N}_{k}} = \frac{L}{( {\prod }_{k = 1}^{m - 1} {N}_{k} ) \cdot ( {\prod }_{k = m + 1}^{M} {N}_{k} )}$$

for multiplication.

The inventive method can include rounding of elements of the original tensor to a desired precision and obtaining the original tensor with the rounded elements, and the factoring can include factoring the original tensor with the rounded elements into the kernel and the commutator as follows.

For the original tensor [\tilde{T}]_{N}_{₁}_{,N}_{₂}_{, . . . ,N}_{ₘ}_{, . . . ,N}_{_{M}}={\tilde{t}ₙ_{₁}_{,n}_{₂}_{, . . . n}_{ₘ}_{, . . . ,n}_{_{M}}|nₘε[1,Nₘ],mε[1,M]}, the elements of the tensor [\tilde{T}]_{N}_{₁}_{,N}_{₂}_{, . . . ,N}_{ₘ}_{, . . . ,N}_{_{M}} are rounded to a given precision E as following:

$${[ T ]}_{{N}_{1} , {N}_{2} , … , {N}_{m} , … , {N}_{M}} = \{ {t}_{{n}_{1} , {n}_{2} , … , {n}_{m} , … , {n}_{M}} \vert {n}_{m} ∈ [ 1 , {N}_{m} ] , m ∈ [ 1 , M ] \} \{ ɛ \cdot round ( \frac{{\tilde{t}}_{{n}_{1} , {n}_{2} , … , {n}_{m} , … , {n}_{M}}}{ɛ} ) \vert {n}_{m} ∈ [ 1 , {N}_{m} ] , m ∈ [ 1 , M ] \}$$

Still another feature of the present invention resides in that the factoring of the original tensor includes factoring into the kernel which contains kernel elements that are different from one another. This can be seen from the process of obtaining intermediate tensor in the recursive process of building the kernel and the commutator, where the said intermediate tensor [P]_{N}_{₁}_{,N}_{₂}_{, . . . ,N}_{ₘ}_{, . . . ,N}_{_{M}} is defined as: [P]_{N}_{₁}_{,N}_{₂}_{, . . . ,N}_{ₘ}_{, . . . ,N}_{_{M}}={pₙ_{₁}_{,n}_{₂}_{, . . . ,n}_{ₘ}_{, . . . ,n}_{_{M}}|nₘε[1,Nₘ],mε[1,M]} [symbol] u_{L}·0|[T]_{N}_{₁}_{,N}_{₂}_{, . . . ,N}_{ₘ}_{, . . . ,N}_{_{M}}₋ᵤ_{_{L}}|={u_{L}·0|t_{η}_{₁}_{,η}_{₂}_{, . . . ,η}_{ₘ}_{, . . . η}_{_{M}}₋ᵤ_{_{L}}∥nₘε[1,Nₘ],mε[1,M]}, and therefore all elements equal to the last obtained element of the kernel are replaced with zeros and are not present at the next iteration.

Thereby, the multiplying includes only multiplying the kernel which contains the different kernel elements.

In the method of the present invention as the commutator [Z]_{N}_{₁}_{,N}_{₂}_{, . . . ,N}_{ₘ}_{, . . . ,N}_{_{M}}_{,L}, a commutator image [Y]_{N}_{₁}_{,N}_{₂}_{, . . . ,N}_{ₘ}_{, . . . ,N}_{_{M}} can be used, in which indices of elements of the kernel are located at positions of corresponding elements of the original tensor. The commutator image [Y]_{N}_{₁}_{,N}_{₂}_{, . . . ,N}_{ₘ}_{, . . . ,N}_{_{M}} can be obtained from the commutator [Z]_{N}_{₁}_{,N}_{₂}_{, . . . ,N}_{ₘ}_{, . . . ,N}_{_{M}}_{,L}={zₙ_{₁}_{,n}_{₂}_{, . . . ,n}_{ₘ}_{, . . . ,n}_{_{M}}_{,l}|nₘε[1,Nₘ],mε[1,M],lε[1, L]} by performing the tensor contraction of the commutator [Z]_{N}_{₁}_{,N}_{₂}_{, . . . ,N}_{ₘ}_{, . . . ,N}_{_{M}}_{,L} with the auxiliary vector

$$\begin{matrix} {[ ϒ ]}_{L} = [ \begin{matrix}1 \\ 2 \\ … \\ l \\ … \\ L - 1 \\ L\end{matrix} ] \text{:} & \\ {[ Y ]}_{{N}_{1} , {N}_{2} , … , {N}_{m} , … , {N}_{M}} = \{ {\sum }_{l = 1}^{L} {z}_{{n}_{1} , {n}_{2} , … , {n}_{m} , … , {n}_{M} , 1} \cdot l \vert {n}_{m} ∈ [ 1 , {N}_{m} ] , n ∈ [ 1 , M ] \} & \end{matrix}$$

In this case the product of the tensor [T]_{N}_{₁}_{,N}_{₂}_{, . . . ,N}_{ₘ}_{, . . . ,N}_{_{M}} and the vector [V]_{N} may be written as:

[R]_{N}_{₁}_{,N}_{₂}_{, . . . ,N}_{_{m−1}}_{,N}_{ₘ₊₁}_{, . . . ,N}_{_{M}}=[T]_{N}_{₁}_{,N}_{₂}_{, . . . ,N}_{ₘ}_{, . . . ,N}_{_{M}}·[V]_{N}_{ₘ}=[l(Y)]_{N}_{₁}_{,N}_{₂}_{, . . . ,N}_{ₘ}_{, . . . ,N}_{_{M}}·[V]_{N}_{ₘ}

This representation of the commutator can be used for the process of tensor factoring and for the process of building fast tensor-vector multiplication computational structures and systems.

The summating can include summating on a priority basis of those pairs of elements whose indices in the commutator image are encountered most often and thereby producing the sums when the pair is encountered for the first time, and using the obtained sum for all remaining similar pairs of elements.

It can be carried out with the aid of a preliminary synthesized computation control structure presented in the embodiment in a matrix form. This structure, along with the input vector, can be used as an input data for a computer algorithm for carrying out a tensor-vector multiplication. The same preliminary synthesized computation control structure can be further used for synthesis a block diagram of a system to perform multiplication of a tensor by a vector.

The computation control structure synthesis process is described below as following. The four objects—the kernel [U]_{L}, the commutator image [Y]_{N}_{₁}_{,N}_{₂}_{, . . . ,N}_{ₘ}_{, . . . ,N}_{_{M}}, a parameter named “operational delay” and a parameter named “number of channels” comprise the initial input of the process of constructing a computational structure to perform one iteration of multiplication by a factored tensor. An operational delay of δ indicates the number of system clock cycles required to perform the addition of two arguments in the computational platform for which a computational system is described. The number of channels σ determines the number of distinct independent vectors that compose the vector that is multiplied by the factored tensor. Then for N elements, the elements {M|Mε[1, ∞]} of channel K, where 1≦K≦N, are resent in the resultant vector as elements

{K+(M−1)·N|Kε[1,N],Mε[0,∞]}.

The process of constructing a description of the computational system for performing one iteration of multiplication by a factored tensor contains the steps described below.

For a given kernel [U]_{L}, commutator tensor [Y]_{N}_{₁}_{,N}_{₂}_{, . . . ,N}_{ₘ}_{, . . . ,N}_{_{M}}, operational delay δ and number of channels σ, the initialization of this process consists of the following steps.

The empty matrix

[Q]_{0,4} [symbol] [ ];

is initialized, to which the combinations

[P]₄=[p₁p₂p₃p₄]

are to be added. These combinations are represented by vectors of length 4. In every such vector the first element p₁ is the identifier or index of the combination. These numbers are an extension of the numeration of elements of the kernel. Thus the index of the first combination is L+1, and each successive combination has an index one more than the preceding combination:

q_{1,1}=L+1,q_{n,1}=q_{n-1,1}+1,n>1

The second element p₂ of each combination is an element of the subset

{[Y]ₙ_{₁}_{,N}_{₂}_{, . . . ,N}_{ₘ}_{, . . . ,N}_{_{M}}|n₁ε[1,N₁−p₄−1],p₄ε[1,N₁−1]}

of elements of the commutator tensor [Y]_{N}_{₁}_{,N}_{₂}_{, . . . ,N}_{ₘ}_{, . . . ,N}_{ₘ} as shown below.

The third element p₃ of the combination represents an element of the subset

{[Y]ₙ_{₁}_{,N}_{₂}_{, . . . ,N}_{ₘ}_{, . . . ,N}_{_{M}}|n₁ε[p₄,N₁],p₄ε[1,N₁−1]}

of elements of the commutator tensor [Y]_{N}_{₁}_{,N}_{₂}_{, . . . ,N}_{ₘ}_{m . . . ,N}_{ₘ} as shown below.

The fourth element p₄ ε[1, N₁−1] of the combination represents the distance along the dimension N₁ between the elements equal to p₂ and p₃ in the commutator tensor [Y]_{N}_{₁}_{,N}_{₂}_{, . . . ,N}_{ₘ}_{, . . . ,N}_{ₘ}.

The index of the first element of the combination is set equal to the dimension of the kernel:

p₁ [symbol] L;

Here ends the initialization and begins the iterative section of the process of constructing a description of the computational structure.

Step 1:

The variable containing the number of occurrences of the most frequent combination is set equal to 0:

α [symbol] 0;

Go to step 2.

Step 2:

The index of the second element is set equal to 1:

p₂ [symbol] 1;

Go to step 3.

Step 3:

The index of the third element of the combination is set equal to 1:

p₃ [symbol] 1;

Go to step 4.

Step 4:

The index of the fourth element is set equal to 1:

p₄ [symbol] 1;

Go to step 5.

Step 5:

The variable containing the number of occurrences of the combination is set equal to 0:

β [symbol] 0;

The indices n₁, n₂, . . . , nₘ, . . . , n_{M} are set equal to 1:

n₁ [symbol] 1;n₂ [symbol] 1; . . . ;nₘ [symbol] 1; . . . ;n_{M} [symbol] 1;

Go to step 6.

Step 6:

The elements of the commutator tensor [Y]_{N}_{₁}_{,N}_{₂}_{, . . . ,N}_{ₘ}_{, . . . ,N}_{_{M}} form the vector

[Θ]N_{M}={θ_{η}|ηε[1,N_{M}]} [symbol] {yₙ_{₁}_{,n}_{₂}_{, . . . ,n}_{ₘ}_{, . . . ,η}|ηε[1,N_{M}]}

Go to step 7.

Step 7:

If θₙ_{_{M}}≠p₂ or θₙ_{_{M}}₊ₚ_{₄}≠p₃, skip to step 9. Otherwise, go to step 8.

Step 8:

The variable containing the number of occurrences of the combination is increased by 1:

β [symbol] β+1;

The elements θₙ_{_{M}} and θₙ_{_{M}}₊ₚ_{₄} of the vector [Θ]_{N}_{ₘ} are set equal to 0:

θn_{M} [symbol] 0;

θₙ_{_{M}}₊ₚ_{₄} [symbol] 0;

If β≦αα, skip to step 10. Otherwise, go to step 9.

Step 9:

The variable containing the number of occurrences of the most frequently occurring combination is set equal to the number of occurrences of the combination:

α [symbol] β;

The most frequently occurring combination is recorded:

[P]₄ [symbol] [p₁+1p₂p₃p₄];

Go to step 10.

Step 10:

The index m is set equal to M:

m [symbol] M;

Go to step 11.

Step 11:

The index nₘ is increased by 1:

nₘ [symbol] nₘ+1;

If nₘ≦Nₘ, then if m=M, go to step 7, and if m<M, go to step 6. If nₘ>Nₘ, go to step 12.

Step 12:

The index nₘ is set equal to 1:

nₘ [symbol] 1;

The index m is decreased by 1:

m [symbol] m−1;

If m≧1,go to step 11. Otherwise, go to step 13.

Step 13:

The index of the fourth element of the combination is increased by 1:

p₄ [symbol] p₄+1;

If p₄<N_{M}, go to step 4. Otherwise go to step 14.

Step 14:

The index of the third element of the combination is increased by 1:

p₃ [symbol] p₃+1;

If p₃≦p₁, go to step 3. Otherwise, go to step 15.

Step 15:

The index of the second element of the combination is increased by 1:

p₂ [symbol] p₂+1;

If p₂ Pₜ, go to step 2. Otherwise, go to step 16.

Step 16:

If a>0, go to step 17. Otherwise, skip to step 18.

Step 17:

The index of the first element is increased by 1:

p₁ [symbol] p₁+1;

To the matrix of combinations the most frequently occurring combination is added:

$${[ Q ]}_{{p}_{1} - L , 4} [ \begin{matrix}{[ Q ]}_{{p}_{1} - L - 1 , 4} \\ {[ P ]}_{4}\end{matrix} ] ;$$

Go to step 18.

Step 18:

The indices n₁, n₂, . . . ,nₘ, . . . ,nₘ are set equal to 1:

n₁ [symbol] 1;n₂ [symbol] 1; . . . ;nₘ [symbol] 1; . . . ;n_{M} [symbol] 1;

Go to step 19.

Step 19:

If yₙ_{₁}_{,n}_{₂}_{, . . . ,n}_{ₘ}_{, . . . ,n}_{_{M}}≠p₂ or yₙ_{₁}_{,n}_{₂}_{, . . . ,n}_{ₘ}_{, . . . ,n}_{_{M}}₊ₚ_{₄}≠p₃, skip to step 21. Otherwise, go to step 20.

Step 20:

The element yₙ_{₁}_{,n}_{₂}_{, . . . ,n}_{ₘ}_{, . . . ,n}_{_{M}} of the commutator tensor [Y]y_{N}_{₁}_{,N}_{₂}_{, . . . ,N}_{ₘ}_{, . . . ,N}_{_{M}} is set equal to 0:

yₙ_{₁}_{,n}_{₂}_{, . . . ,n}_{ₘ}_{, . . . ,n}_{_{M}} [symbol] 0;

The element yₙ_{₁}_{,n}_{₂}_{, . . . ,n}_{ₘ}_{, . . . ,n}_{_{M}} of the commutator tensor [Y]_{N}_{₁}_{,N}_{₂}_{, . . . ,N}_{ₘ}_{, . . . ,N}_{_{M}} is set equal to the current value of the index of the first element of the combination:

yₙ_{₁}_{,n}_{₂}_{, . . . ,n}_{ₘ}_{, . . . ,n}_{_{M}} [symbol] p₁;

Go to step 21.

Step 21:

The index m is set equal to M:

m [symbol] M;

Go to step 22.

Step 22:

The index nₘ is increased by 1:

nₘ [symbol] nₘ+1;

If m<M and nₘ≦Nₘ or m=M and nₘ≦Nₘ−p₄, then go to step 19. Otherwise, go to step 23.

Step 23:

The index nₘ is set equal to 1:

nₘ [symbol] 1;

The index m is decreased by 1:

m [symbol] m−1;

If m≧1, go to step 22. Otherwise, go to step 24.

Step 24:

At the end of each row of the matrix of combinations, append a zero element:

$${[ Q ]}_{{p}_{1} - L , 5} [ {{[ Q ]}_{{p}_{1} - L , 4} [ \begin{matrix}0 \\ … \\ 0 \\ … \\ 0\end{matrix} ]}_{{p}_{1} - L} ] ;$$

Go to step 25.

Step 25:

The variable fl is set equal to the number p₁−L of rows in the resulting matrix of combinations

[Q]ₚ_{₁}_{-L,5}:

Ω [symbol] p₁−L;

Go to step 26.

Step 26:

The index μ is set equal to 1:

μ [symbol] 1;

Go to step 27.

Step 27:

The index is set equal to one more than the index μ:

ξ [symbol] μ+1;

Go to step 28.

Step 28:

If p_{μ,1}≠q_{ξ,2}, skip to step 30. Otherwise, go to step 29.

Step 29:

The element q_{ξ,4} of the matrix of combinations is decreased by the value of the operational delay δ:

q_{ξ,4} [symbol] q_{ξ,4}−δ;

Go to step 30.

Step 20:

If p_{μ, 1}≠q_{ξ,3}, skip to step 32. Otherwise, go to step 31.

Step 31:

The element q_{ξ,5} of the matrix of combinations is decreased by the value of the operational delay δ:

q_{ξ,5} [symbol] q_{ξ,5}−δ;

Go to step 32.

Step 32:

The index is increased by 1:

ξ [symbol] ξ+1;

If ξ≦Ω, go to step 28. Otherwise go to step 33.

Step 33:

The index μ is increased by 1:

μ [symbol] μ+1;

If μ<Ω, go to step 27. Otherwise go to step 34.

Step 34:

The cumulative operational delay of the computational scheme is set equal to 0:

Δ [symbol] 0;

The index μ is set equal to 1:

μ [symbol] 1;

Go to step 35.

Step 35:

The index ξ is set equal to 4:

ξ [symbol] 4;

Go to step 36.

Step 36:

If Δ>q_{μ,86}, skip to step 38. Otherwise, go to step 37.

Step 37:

The value of the cumulative operational delay of the computational scheme is set equal to the value of q_{μ,ξ}:

Δ [symbol] q_{μ,ξ};

Go to step 38.

Step 38:

The index n is increased by 1:

ξ [symbol] ξ+1;

If ξ≦5, go to step 36. Otherwise, go to step 39.

Step 39:

The index μ is increased by 1:

μ [symbol] μ+1;

If μ<Ω, go to step 35. Otherwise, go to step 40.

Step 40:

To each element of the two rightmost columns of the matrix of combinations, add the calculated value of the cumulative operational delay of the computational scheme:

{q_{μ,ξ} [symbol] q_{μ,ξ}+Δ|με[1,Ω],ξε[4,5]};

Go to step 41.

Step 41:

After step 24, any subset {yₙ_{₁}_{,n}_{₂}_{, . . . ,n}_{ₘ}_{, . . . ,n}_{_{M}}_{γ}|mε[1,M−1], γΣ[1, N_{M}]} of elements of the commutator tensor [Y]_{N}_{₁}_{,N}_{₂}_{, . . . ,N}_{ₘ}_{, . . . ,N}_{_{M}} contains no more than one nonzero element. These elements contain the result of the constructed computational scheme represented by the matrix of combinations [Q]_{Ω,5}. Moreover, the position of each such element along the dimension n_{M} determines the delay in calculating each of the elements relative to the input and each other.

The tensor [D]_{N}_{₁}_{,N}_{₂}_{, . . . ,N}_{ₘ}_{, . . . ,N}_{_{M−1}} of dimension (N₁, N₂, . . . , Nₘ, . . . , N_{M-1}), containing the delay in calculating each corresponding element of the resultant may be found using the following operation:

[D]_{N}_{₁}_{,N}_{₂}_{, . . . ,N}_{ₘ}_{, . . . ,N}_{_{M−1}}={dₙ_{₁}_{,n}_{₂}_{, . . . ,n}_{ₘ}_{, . . . ,n}_{_{M−1}}|mε[1,M−1],nₘε[1,N_{M}]} [symbol] {Σ_{γ=1}ⁿ^{_{M−1}}γ·(1−0|yₙ_{₁}_{,n}_{₂}_{, . . . ,n}_{ₘ}_{·γ}|)|mε[1,M−1],n_{M}ε[1,N_{M}]}

The indices of the combinations comprising the resultant tensor [R]_{N}_{₁}_{,N}_{₂}_{, . . . ,N}_{ₘ}_{, . . . ,N}_{_{m−1}} of dimensions (N₁, N₂, . . . , Nₘ, . . . , Nₘ₋₁) may be determined using the following operation:

[R]_{N}_{₁}_{,N}_{₂}_{, . . . ,N}_{ₘ}_{, . . . ,N}_{_{M−1}}={rₙ_{₁}_{,n}_{₂}_{, . . . ,n}_{ₘ}_{, . . . ,n}_{_{M−1}}|mε[1,M−1],nₘε[1,N_{M}]} [symbol] {yn₁,n₂, . . . , nₘ, n_{M-1},dₙ_{₁}_{, n}_{₂}_{, . . . ,}_{ₘ}_{,n}_{_{M−1}}|mε[1,M−1],n_{M}ε[1,N_{M}]}

Go to step 42.

Step 42:

Each of the elements of the two rightmost columns of the matrix of combinations is multiplied by the number of channels σ:

{q_{μ,ξ} [symbol] σ·q_{μ,ξ}|με[1,Ω],ξε[4,5]};

The construction of the computational structure is concluded. The results of this process are:
The cumulative value of the operational delay Δ;
The matrix of combinations [Q]_{Ω,5};
The tensor of indices [R]_{N}_{₁}_{,N}_{₂}_{, . . . ,N}_{ₘ}_{, . . . ,N}_{_{M−1}};
The tensor of delays [D]_{N}_{₁}_{,N}_{₂}_{, . . . ,N}_{ₘ}_{, . . . ,N}_{_{M−1}}.

The described above computational structure serves as the input for an algorithm of fast tensor-vector multiplication. The algorithm and the process of carrying out of such multiplication is described below as following.

The initialization step consists of allocating memory within the computational system for the storage of copies of all components with the corresponding time delays. The iterative section is contained within the waiting loop or is activated by an interrupt caused by the arrival of a new element of the input tensor. It results in the movement through the memory of the components that have already been calculated, the performance of operations represented by the rows of the matrix of combinations [Q]_{Ω,5} and the computation of the result. The following is a more detailed discussion of one of the many possible examples of such a process.

For a given initial vector of length N_{M}, number σ of channels, cumulative operational delay Δ, matrix [Q]_{Ω,5} of combinations, kernel vector [U]_{ω}_{_{1,1}}₋₁, tensor [R]_{N}_{₁}_{,N}_{₂}_{, . . . ,N}_{ₘ}_{, . . . ,N}_{_{M−1}} of indices and tensor [D]_{N}_{₁}_{,N}_{₂}_{, . . . ,N}_{ₘ}_{, . . . ,N}_{_{M−1}} of delays, the steps given below constitute a process for iterative multiplication.

Step 1 (Initialization):

A two-dimensional array is allocated and initialized, represented here by the matrix [Φ]_{ω}_{_{Ω,1}}_{,σ·(n}_{_{M}}_{+Δ)} of dimension ω_{Ω,1},σ(N_{M}+Δ):

[Φ]_{ω}_{_{Ω,1}}_{,σ·(n}_{_{M}}_{+Δ)}={φ_{μ,η} [symbol] 0|με[1,ωΩ,1],ηε[1,σ·(N_{M}+Δ)]};

The variable ξ, serving as the indicator of the current column of the matrix [Φ]_{ω}_{_{Ω,1}}_{,σ·(n}_{_{M}}_{+Δ)} is initialized:

ξ [symbol] σ·(Nₘ+Δ);

Go to step 2.

Step 2:

Obtain the value of the next element of the input vector and record it in variable χ.

The indicator ξ of the current column of the matrix [Φ]_{ω}_{_{Ω,1}}_{,σ·(n}_{_{M}}_{+Δ)} is cyclically shifted to the right:

ξ [symbol] 1+(ξ)mod(σ·(N_{M}+Δ));

The product of the variable χ by the elements of the kernel [U]_{ω}_{_{1,1}}₋₁ are obtained and recorded in the corresponding positions of the matrix [Φ]_{ω}_{_{Ω,1}}_{,σ·(n}_{_{M}}_{+Δ)}:

{φ_{μ,ξ} [symbol] χ·u_{μ}|με[1,ω_{1,1}−1]};

The variable μ, serving as an indicator of the current row of the matrix of combinations [Q]_{Ω,5} is initialized:

μ [symbol] 1;

Go to step 3.

Step 3:

Find the new value of combination μ and assign it to the element φ_{μ+ω}_{_{1,1}}_{-1,ξ} of the matrix [Φ]_{ω}_{_{Ω,1}}_{,σ·(n}_{_{M}}_{+Δ)}:

Φ_{μ+ω}_{_{1,1}}_{-1,ξ} [symbol] Σ_{τ=0}¹ Φ_{q}_{_{μ, 2+τ}}_{, 1+(ξ-1-q}_{_{μ, 4+τ)}}mod(σ·(N_{M}+Δ));

The variable μ is increased by 1:

μ [symbol] μ+1;

Go to step 4.

Step 4:

If ≦Ω, go to step 3. Otherwise, go to step 5.

Step 5:

The elements of the tensor [P]_{N}_{₁}_{,N}_{₂}_{, . . . ,N}_{ₘ}_{, . . . ,N}_{_{M−1}}, containing the result, are determined:

[P]_{N}_{₁}_{,N}_{₂}_{, . . . ,N}_{ₘ}_{, . . . ,N}_{_{M−1}}={ρn₁,n₂, . . . ,nₘn_{M-1} [symbol] Φrₙ_{₁}_{,n}_{₂}_{, . . . , n}_{ₘ}_{,n}_{_{M−1}},1+(ξ−1−dₙ_{₁}_{,n}_{₂}, . . . ,ₙ_{ₘ}_{, n}_{_{M−1}}) mod(σ·(N_{M}+Δ))|mε[1,M−1],n_{M}ε[1,N_{M}]}

If all elements of the input vector have been processed, the process is concluded and the tensor [P]_{N}_{₁}_{,N}_{₂}_{, . . . ,N}_{ₘ}_{, . . . ,N}_{_{M−1}} is the product of the multiplication. Otherwise, go to step 2.

When a digital or an analog hardware platform must be used for performing the operation of tensor-vector multiplication, a schematic of such system can be synthesized with the usage of the same computation control structure as the one used for guiding the process above. The synthesis of such schematic represented in a form of a component set with their interconnections is described below.

There are a total of three basic elements used for synthesis. For a synchronous digital system these elements are: a time delay element of one system count, a two-input summator with an operational delay of δ system counts, and a scalar multiplication operator. For an asynchronous analog system or an impulse system, these are a delay time between successive elements of the input vector, a two-input summator with a time delay of δ element counts, and a scalar multiplication component in the form of an amplifier or attenuator.

Thus, for an input vector of length Nₘ, number of channels σ, matrix [Q]_{Ω,5} of combinations, kernel vector [U]_{ω}_{_{1,1}}₋₁, tensor [R]_{N}_{₁}_{,N}_{₂}_{, . . . ,N}_{ₘ}_{, . . . ,N}_{_{M−1}} of indices and tensor [D]_{N}_{₁}_{,N}_{₂}_{, . . . ,N}_{ₘ}_{, . . . ,N}_{_{M−1}} of time delays, the steps shown below describe the process of formation of a schematics description for a system for the iterative multiplication of a vector by a tensor. For convenience in representing the process of synthesis, the following convention is introduced: any variable enclosed in triangular brackets, for example<ξ>, represents the alphanumeric value currently assigned to that variable. This value in turn may be part of a value identifying a node or component of the block diagram. Alphanumeric strings will be enclosed in double quotes.

Step 1:

The initially empty block diagram of the system is generated, and within it the node “N_{—}0” which is the input port for the elements of the input vector.

The variable ξ is initialized, serving as the indicator of the current element of the kernel [U]_{ω}_{_{1,1}}₋₁:

ξ [symbol] 1;

Go to step 2.

Step 2:

To the block diagram of the apparatus add the node “N_ [symbol] ξ [symbol] _{—}0” and the multiplier “M_ [symbol] ξ [symbol] _{—}0” the input of which is connected to the node “N_{—}0”, and the output to the node “N⁺ [symbol] ξ [symbol] _{—}0”.

The value of the indicator of the current element of the kernel [U]_{ω}_{_{1,1}}₋₁ is increased by 1:

ξ [symbol] ξ+1;

Go to step 3.

Step 3:

If ≧ω_{1,1}, go to step 2. Otherwise, go to step 4.

Step 4:

The variable μ is initialized, serving as an indicator of the current row of the matrix of combinations [Q]_{Ω,5}:

μ [symbol] 1;

Go to step 5.

Step 5:

To the block diagram of the system add the node “N_ [symbol] q_{μ,1} [symbol] _{—}0” and the summator “A_ [symbol] q_{μ,1} [symbol] ” the output of which is connected to the node “N_ [symbol] q_{μ,1} [symbol] _{—}0”.

The variable ξ is initialized, serving as an indicator of the number of the input of the summator “A_ [symbol] q_{μ,1} [symbol] ”:

ξ [symbol] 1;

Go to step 6.

Step 6:

The variable γ is initialized, storing the delay component index offset:

γ [symbol] 0;

Go to step 7.

Step 7:

If the node N_ [symbol] q_{μ,ξ+1} [symbol] _ [symbol] q_{μ,ξ+3}−γ [symbol] has already been initialized, skip to step 12. Otherwise, go to step 8.

Step 8:

To the block diagram of the system add the node N_ [symbol] q_{μ,ξ+1} [symbol] _ [symbol] q_{μ,ξ+3}−γ [symbol] and a unit delay Z_ [symbol] q_{μξ+1} [symbol] _ [symbol] q_{μ,ξ+3}−y [symbol] , the output of which is connected to the node N_ [symbol] q_{μ,ξ+1} [symbol] _ [symbol] q_{μ,ξ+3}−γ [symbol] .

If γ>0, go to step 10. Otherwise, go to step 9.

Step 9:

Input number of the summator “A_ [symbol] q_{μ,1} [symbol] ” is connected to the node N_ [symbol] q_{μ,ξ+1} [symbol] _ [symbol] q_{μ,ξ+3} [symbol] .

Go to step 11

Step 10:

The input of the element of one count delay Z_ [symbol] q_{μ,ξ+1} [symbol] _ [symbol] q_{μ,ξ+3}−γ [symbol] is connected to the node N_ [symbol] q_{μ,ξ+1} [symbol] _ [symbol] q_{μ,ξ+3}−γ+1 [symbol] .

Go to step 11.

Step 11:

The delay component index offset is increased by 1:

γ [symbol] γ+1;

If γ<2, go to step 7. Otherwise, go to step 12.

Step 12:

The indicator μ of the current row of the matrix of combinations [Q]_{Ω,5} is increased by 1:

μ [symbol] μ+1;

If ≦Ω, go to step 5. Otherwise, go to step 13.

Step 13:

From each element of the delay tensor [D]_{N}_{₁}_{,N}_{₂}_{, . . . ,N}_{ₘ}_{, . . . ,N}_{_{M−1}} subtract the value of the least element of that matrix:

[D]_{N}_{₁}_{,N}_{₂}_{, . . . ,N}_{ₘ}_{, . . . ,N}_{_{M−1}} [symbol] [D]_{N}_{₁}_{,N}_{₂}_{, . . . ,N}_{ₘ}_{, . . . ,N}_{_{M−1}}−min(dₙ_{₁}_{,n}_{₂}_{, . . . ,n}_{ₘ}_{, . . . ,n}_{_{M−1}}|mε[1,M−1],nₘε[1,Nₘ]);

The indices n₁, n₂, . . . , nₘ, . . . , n_{M-1} are set equal to 1:

n₁ [symbol] 1;n₂ [symbol] 1; . . . ;nₘ [symbol] 1; . . . ;n_{M} [symbol] 1;

Go to step 14.

Step 14:

To the block diagram of the system add the node N_ [symbol] n₁ [symbol] _ [symbol] n₂ [symbol] _{—} . . ._ [symbol] nₘ [symbol] _{—} ..._ [symbol] nₘ₋₁ [symbol] at the output of the element n₁, n₂, . . . , nₘ, . . . , n_{M-1} of the result of multiplying the tensor by the vector.

Go to step 15.

Step 15:

The variable γ is initialized, storing the delay component index offset:

γ [symbol] 0;

Go to step 16.

Step 16:

If the node N_ [symbol] rₙ_{₁}_{,n}_{₂}_{, . . . ,n}_{ₘ}_{, . . . ,n}_{_{M−1}} [symbol] [symbol] dₙ_{₁}_{,n}_{₂}_{, . . . ,n}_{ₘ}_{, . . . ,n}_{_{M−1}}−γ [symbol] has already bee initialized, skip to step 21. Otherwise, go to step 16.

Step 17:

To the block diagram of the system introduce the node N_ [symbol] ₙ_{₁}_{,n}_{₂}_{, . . . ,n}_{ₘ}_{, . . . ,n}_{_{M−1}} [symbol] _ [symbol] dₙ_{₁}_{,n}_{₂}_{, . . . ,n}_{ₘ}_{, . . . ,n}_{_{M−1}}−γ [symbol] and the unit delay Z_ [symbol] rₙ_{₁}_{,n}_{₂}_{, . . . ,n}_{ₘ}_{, . . . ,n}_{_{M−1}} [symbol] _ [symbol] dₙ_{₁}_{,n}_{₂}_{, . . . ,n}_{ₘ}_{, . . . ,n}_{_{M−1}}−γ [symbol] .

If γ>0, Go to step 18. Otherwise skip to step 19.

Step 18:

The output of the delay element Z_ [symbol] rₙ_{₁}_{,n}_{₂}_{, . . . ,n}_{ₘ}_{, . . . ,n}_{_{M−1}} [symbol] _ [symbol] dₙ_{₁}_{,n}_{₂}_{, . . . ,n}_{ₘ}_{, . . . ,n}_{_{M−1}}−γ [symbol] is connected to the node N_ [symbol] rₙ_{₁}_{,n}_{₂}_{, . . . ,n}_{ₘ}_{, . . . ,n}_{_{M−1}} [symbol] _ [symbol] dₙ_{₁}_{,n}_{₂}_{, . . . ,n}_{ₘ}_{, . . . ,n}_{_{M−1}}−γ+1 [symbol] .

Go to step 19.

Step 19:

The output of the delay element Z_ [symbol] rₙ_{₁}_{,n}_{₂}_{, . . . ,n}_{ₘ}_{, . . . ,n}_{_{M−1}} [symbol] _ [symbol] dₙ_{₁}_{,n}_{₂}_{, . . . ,n}_{ₘ}_{, . . . ,n}_{_{M−1}}−γ [symbol] is connected to the node N_ [symbol] ₙ_{₁}_{,n}_{₂}_{, . . . ,n}_{ₘ}_{, . . . ,n}_{_{M−1}} [symbol] _ [symbol] ₙ_{₁}_{,n}_{₂}_{, . . . ,n}_{ₘ}_{, . . . ,n}_{_{M−1}}−γ+1 [symbol] .

Go to step 20.

Step 20:

The delay component index offset is increased by 1:

γ [symbol] γ+1;

Go to step 16.

Step 21:

If γ>0, skip to step 23. Otherwise, go to step 22.

Step 22:

The node N_ [symbol] rₙ_{₁}_{,n}_{₂}_{, . . . ,n}_{ₘ}_{, . . . ,n}_{_{M−1}} [symbol] _ [symbol] dₙ_{₁}_{,n}_{₂}_{, . . . ,n}_{ₘ}_{, . . . ,n}_{_{M−1}}−γ [symbol] is connected to the node N_ [symbol] n₁ [symbol] _ [symbol] n₂ [symbol] _. . . _ [symbol] nₘ [symbol] _ . . . _ [symbol] n_{M-1} [symbol] .

Go to step 23.

Step 23:

The index m is set equal to M:

m [symbol] M;

Go to step 24.

Step 24:

The index nₘ is increased by 1:
nₘ [symbol] n_{M}+1;

If m<M and nₘ≦Nₘ then go to step 14. Otherwise, go to step 25.

Step 25:

The index nₘ is set equal to 1:

nₘ [symbol] 1;

The index m is decreased by 1:

m [symbol] m−1;

If m≧1, go to step 24. Otherwise, the process is concluded.

The described process of synthesis of the computation description structure along with the process and the synthesized schematic for carrying out a continuous multiplying of incoming vector by a tensor represented in a form of a product of the kernel and the commutator, enable usage of minimal number of addition operations which are carried out on the priority basis.

In the method of the present invention a plurality of consecutive cyclically shifted vectors can be used; and the multiplying can be performed by multiplying a first of the consecutive vectors and cyclic shift of the matrix for all subsequent shift positions. This step of the inventive method is described herein below.

The tensor

[T]_{N}_{₁}_{,N}_{₂}_{, . . . ,N}_{ₘ}_{, . . . ,N}_{_{M}}={tₙ_{₁}_{,n}_{₂}_{, . . . ,n}_{ₘ}_{, . . . ,n}_{_{M}}|nₘε[1,Nₘ]mε[1,M]}

containing

L≦Πₖ₌₁^{M}Nₖ

distinct nonzero elements is to be multiplied by the vector

$${[ V ]}_{{N}_{m}} = {[ {V}_{0} ]}_{{N}_{m}} = [ \begin{matrix}{v}_{1} \\ … \\ {v}_{n} \\ … \\ {v}_{{N}_{m}}\end{matrix} ]$$

and all its circularly-shifted variants:

$$\{ {[ {V}_{1} ]}_{{N}_{m}} , {[ {V}_{2} ]}_{{N}_{m}} , … , {[ {V}_{{N}_{m} - 1} ]}_{{N}_{m}} \} = \{ [ \begin{matrix}{v}_{2} \\ … \\ … \\ {v}_{{N}_{m}} \\ {v}_{1}\end{matrix} ] , [ \begin{matrix}{v}_{3} \\ … \\ … \\ {v}_{1} \\ {v}_{2}\end{matrix} ] , … , [ \begin{matrix}{v}_{{N}_{m}} \\ {v}_{1} \\ … \\ … \\ {v}_{{N}_{m} - 1}\end{matrix} ] \} .$$

The tensor [T]_{N}_{₁}_{,N}_{₂}_{, . . . ,N}_{ₘ}_{, . . . ,N}_{_{M}} is written as the product of the commutator

[Z]_{N}_{₁}_{,N}_{₂}_{, . . . ,N}_{ₘ}_{, . . . ,N}_{ₘ}_{,L}={zₙ_{₁}_{,n}_{₂}_{, . . . ,n}_{ₘ}_{, . . . ,n}_{_{M}}_{,l}|nₘε[1,Nₘ],mε[1,M],lε[1,L]}

and the kernel

$$\begin{matrix} {[ U ]}_{L} = [ \begin{matrix}{u}_{1} \\ … \\ {u}_{l} \\ … \\ {u}_{L}\end{matrix} ] \text{:} & \\ {[ T ]}_{{N}_{1} , {N}_{2} , … , {N}_{m} , … , {N}_{M}} = {[ Z ]}_{{N}_{1} , {N}_{2} , … , {N}_{m} , … , {N}_{M} , L} \cdot {[ U ]}_{L} = \{ {\sum }_{l = 1}^{l = L} {z}_{{n}_{1} , {n}_{2} , … , {n}_{m} , … , {n}_{M} , 1} \cdot {u}_{1} \vert {n}_{m} ∈ [ 1 , {N}_{m} ] , m ∈ [ 1 , M ] \} & \end{matrix}$$

First the product of the tensor [T]_{N}_{₁}_{,N}_{₂}_{, . . . ,N}_{ₘ}_{, . . . ,N}_{_{M}} and the vector [V]_{N}_{ₘ} is obtained. This product may be written as:

[R]_{N}_{₁}_{,N}_{₂}_{, . . . ,N}_{_{m−1}}_{,N}_{ₘ₊₁}_{, . . . ,N}_{_{M}}=[T]_{N}_{₁}_{, . . . ,N}_{₂}_{, . . . ,N}_{ₘ}_{, . . . ,N}_{_{M}}·[V]Nₘ=={Σₙ₌₁^{N}^{ₘ}Σₗ₌₁^{L}zₙ_{₁}_{,n}_{₂}_{, . . . ,n}_{_{m−1}}_{,n,n}_{ₘ₊₁}_{, . . . ,n}_{_{M}}_{,l}·p_{l,n}|nₖε[1,Nₖ],kε{[1,m−1],[m+1,M]}}

, where p_{l,n} are the elements of the matrix [P]_{L,N}_{ₘ} obtained from the multiplication of the kernel [U]_{L}, by the transposed vector [V]_{N}_{ₘ}:

$${[ P ]}_{L , {N}_{m}} = {[ U ]}_{L} \cdot {[ V ]}_{{N}_{m}}^{t} = [ \begin{matrix}{u}_{1} \\ … \\ {u}_{l} \\ … \\ {u}_{L}\end{matrix} ] \cdot [ \begin{matrix}{v}_{1} & … & {v}_{n} & … & {v}_{{N}_{m}}\end{matrix} ] = [ \begin{matrix}{v}_{1} \cdot {u}_{1} & … & {v}_{{N}_{m}} \cdot {u}_{1} \\ ⋮ & {v}_{n} \cdot {u}_{1} & ⋮ \\ {v}_{1} \cdot {u}_{L} & … & {v}_{{N}_{m} N} \cdot {u}_{L}\end{matrix} ] \qquad$$

To obtain the succeeding value, the product of the tensor [T]_{N}_{₁}_{,N}_{₂}_{, . . . ,N}_{ₘ}_{, . . . ,N}_{_{M}} and the first circularly-shifted variant of the vector [V]_{N}_{ₘ}, which is the vector

$${[ {V}_{1} ]}_{{N}_{m }} = [ \begin{matrix}{v}_{2} \\ … \\ … \\ {v}_{{N}_{m}} \\ {v}_{1 }\end{matrix} ] ,$$

the new matrix [P₁]_{L,N}_{ₘ} is obtained:

$${[ {P}_{1} ]}_{L , {N}_{m}} = {[ U ]}_{L} \cdot {[ {V}_{1} ]}_{{N}_{m}}^{t} = [ \begin{matrix}{u}_{1} \\ … \\ {u}_{l} \\ … \\ {u}_{L}\end{matrix} ] \cdot [ \begin{matrix}{v}_{2} & … & {v}_{n + 1} & … & {v}_{{N}_{m}} & {v}_{1}\end{matrix} ] = [ \begin{matrix}{v}_{2} \cdot {u}_{1} & … & {v}_{{N}_{m}} \cdot {u}_{1} & {v}_{1} \cdot {u}_{1} \\ ⋮ & ⋮ & ⋮ & ⋮ \\ {v}_{2} \cdot {u}_{L} & … & {v}_{{N}_{m}} \cdot {u}_{L} & {v}_{1} \cdot {u}_{L}\end{matrix} ]$$

Clearly, the matrix [P₁]_{L,N}_{ₘ} is equivalent to the matrix [P]_{L,N}_{ₘ} cyclically shifted one position to the left. Each element p1_{l,n} of the matrix [P₁]_{L,N}_{ₘ} is a copy of the element p_{l,1+(n-2)mod(N}_{ₘ}₎ of the matrix [P]_{L,N}_{ₘ}, the element p2_{l,n} of the matrix [Pₖ]_{L,N}_{ₘ},kε[0,Nₘ−1] is a copy of the element p_{l,1+(n-3)mod(N}_{ₘ}₎ of the matrix [P₁]_{L,N}_{ₘ} and also a copy of the element p_{l,1+(n-3)mod(N}_{ₘ}₎ of the matrix [P]_{L,N}_{ₘ}. The general rule of representing an element of any matrix [Pₖ]_{L,N}_{ₘ},kε[0,Nₘ−1] in terms of elements of the matrix [P]_{L,N}_{ₘ} may be written as:

pk_{l,1=(n-1+k)mod(N}_{ₘ}₎=p_{l,n}

pₖ_{_{l,n}}=p_{l,1+(n-1+k)mod(N}_{ₘ}₎

All elements p_{k,}_{_{l,n}} may be included in a tensor [P]_{N}_{ₘ}_{,L,N}_{ₘ} of rank 3, and thus the result of cyclical multiplication of a tensor by a vector may be written as:

$${[ R ]}_{{N}_{m} , {N}_{1} , {N}_{2} , … , {N}_{m - 1} , {N}_{m + 1} , … , {N}_{M}} = \{ {[ T ]}_{{N}_{1} , {N}_{2} , … , {N}_{M}} \cdot {[ {V}_{k} ]}_{{N}_{M}} \vert k ∈ [ 0 , {N}_{m} - 1 ] \} = {[ Z ]}_{{N}_{1} , {N}_{2} , … , {N}_{m} , … , {N}_{M} , L} \cdot {[ P ]}_{{N}_{m} , L , {N}_{m}} = \{ {\sum }_{n = 1}^{{N}_{m}} {\sum }_{l = 1}^{L} {z}_{{n}_{1} , {n}_{2} , … , {n}_{m - 1} , n , {n}_{m + 1} , … , {n}_{M} , 1} \cdot {p}_{{k}_{l , n}} \vert {n}_{i} ∈ [ 1 , {N}_{i} ] , i ∈ \{ [ 1 , m - 1 ] , [ m + 1 , M ] \} , k ∈ [ 0 , {N}_{m} - 1 ] \} = \{ {\sum }_{n = 1}^{{N}_{m}} {\sum }_{l = 1}^{L} {z}_{{n}_{1} , {n}_{2} , … , {n}_{m - 1} , n , {n}_{m + 1} , … , {n}_{M} , 1} \cdot {p}_{l , 1 + ( n - 1 + k ) mod ( {N}_{m} )} \vert {n}_{i} ∈ [ 1 , {N}_{i} ] , i ∈ \{ [ 1 , m - 1 ] , [ m + 1 , M ] \} , k ∈ [ 0 , {N}_{m} - 1 ] \}$$

The recursive multiplication of a tensor by a vector of length Nₘ may be carried out in two steps. First the tensor [P]_{N}_{ₘ}_{,L,N}_{ₘ} is obtained, consisting of all Nₘ cyclically shifted variants of the matrix containing the product of each element of the initial vector and each element of the kernel of the initial tensor [T]_{N}_{₁}_{,N}_{₂}_{, . . . ,N}_{ₘ}_{, . . . ,N}_{_{M}}. Then each element of the resulting tensor [R]_{N}_{ₘ}_{,N}_{₁}_{,N}_{₂}_{, . . . ,N}_{_{m−1}}_{,N}_{ₘ₊₁}_{, . . . ,N}_{_{M}} is obtained as the tensor contraction of the commutator with the tensor [P]_{N}_{ₘ}_{,L,N}_{ₘ} obtained in the first step. Thus all multiplication operations take place during the first step, and their maximal number is equal to the product of the length Nₘ of the original vector and the number L of distinct nonzero elements of the initial tensor [T]_{N}_{₁}_{,N}_{₂}_{, . . . ,N}_{ₘ}_{, . . . ,N}_{_{M}} not the product of the length Nₘ of the original vector and the total number of elements in the original tensor [T]_{N}_{₁}_{,N}_{₂}_{, . . . ,N}_{ₘ}_{, . . . ,N}_{_{M}} which is Πₖ₌₁^{M}Nₖ, as in the case of multiplication without factorization of the tensor. All addition operations take place during the second step, and their maximal number is

$$\frac{{N}_{m}}{{N}_{m}} \cdot \frac{{N}_{m} - 1}{{N}_{m}} \cdot {\prod }_{k = 1}^{M} {N}_{k} .$$

Thus the ratio of the number of operations with a method using the decomposition of the tensor into a kernel and a commutator to the number of operations required with a method that does not include such a decomposition is

$${Cm}_{+} \leq \frac{\frac{{N}_{m} - 1}{{N}_{m}} \cdot {\prod }_{k = 1}^{M} {N}_{k}}{\frac{{N}_{m} - 1}{{N}_{m}} \cdot {\prod }_{k = 1}^{M} {N}_{k}} = 1$$

for addition and

$${Cm}_{*} \leq \frac{{N}_{m} \cdot L}{{N}_{m} \cdot {\prod }_{k = 1}^{M} {N}_{k}} = \frac{L}{{\prod }_{k = 1}^{M} {N}_{k}}$$

for multiplication.

In the method of the present invention a plurality of consecutive linearly shifted vectors can also be used and the multiplying can be performed by multiplying a last appeared element of each of the consecutive vectors and linear shift of the matrix. This step of the inventive method is described herein below.

Here the objective is sequential and continuous, which is to say iterative multiplication of a known and constant tensor

[T]_{N}_{₁}_{,N}_{₂}_{, . . . ,N}_{ₘ}_{, . . . ,N}_{_{M}}={tₙ_{₁}_{,n}_{₂}_{, . . . ,n}_{ₘ}_{, . . . ,n}_{_{M}}|nₘε[1,Nₘ],mε[1,M]}

containing

L≦Πₖ₌₁^{M}Nₖ

distinct nonzero elements, by a series of vectors, each of which is obtained from the preceding vector by a linear shift of each of its elements one position upward. At each successive iteration the lowest position of the vector is filled by a new element, and the uppermost element is lost. At each iteration the tensor [T]_{N}_{₁}_{,N}_{₂}_{, . . . ,N}_{ₘ}_{, . . . ,N}_{_{M}} is multiplied by the vector

$${[ {V}_{1} ]}_{{N}_{m}} = [ \begin{matrix}{v}_{1} \\ … \\ {v}_{n} \\ … \\ {N}_{m}\end{matrix} ] ,$$

after obtaining the matrix [P₁]_{L,N}_{ₘ}, which is the product of the kernel [U]_{L} of tensor [T]_{N}_{₁}_{,N}_{₂}_{, . . . ,N}_{ₘ}_{, . . . ,N}_{_{M}} and the transposed vector [V₁]Nₘ:

$${[ {P}_{1} ]}_{L , {N}_{m}} = {[ U ]}_{L} \cdot {[ {V}_{1} ]}_{{N}_{m}}^{t} = [ \begin{matrix}{u}_{1} \\ … \\ {u}_{l} \\ … \\ {u}_{L}\end{matrix} ] \cdot [ \begin{matrix}{v}_{1} & … & {v}_{n} & … & {v}_{{N}_{m}}\end{matrix} ] = [ \begin{matrix}{v}_{1} \cdot {u}_{1} & … & {v}_{{N}_{m}} \cdot {u}_{1} \\ ⋮ & {v}_{n} \cdot {u}_{l} & ⋮ \\ {v}_{1} \cdot {u}_{L} & … & {v}_{{N}_{m}} \cdot {u}_{L}\end{matrix} ] == [ [ \begin{matrix}{u}_{1} \\ … \\ {u}_{l} \\ … \\ {u}_{L}\end{matrix} ] \cdot {v}_{1} [ \begin{matrix}{u}_{1} \\ … \\ {u}_{l} \\ … \\ {u}_{L}\end{matrix} ] \cdot {v}_{2} … [ \begin{matrix}{u}_{1} \\ … \\ {u}_{l} \\ … \\ {u}_{L}\end{matrix} ] \cdot {v}_{ n} … [ \begin{matrix}{u}_{1} \\ … \\ {u}_{l} \\ … \\ {u}_{L}\end{matrix} ] \cdot {v}_{{N}_{m} - 1} [ \begin{matrix}{u}_{1} \\ … \\ {u}_{l} \\ … \\ {u}_{L}\end{matrix} ] \cdot {v}_{{N}_{m}} ]$$

In its turn the tensor [T]_{N}_{₁}_{,N}_{₂}_{, . . . ,N}_{ₘ}_{, . . . ,N}_{_{M}} is represented as the product of the commutator [Z]_{N}_{₁}_{,N}_{₂}_{, . . . ,N}_{ₘ}_{, . . . ,N}_{_{M}}^{,L}={zₙ_{₁}_{,n}_{₂}_{, . . . ,n}_{ₘ}_{, . . . ,n}_{_{M}}_{,l}|nₘε[1,Nₘ],mε[1,Nₘ],mε[1,M],lε[1,L]} and the kernel

$${[ U ]}_{L} = [ \begin{matrix}{u}_{1} \\ … \\ {u}_{l} \\ … \\ {u}_{L}\end{matrix} ] {\text{:} \\ [ T ]}_{{N}_{1} , {N}_{2} , … , {N}_{m} , … , {N}_{M}} = {[ Z ]}_{{N}_{1} , {N}_{2} , … , {N}_{m} , … , {N}_{M} , L} \cdot {[ U ]}_{L} = \{ {\sum }_{l = 1}^{l = L} {z}_{{n}_{1} , {n}_{2} , … , {n}_{m} , … , {n}_{M} , l} \cdot {u}_{l} \text{\textbar} {n}_{m} ∈ [ 1 , {N}_{m} ] , m ∈ [ 1 , M ] \}$$

Obviously, at the previous iteration the tensor [T]_{N}_{₁}_{,N}_{₂}_{, . . . ,N}_{ₘ}_{, . . . ,N}_{_{M}} was multiplied by the vector

$${[ {V}_{0} ]}_{{N}_{m}} = [ \begin{matrix}{v}_{0} \\ … \\ {v}_{n} \\ … \\ {v}_{{N}_{m} - 1}\end{matrix} ] ,$$

and therefore there exists a matrix [P₀]_{L,N}_{ₘ} which is obtained by the multiplication of the kernel [U]_{L} of the tensor [T]_{N}_{₁}_{,N}_{₂}_{, . . . ,N}_{ₘ}_{, . . . ,N}_{_{M}} by the transposed vector [V₀]Nₘ:

$${[ {P}_{0} ]}_{L , {N}_{m}} = {[ U ]}_{L} \cdot {[ {V}_{0} ]}_{{N}_{m}}^{t} = [ \begin{matrix}{u}_{1} \\ … \\ {u}_{l} \\ … \\ {u}_{L}\end{matrix} ] \cdot [ \begin{matrix}{v}_{0} & … & {v}_{n - 1} & … & {v}_{{N}_{m} - 1}\end{matrix} ] = [ \begin{matrix}{v}_{0} \cdot {u}_{1} & … & {v}_{{N}_{m} - 1} \cdot {u}_{1} \\ ⋮ & {v}_{n - 1} \cdot {u}_{l} & ⋮ \\ {v}_{0} \cdot {u}_{L} & … & {v}_{{N}_{m} - 1} \cdot {u}_{L}\end{matrix} ] = [ [ \begin{matrix}{u}_{1} \\ … \\ {u}_{l} \\ … \\ {u}_{L}\end{matrix} ] \cdot {v}_{0} [ \begin{matrix}{u}_{1} \\ … \\ {u}_{l} \\ … \\ {u}_{L}\end{matrix} ] \cdot {v}_{1} … [ \begin{matrix}{u}_{1} \\ … \\ {u}_{l} \\ … \\ {u}_{L}\end{matrix} ] \cdot {v}_{n - 1} … [ \begin{matrix}{u}_{1} \\ … \\ {u}_{l} \\ … \\ {u}_{L}\end{matrix} ] \cdot {v}_{{N}_{m} - 2} [ \begin{matrix}{u}_{1} \\ … \\ {u}_{l} \\ … \\ {u}_{L}\end{matrix} ] \cdot {v}_{{N}_{m} - 1} ]$$

The matrix [P₁]_{L,N}_{ₘ} is equivalent to the matrix [P₀]_{L,N}_{ₘ} linearly shifted to the left, where the rightmost column is the product of the kernel

$${[ U ]}_{L} = [ \begin{matrix}{u}_{1} \\ … \\ {u}_{l} \\ … \\ {u}_{L}\end{matrix} ]$$

and the new value v_{N}_{ₘ}.

Each element {p1_{l,n}|lε[1,L],nε[1,Nₘ−1]} of the matrix [P₁]_{L,N}_{ₘ} is a copy of the element {p_{l,n+1}|lε[1,L]nε[1, Nₘ−1]} of the matrix [P]_{L,N}_{ₘ} obtained in the previous iteration, and may be used in the current iteration, thereby obviating the need to use a multiplication operation to obtain them. Each element {p1_{l,N}_{ₘ}|lε[1,L]}—which is an element of the rightmost column of the matrix [P]_{L,N}_{ₘ} is formed from the multiplication of each element of the kernel and the new value of v_{N}_{ₘ} of the new input vector. A general rule for the formation of the elements of the matrix [Pᵢ]_{L,N}_{ₘ} from the elements of the matrix [Pᵢ₋₁]_{L,N}_{ₘ} may be written as:

$${p}_{{i}_{l , n}} = \{ \begin{matrix}{p}_{i - {1}_{l , n + 1}} , \vert n ∈ [ 1 , {N}_{m} - 1 ] \\ {u}_{l} \cdot {v}_{{N}_{m}} , \vert n = {N}_{m}\end{matrix} , l ∈ [ 1 , L ] , i ∈ [ 1 , ∞ [$$

Thus, iteration iε[1,∞[ is written as:

$$\{ \begin{matrix}{p}_{{i}_{l , n}} = \{ \begin{matrix}{p}_{i - {1}_{l , n + 1}} , \vert n ∈ [ 1 , {N}_{m} - 1 ] \\ {u}_{l} \cdot {v}_{{N}_{m}} , \vert n = {N}_{m}\end{matrix} , l ∈ [ 1 , L ] \\ {[ {R}_{i} ]}_{{N}_{1} , {N}_{2} , … , {N}_{m - 1} , {N}_{m + 1} , … , {N}_{M}} = \{ \begin{matrix}{\sum }_{n = 1}^{{N}_{m}} {\sum }_{l = 1}^{L} {z}_{{n}_{1} , {n}_{2} , … , {n}_{m - 1} , n , {n}_{m + 1} , … , {n}_{M} , l} \cdot \\ {p}_{{i}_{l , n}} \vert {n}_{k} ∈ [ 1 , {N}_{k} ] , k ∈ \{ [ 1 , m - 1 ] , [ m + 1 , M ] \}\end{matrix} \}\end{matrix} \}$$

Every such iteration consists of two steps—the first step contains all operations of multiplication and the formation of the matrix [Pᵢ]_{L,N}_{ₘ} and in the second step the result [R]_{N}_{₁}_{,N}_{₂}_{, . . . ,N}_{_{m−1}}_{, N}_{ₘ₊₁}_{, . . . ,N}_{_{M}} is obtained via tensor contraction of the commutator and the new matrix [Pᵢ]_{L,N}_{ₘ} Since the iterative formation of [Pᵢ]_{L,N} requires the multiplication of only the newest component v_{N}_{ₘ} of the vector [V]_{N}_{ₘ} by the kernel, the maximum number of operations in a single iteration is the number L of distinct nonzero elements of the original tensor [T]_{N}_{₁}_{,N}_{₂}_{, . . . ,N}_{ₘ}_{, . . . ,N}_{_{M}} rather than the total number of elements in the original tensor [T]_{N}_{₁}_{,N}_{₂}_{, . . . ,N}_{ₘ}_{, . . . ,N}_{_{M}}, which is Πₖ₌₁^{M}Nₖ. The maximum number of addition operations is

$$\frac{{N}_{m} - 1}{{N}_{m}} \cdot {\prod }_{k = 1}^{M} {N}_{k} .$$

Thus the ratio of the number of operations with a method using the decomposition of the vector into a kernel and a commutator to the number of operations required with a method that does not include such a decomposition is

$${Cm}_{+} \leq \frac{\frac{{N}_{m} - 1}{{N}_{m}} \cdot {\prod }_{k = 1}^{M} {N}_{k}}{\frac{{N}_{m} - 1}{{N}_{m}} \cdot {\prod }_{k = 1}^{M} {N}_{k}} = 1$$

for addition and

$${Cm}_{*} \leq \frac{L}{{\prod }_{k = 1}^{M} {N}_{k}}$$

for multiplication.

The inventive method further comprises using as the original tensor a tensor which is a matrix. The examples of such usage are shown below.

Factorization of the original tensor which is a matrix is carried out as follows.

The original tensor which is a matrix

$${[ T ]}_{M , N} = [ \begin{matrix}{t}_{1 , 1} & … & {t}_{1 , N} \\ ⋮ & {t}_{m , n} & ⋮ \\ {t}_{M , 1} & … & {t}_{M , N}\end{matrix} ]$$

has dimensions M×N and contains L≦M·N distinct nonzero elements. Here, the kernel is a vector

$${[ U ]}_{L} = [ \begin{matrix}{u}_{1} \\ … \\ {u}_{l} \\ … \\ {u}_{L}\end{matrix} ]$$

consisting of all the unique nonzero elements of the matrix [T]_{M,N}.

This same matrix [T]_{M,N} is used to form a new intermediate matrix

$${[ Y ]}_{M , N} = [ \begin{matrix}{y}_{1 , 1} & … & {y}_{1 , N} \\ ⋮ & {y}_{m , n} & ⋮ \\ {y}_{M , 1} & … & {y}_{M , N}\end{matrix} ]$$

of the same dimensions M×N as the matrix [T]_{M,N} each of whose elements is either equal to zero or equal to the index of the element of the vector [U]_{L}, which is equal in value to this element of the matrix [T]_{M,N}. The matrix [Y]_{M,N} can be obtained by replacing each nonzero element t_{m,n} of the matrix [T]_{M,N} by the index l of the equivalent element uₗ in the vector [U]_{L}.

From the resulting intermediate matrix [Y]_{M,N} the commutator

[Z]_{M,N,L}={Z_{m,n,l}|mε[1,M],nε[1,N],lε[1,L]}

a tensor of rank 3, is obtained by replacing each nonzero element y_{m,n} of the matrix [Y]_{M,N} by the vector of length L with all elements equal to 0 if y_{m,n}=0, or with a single unit element in the position corresponding to the nonzero value of y_{m,n} and L−1 zero elements in all other positions.

The resulting commutator can be expressed as:

$${[ Z ]}_{M , N , L} = \{ \{ \begin{matrix}{[ 0 … 0 ]}_{L} , & for {y}_{m , n} = 0 \\ {[ 0 … 0 ]}_{{y}_{m , n} - 1} {1 [ 0 … 0 ]}_{L - {y}_{m , n}} , & for {y}_{m , n} > {0}^{\vert m ∈ [ 1 , M ] , n ∈ [ 1 , N ]}\end{matrix} \}$$

The factorization of the matrix [T]_{M,N} is equivalent to the convolution of the commutator [Z]_{M,N,L} with the kernel [U]_{L}:

[T]_{M,N}=[z]_{M,N,L}·[U]_{L}={Σₗ₌₁^{l=L}z_{m,n,l}·uₗ|mε[1,M],nε[1,N]}

An example of factorization of the original tensor which is a matrix is shown below.

The matrix

$${[ T ]}_{M , N} = [ \begin{matrix}{t}_{1 , 1} {t}_{1 , 2} {t}_{1 , 3} \\ {t}_{2 , 1} {t}_{2 , 2} {t}_{2 , 3} \\ {t}_{3 , 1} {t}_{3 , 2} {t}_{3 , 3} \\ {t}_{4 , 1} {t}_{4 , 2} {t}_{4 , 3}\end{matrix} ] = [ \begin{matrix}252 \\ 309 \\ 070 \\ 923\end{matrix} ]$$

of dimension M×N=4×3 contains L=5 distinct nonzero elements 2, 3, 5, 7, and 9 comprising the kernel

$${[ U ]}_{L} = [ \begin{matrix}{u}_{1} \\ {u}_{2} \\ {u}_{3} \\ {u}_{4} \\ {u}_{5}\end{matrix} ] = [ \begin{matrix}2 \\ 3 \\ 5 \\ 7 \\ 9\end{matrix} ] .$$

From the intermediate matrix

$${[ Y ]}_{M , N} = [ \begin{matrix}{y}_{1 , 1} {y}_{1 , 2} {y}_{1 , 3} \\ {y}_{2 , 1} {y}_{2 , 2} {y}_{2 , 3} \\ {y}_{3 , 1} {y}_{3 , 2} {y}_{3 , 3} \\ {y}_{4 , 1} {y}_{4 , 2} {y}_{4 , 3}\end{matrix} ] = [ \begin{matrix}131 \\ 205 \\ 040 \\ 512\end{matrix} ]$$

the following commutator, a tensor of rank 3, is obtained:

$$\begin{matrix}{[ Z ]}_{M , N , L} = \{ {Z}_{m , n , 1} \vert m ∈ [ 1 , 4 ] , n ∈ [ 1 , 3 ] , l ∈ [ 1 , 5 ] \} \\ = \{ {Z}_{1 , 2 , 1} … {Z}_{1 , 2 , 5 } … … {Z}_{1 , 3 , 5 } … … … {Z}_{4 , 3 , 5} \} \\ = [ \begin{matrix}[ {Z}_{1 , 1 , 1} … {Z}_{1 , 1 , 5} ] & [ {Z}_{1 , 2 , 1} … {Z}_{1 , 2 , 5} ] & [ {Z}_{1 , 3 , 1} … {Z}_{1 , 3 , 5} ] \\ [ {Z}_{2 , 1 , 1} … {Z}_{2 , 1 , 5} ] & [ {Z}_{2 , 2 , 1} … {Z}_{2 , 2 , 5} ] & [ {Z}_{2 , 3 , 1} … {Z}_{2 , 3 , 5} ] \\ [ {Z}_{3 , 1 , 1} … {Z}_{3 , 1 , 5} ] & [ {Z}_{3 , 2 , 1} … {Z}_{3 , 2 , 5} ] & [ {Z}_{3 , 3 , 1} … {Z}_{3 , 3 , 5} ] \\ [ {Z}_{4 , 1 , 1} … {Z}_{4 , 1 , 5} ] & [ {Z}_{4 , 2 , 1} … {Z}_{4 , 2 , 5} ] & [ {Z}_{4 , 3 , 1} … {Z}_{4 , 3 , 5} ]\end{matrix} ] \\ = [ \begin{matrix}[ 1 \; 0 \; 0 \; 0 \; 0 ] & [ 0 \; 0 \; 1 \; 0 \; 0 ] & [ 1 \; 0 \; 0 \; 0 \; 0 ] \\ [ 0 \; 1 \; 0 \; 0 \; 0 ] & [ 0 \; 0 \; 0 \; 0 \; 0 ] & [ 0 \; 0 \; 0 \; 0 \; 1 ] \\ [ 0 \; 0 \; 0 \; 0 \; 0 ] & [ 0 \; 0 \; 0 \; 1 \; 0 ] & [ 0 \; 0 \; 0 \; 0 \; 0 ] \\ [ 0 \; 0 \; 0 \; 0 \; 1 ] & [ 1 \; 0 \; 0 \; 0 \; 0 ] & [ 0 \; 1 \; 0 \; 0 \; 0 ]\end{matrix} ]\end{matrix}$$

The matrix [T]_{M,N} has the form of the convolution of the commutator[Z]_{M,N,L} with the kernel [U]_{L}:

$$\begin{matrix}{[ T ]}_{M , N} = [ \begin{matrix}{\sum }_{l = 1}^{l = 5} {z}_{1 , 1 , l} \cdot {u}_{l} & {\sum }_{l = 1}^{l = 5} {z}_{1 , 2 , l} \cdot {u}_{l} & {\sum }_{l = 1}^{l = 5} {z}_{1 , 3 , l} \cdot {u}_{l} \\ {\sum }_{l = 1}^{l = 5} {z}_{2 , 1 , l} \cdot {u}_{l} & {\sum }_{l = 1}^{l = 5} {z}_{2 , 2 , l} \cdot {u}_{l} & {\sum }_{l = 1}^{l = 5} {z}_{2 , 3 , l} \cdot {u}_{l} \\ {\sum }_{l = 1}^{l = 5} {z}_{3 , 1 , l} \cdot {u}_{l} & {\sum }_{l = 1}^{l = 5} {z}_{3 , 2 , l} \cdot {u}_{l} & {\sum }_{l = 1}^{l = 5} {z}_{3 , 3 , l} \cdot {u}_{l} \\ {\sum }_{l = 1}^{l = 5} {z}_{4 , 1 , l} \cdot {u}_{l} & {\sum }_{l = 1}^{l = 5} {z}_{4 , 2 , l} \cdot {u}_{l} & {\sum }_{l = 1}^{l = 5} {z}_{1 , 3 , l} \cdot {u}_{l}\end{matrix} ] \\ = [ \begin{matrix}[ 1 \; 0 \; 0 \; 0 \; 0 ] & [ 0 \; 0 \; 1 \; 0 \; 0 ] & [ 1 \; 0 \; 0 \; 0 \; 0 ] \\ [ 0 \; 1 \; 0 \; 0 \; 0 ] & [ 0 \; 0 \; 0 \; 0 \; 0 ] & [ 0 \; 0 \; 0 \; 0 \; 1 ] \\ [ 0 \; 0 \; 0 \; 0 \; 0 ] & [ 0 \; 0 \; 0 \; 1 \; 0 ] & [ 0 \; 0 \; 0 \; 0 \; 0 ] \\ [ 0 \; 0 \; 0 \; 0 \; 1 ] & [ 1 \; 0 \; 0 \; 0 \; 0 ] & [ 0 \; 1 \; 0 \; 0 \; 0 ]\end{matrix} ] \cdot [ \begin{matrix}{u}_{1} \\ {u}_{2} \\ {u}_{3} \\ {u}_{4} \\ {u}_{5}\end{matrix} ] \\ = [ \begin{matrix}[ 1 \; 0 \; 0 \; 0 \; 0 ] & [ 0 \; 0 \; 1 \; 0 \; 0 ] & [ 1 \; 0 \; 0 \; 0 \; 0 ] \\ [ 0 \; 1 \; 0 \; 0 \; 0 ] & [ 0 \; 0 \; 0 \; 0 \; 0 ] & [ 0 \; 0 \; 0 \; 0 \; 1 ] \\ [ 0 \; 0 \; 0 \; 0 \; 0 ] & [ 0 \; 0 \; 0 \; 1 \; 0 ] & [ 0 \; 0 \; 0 \; 0 \; 0 ] \\ [ 0 \; 0 \; 0 \; 0 \; 1 ] & [ 1 \; 0 \; 0 \; 0 \; 0 ] & [ 0 \; 1 \; 0 \; 0 \; 0 ]\end{matrix} ] \cdot [ \begin{matrix}2 \\ 3 \\ 5 \\ 7 \\ 9\end{matrix} ] \\ = [ \begin{matrix}252 \\ 309 \\ 070 \\ 923\end{matrix} ]\end{matrix}$$

A factorization of the original tensor which is a matrix whose rows constitute all possible permutations of a finite set of elements is carried out as follows.

For finitely many distinct nonzero elements

E={e₁,e₂, . . . ,eₖ},

the matrix [T]_{M,N}, of dimensions M×N and containing L≦M˜N distinct nonzero elements, whose rows constitute a complete set of the permutations of the elements of E of length M will contain N columns and M=k^{N} rows:

$${[ T ]}_{{k}^{N} , N} = [ \begin{matrix}{t}_{1 , 1} & … & {t}_{1 , N} \\ ⋮ & {t}_{m , n} & ⋮ \\ {t}_{M , 1} & … & {t}_{M , N}\end{matrix} ] = [ \begin{matrix}{e}_{1} {e}_{1} {e}_{1} … {e}_{1} \\ {e}_{2} {e}_{1} {e}_{1} … {e}_{1} \\ … \\ {e}_{k} {e}_{1} {e}_{1} … {e}_{1} \\ {e}_{1} {e}_{2} {e}_{1} … {e}_{1} \\ {e}_{2} {e}_{2} {e}_{1} … {e}_{1} \\ … \\ {e}_{k} {e}_{2} {e}_{1} … {e}_{1} \\ … \\ … \\ {e}_{1} {e}_{k} {e}_{k} … {e}_{k} \\ {e}_{2} {e}_{k} {e}_{k } … {e}_{k} \\ … \\ {e}_{k} {e}_{k} {e}_{k} … {e}_{k}\end{matrix} ] = \{ {e}_{1 + floor ( \frac{v + m - 1}{{k}^{( h + n - 1 ) mod N}} mod k )} \vert m ε [ 1 , {k}^{N} ] , n ε [ 1 , N ] \} = [ \begin{matrix}{e}_{1 + floor ( \frac{v}{{k}^{( n ) mod N}} mod k )} & … & {e}_{1 + floor ( \frac{v}{{k}^{( h + n - 1 ) mod N}} mod k )} \\ ⋮ & {e}_{1 + floor ( \frac{v + m - 1}{{k}^{( h + n - 1 ) mod N}} mod k )} & ⋮ \\ {e}_{1 + floor ( \frac{v + {k}^{ N} - 1}{{k}^{( h ) mod N}} mod k )} & … & {e}_{1 + floor ( \frac{v + {k}^{N} - 1}{{k}^{( h + N - 1 ) mod N}} mod k )}\end{matrix} ]$$

From this matrix the kernel is obtained as the vector

$${[ U ]}_{L} = [ \begin{matrix}{u}_{1} \\ … \\ {u}_{l} \\ … \\ {u}_{L}\end{matrix} ]$$

consisting of all the distinct nonzero elements of the matrix [T]_{M,N}.

From the same matrix [T]_{M,N} the intermediate matrix

$${[ Y ]}_{M , N} = [ \begin{matrix}{y}_{1 , 1} & … & {y}_{1 , N} \\ ⋮ & {y}_{m , n} & ⋮ \\ {y}_{M , 1} & … & {y}_{M , N}\end{matrix} ]$$

is obtained, with the same dimensions M×N as the matrix [T]_{M,N} and with each element equal either to zero or to the index of that element of the vector [U]_{L} which is equal in value to this element of the matrix [T]_{M,N}. The matrix [Y]_{M,N} may be obtained by replacing each nonzero element t_{m,n} of the matrix [T]_{M,N} by the index 1 of the equivalent element uₗ of the vector [U]_{L}.

From the resulting intermediate matrix [Y]_{M,N} the commutator,

[Z]_{M,N,L}={Z_{m,n,l}|mε[1,M],nε[1,N],lε[1,L]}

a tensor of rank 3, is obtained by replacing each nonzero element y_{m,n} of the matrix [Y]_{M,N} by the vector of length L, with all elements equal to 0 if y_{m,n}=0, or with a single unit element in the position corresponding to the nonzero value of y_{m,n} and L−1 elements equal to 0 in all other positions.

The resulting commutator may be written as:

$${[ Z ]}_{M , N , L} = \{ \{ \begin{matrix}{[ 0 … 0 ]}_{L} , & for {y}_{m , n} = 0 \\ {[ 0 … 0 ]}_{{y}_{m , n} - 1} {1 [ 0 … 0 ]}_{L - {y}_{m , n}} , & for {y}_{m , n} > {0}^{\vert m ∈ [ 1 , M ] , n ∈ [ 1 , N ]}\end{matrix} \}$$

The factorization of the matrix [T]_{M,N} is of the form of the convolution of the commutator [Z]_{M,N,L} with the kernel [U]_{L}:

[T]_{M,N}=[Z]_{M,N,L}[U]_{L}={Σₗ₌₁^{l=L}z_{m,n,l}·uₗ|mε[1,M],nε[1,N]}

An example of factorization of the original tensor which is a matrix whose rows constitute all possible permutations of a finite set of elements is shown below.

The matrix

$${[ T ]}_{M , N} = [ \begin{matrix}{t}_{1 , 1} {t}_{1 , 2} {t}_{1 , 3} \\ {t}_{2 , 1} {t}_{2 , 2} {t}_{2 , 3} \\ {t}_{3 , 1} {t}_{3 , 2} {t}_{3 , 3} \\ {t}_{4 , 1} {t}_{4 , 2} {t}_{4 , 3}\end{matrix} ] = [ \begin{matrix}2 \; 5 \; 2 \\ 3 \; 0 \; 9 \\ 0 \; 7 \; 0 \\ 9 \; 2 \; 3\end{matrix} ]$$

of dimensions M×N=4×3 contains L=5 distinct nonzero elements 2, 3, 5, 7, and 9 constituting the kernel

$${[ U ]}_{L} = [ \begin{matrix}{u}_{1} \\ {u}_{2} \\ {u}_{3} \\ {u}_{4} \\ {u}_{5}\end{matrix} ] = [ \begin{matrix}2 \\ 3 \\ 5 \\ 7 \\ 9\end{matrix} ] .$$

From the intermediate matrix

$${[ Y ]}_{M , N} = [ \begin{matrix}{y}_{1 , 1} & {y}_{1 , 2} & {y}_{1 , 3} \\ {y}_{2 , 1} & {y}_{2 , 2} & {y}_{2 , 3} \\ {y}_{3 , 1} & {y}_{3 , 2} & {y}_{3 , 3} \\ {y}_{4 , 1} & {y}_{4 , 2} & {y}_{4 , 3}\end{matrix} ] = [ \begin{matrix}1 & 3 & 1 \\ 2 & 0 & 5 \\ 0 & 4 & 0 \\ 5 & 1 & 2\end{matrix} ]$$

the following commutator, a tensor of rank 3, is obtained:

$${[ Z ]}_{M , N , L} = \{ {Z}_{m , n , l} \vert m ∈ [ 1 , 4 ] , n ∈ [ 1 , 3 ] , l ∈ [ 1 , 5 ] \} = \{ {Z}_{1 , 2 , 1} … {Z}_{1 , 2 , 5} … … {Z}_{1 , 3 , 5} … … … {Z}_{4 , 3 , 5} \} = [ \begin{matrix}[ {Z}_{1 , 1 , 1} … {Z}_{1 , 1 , 5} ] & [ {Z}_{1 , 2 , 1} … {Z}_{1 , 2 , 5} ] & [ {Z}_{1 , 3 , 1} … {Z}_{1 , 3 , 5} ] \\ [ {Z}_{2 , 1 , 1} … {Z}_{2 , 1 , 5} ] & [ {Z}_{2 , 2 , 1} … {Z}_{2 , 2 , 5} ] & [ {Z}_{2 , 3 , 1} … {Z}_{2 , 3 , 5} ] \\ [ {Z}_{3 , 1 , 1} … {Z}_{3 , 1 , 5} ] & [ {Z}_{3 , 2 , 1} … {Z}_{3 , 2 , 5} ] & [ {Z}_{3 , 3 , 1} … {Z}_{3 , 3 , 5} ] \\ [ {Z}_{4 , 1 , 1} … {Z}_{4 , 1 , 5} ] & [ {Z}_{4 , 2 , 1} … {Z}_{4 , 2 , 5} ] & [ {Z}_{4 , 3 , 1} … {Z}_{4 , 3 , 5} ]\end{matrix} ] = [ \begin{matrix}[ 10000 ] & [ 00100 ] & [ 10000 ] \\ [ 01000 ] & [ 00000 ] & [ 00001 ] \\ [ 00000 ] & [ 00010 ] & [ 00000 ] \\ [ 00001 ] & [ 10000 ] & [ 01000 ]\end{matrix} ]$$

The matrix [T]_{M,N} is equal to the convolution of the commutator [Z]_{M,N,L} and the kernel [U]_{L}:

$${[ T ]}_{M , N} = [ \begin{matrix}{\sum }_{l = 1}^{l = 5} {z}_{1 , 1 , l} \cdot {u}_{l} & {\sum }_{l = 1}^{l = 5} {z}_{1 , 2 , l} \cdot {u}_{l} & {\sum }_{l = 1}^{l = 5} {z}_{1 , 3 , l} \cdot {u}_{l} \\ {\sum }_{l = 1}^{l = 5} {z}_{2 , 1 , l} \cdot {u}_{l} & {\sum }_{l = 1}^{l = 5} {z}_{2 , 2 , l} \cdot {u}_{l} & {\sum }_{l = 5}^{l = 5} {z}_{2 , 3 , l} \cdot {u}_{l} \\ {\sum }_{l = 1}^{l = 5} {z}_{3 , 1 , l} \cdot {u}_{l} & {\sum }_{l = 1}^{l = 5} {z}_{3 , 2 , l} \cdot {u}_{l} & {\sum }_{l = 1}^{l = 5} {z}_{3 , 3 , l} \cdot {u}_{l} \\ {\sum }_{l = 1}^{l = 5} {z}_{4 , 1 , l} \cdot {u}_{l} & {\sum }_{l = 1}^{l = 5} {z}_{4 , 2 , l} \cdot {u}_{1} & {\sum }_{l = 1}^{l = 5} {z}_{4 , 3 , l} \cdot {u}_{l}\end{matrix} ] = [ \begin{matrix}[ 10000 ] & [ 00100 ] & [ 10000 ] \\ [ 01000 ] & [ 00000 ] & [ 00001 ] \\ [ 00000 ] & [ 00010 ] & [ 00000 ] \\ [ 00001 ] & [ 10000 ] & [ 01000 ]\end{matrix} ] \cdot [ \begin{matrix}{u}_{1} \\ {u}_{2} \\ {u}_{3} \\ {u}_{4} \\ {u}_{5}\end{matrix} ] = [ \begin{matrix}[ 10000 ] & [ 00100 ] & [ 10000 ] \\ [ 01000 ] & [ 00000 ] & [ 00001 ] \\ [ 00000 ] & [ 00010 ] & [ 00000 ] \\ [ 00001 ] & [ 10000 ] & [ 01000 ]\end{matrix} ] \cdot [ \begin{matrix}2 \\ 3 \\ 5 \\ 7 \\ 9\end{matrix} ] = [ \begin{matrix}2 & 5 & 2 \\ 3 & 0 & 9 \\ 0 & 7 & 0 \\ 9 & 2 & 3\end{matrix} ]$$

The inventive method further comprises using as the original tensor a tensor which is a vector. The example of such usage is shown below.

A vector

$${[ T ]}_{N} = [ \begin{matrix}{t}_{1} \\ … \\ {t}_{n} \\ … \\ {t}_{N}\end{matrix} ]$$

has length N and contains L≦N distinct nonzero elements. From this vector the kernel consisting of the vector

$${[ U ]}_{L} = [ \begin{matrix}{u}_{1} \\ … \\ {u}_{l} \\ … \\ {u}_{L}\end{matrix} ]$$

is obtained by including the unique nonzero elements of [T]_{N} in the vector [U]_{L}, in arbitrary order.

From the same vector [T]_{N} the intermediate vector

$${[ Y ]}_{N} = [ \begin{matrix}{y}_{1} \\ … \\ {y}_{n} \\ … \\ {y}_{N}\end{matrix} ]$$

is formed, with the same dimension N as the vector [T]_{N} and with each element equal either to zero or to the index of the element of the vector [U]_{L} which is equal in value to this element of vector [T]_{N}. The vector [Y]_{N} can be obtained by replacing every nonzero element tₙ of the vector [T]_{N} by the index l of the element uₗ of the vector [U]_{L} that has the same value.

From the intermediate vector [Y]_{N} the commutator

$${[ Z ]}_{N , L} = [ \begin{matrix}{z}_{1 , 1} & … & {z}_{1 , L} \\ ⋮ & {z}_{n , 1} & ⋮ \\ {z}_{N - 1} & … & {z}_{N , L}\end{matrix} ]$$

is obtained by replacing every nonzero element yₙ of the vector [Y]_{N} with a row vector of length L, with a single unit element in the position with index equal to the value of yₙ and L−1 zero elements in all other positions. The resulting commutator is represented as:

$${[ Z ]}_{N , L} = [ \begin{matrix}\{ \begin{matrix}{[ 0 … 0 ]}_{L} , for {y}_{1} = 0 \\ {[ 0 … 0 ]}_{{y}_{1} - 1} {1 [ 0 … 0 ]}_{L - {y}_{1}} , for {y}_{1} > 0\end{matrix} \\ … \\ \{ \begin{matrix}{[ 0 … 0 ]}_{L} , for {y}_{n} = 0 \\ {[ 0 … 0 ]}_{{y}_{n} - 1} {1 [ 0 … 0 ]}_{L - {y}_{n}} , for {y}_{n} > 0\end{matrix} \\ … \\ \{ \begin{matrix}{[ 0 … 0 ]}_{L} , for {y}_{N} = 0 \\ {[ 0 … 0 ]}_{{y}_{N} - 1} {1 [ 0 … 0 ]}_{L - {y}_{N}} , for {y}_{N} > 0\end{matrix}\end{matrix} ]$$

The vector [T]_{N} is factored as the product of the multiplication of the commutator [Z]_{N,L} by the kernel [U]_{L}:

$${[ T ]}_{N} = {[ Z ]}_{N , L} \cdot {[ U ]}_{L} = [ \begin{matrix}{z}_{1 , 1} & … & {z}_{1 , L} \\ ⋮ & {z}_{n , l} & ⋮ \\ {z}_{N , 1} & … & {z}_{N , L}\end{matrix} ] \cdot [ \begin{matrix}{u}_{1} \\ … \\ {u}_{1} \\ … \\ {u}_{L}\end{matrix} ]$$

An example of factorization of the original tensor which is a vector is shown below.

The vector

$${[ T ]}_{N} = [ \begin{matrix}{t}_{1} \\ {t}_{2} \\ {t}_{3} \\ {t}_{4} \\ {t}_{5} \\ {t}_{6} \\ {t}_{7}\end{matrix} ] = [ \begin{matrix}0 \\ 1 \\ 5 \\ 7 \\ 5 \\ 0 \\ 1\end{matrix} ]$$

of length N=7 contains L=3 distinct nonzero elements, 1, 5, and 7, which yield the kernel

$${[ U ]}_{L} = [ \begin{matrix}{u}_{1} \\ {u}_{2} \\ {u}_{3}\end{matrix} ] = [ \begin{matrix}5 \\ 1 \\ 7\end{matrix} ] .$$

From the intermediate vector

$${[ Y ]}_{N} = [ \begin{matrix}{y}_{1} \\ {y}_{2} \\ {y}_{3} \\ {y}_{4} \\ {y}_{5} \\ {y}_{6} \\ {y}_{7}\end{matrix} ] = [ \begin{matrix}0 \\ 2 \\ 1 \\ 3 \\ 1 \\ 0 \\ 2\end{matrix} ]$$

the commutator

$${[ Z ]}_{N , L} = [ \begin{matrix}0 & 0 & 0 \\ 0 & 1 & 0 \\ 1 & 0 & 0 \\ 0 & 0 & 1 \\ 1 & 0 & 0 \\ 1 & 0 & 0 \\ 0 & 0 & 0 \\ 0 & 1 & 0\end{matrix} ]$$

is obtained.

The factorization of the vector [T]_{N} is the same as the product of the multiplication of the commutator [Z]_{N,L} by the kernel [U]_{L}:

$${[ T ]}_{N} = {[ Z ]}_{N , L} \cdot {[ U ]}_{L} = [ \begin{matrix}0 & 0 & 0 \\ 0 & 1 & 0 \\ 1 & 0 & 0 \\ 0 & 0 & 1 \\ 1 & 0 & 0 \\ 0 & 0 & 0 \\ 0 & 1 & 0\end{matrix} ] \cdot [ \begin{matrix}{u}_{1} \\ {u}_{2} \\ {u}_{3}\end{matrix} ] = [ \begin{matrix}0 & 0 & 0 \\ 0 & 1 & 0 \\ 1 & 0 & 0 \\ 0 & 0 & 1 \\ 1 & 0 & 0 \\ 0 & 0 & 0 \\ 0 & 1 & 0\end{matrix} ] \cdot [ \begin{matrix}5 \\ 1 \\ 7\end{matrix} ] = [ \begin{matrix}0 \\ 1 \\ 5 \\ 7 \\ 5 \\ 0 \\ 1\end{matrix} ]$$

In the inventive method, the elements of the tensor and the vector can be single bit values, integer numbers, fixed point numbers, floating point numbers, non-numeric literals, real numbers, imaginary numbers, complex numbers represented by pairs having one real and one imaginary components, complex numbers represented by pairs having one magnitude and one angle components, quaternion numbers, and combinations thereof.

Also in the inventive method, operations with the tensor and the vector with elements being non-numeric literals can be string operations such as string concatenation operations, string replacement operations, and combinations thereof.

Finally, in the inventive method, operations with the tensor and the vector with elements being single bit values can be logical operations such as logic conjunction operations, logic disjunction operations, modulo two addition operations with their logical inversions, and combinations thereof.

The present invention also deals with a system for fast tensor-vector multiplication. The inventive system shown in FIG. 1 is identified with reference numeral 1. It has input for vectors, input for original tensor, input for precision value, input for operational delay value, input for number of channels, and output for resulting tensor. The input for vectors receives elements of input vectors for each channel. The input for original tensor receives current values of the elements of the original tensor. The input for precision value receives current values of rounding precision, the input for operational delay value receives current values of operational delay, the input for number of channels receives current values of number of channels representing number of vectors simultaneously multiplied by the original tensor. The output for the resulting tensor contains current values of elements of the resulting tensors of all channels.

### Configurable Filter Bank Implementation Examples

### Example 1

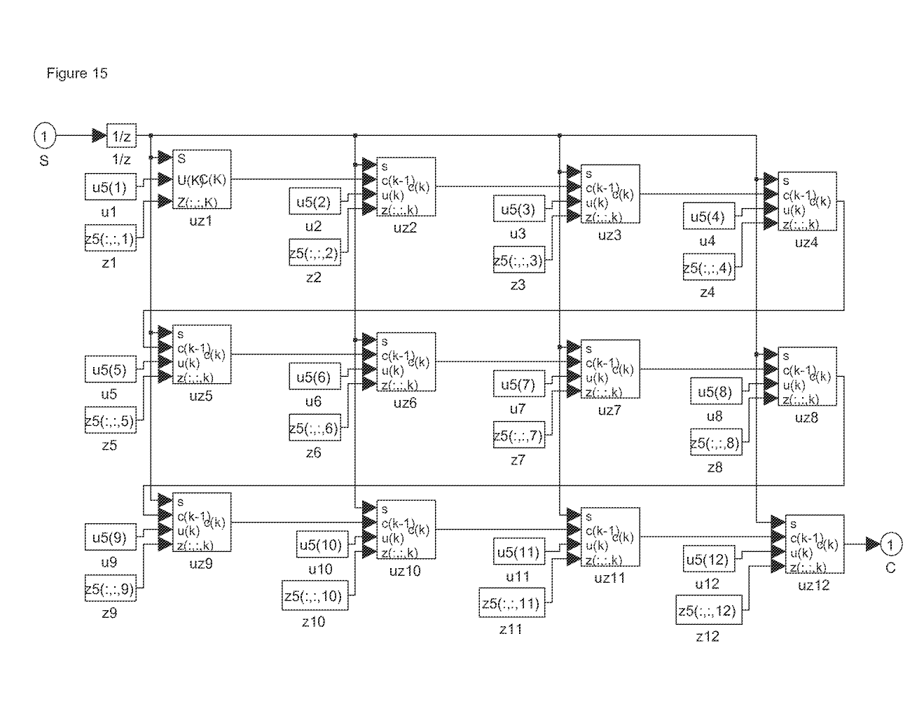

On FIG. 15 a filter bank in the form of a matrix—vector multiplier for 20×32 matrix and 1×20 vector. Uses 12 scalar product units instead of 20×32=640 multipliers required for conventional implementation.

Input signal samples are supplied to the input S of size 1. Output samples come from multichannel output c of size 32. Each channel of the output s is a corresponding element of the result of the matrix-vector multiplication or, in other words, the filtered signal samples of channel 1 to 32. values Blocks uz1 . . . uz12 perform matrix multiplication according to the kernel-multiplexer matrix decomposition.

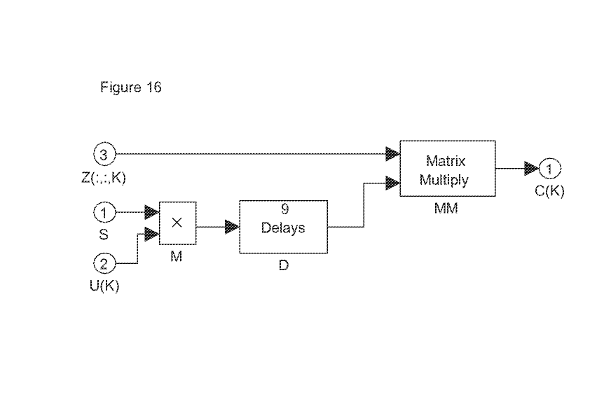

Blocks uz1 . . . uz12 internal structure is shown on FIG. 16 below.

All “mm” blocks (matrix multiply) do not use scalar products since they multiply by only zeros and ones and essentially are multiplexers controlled by corresponding elements of multiplexer tensor.

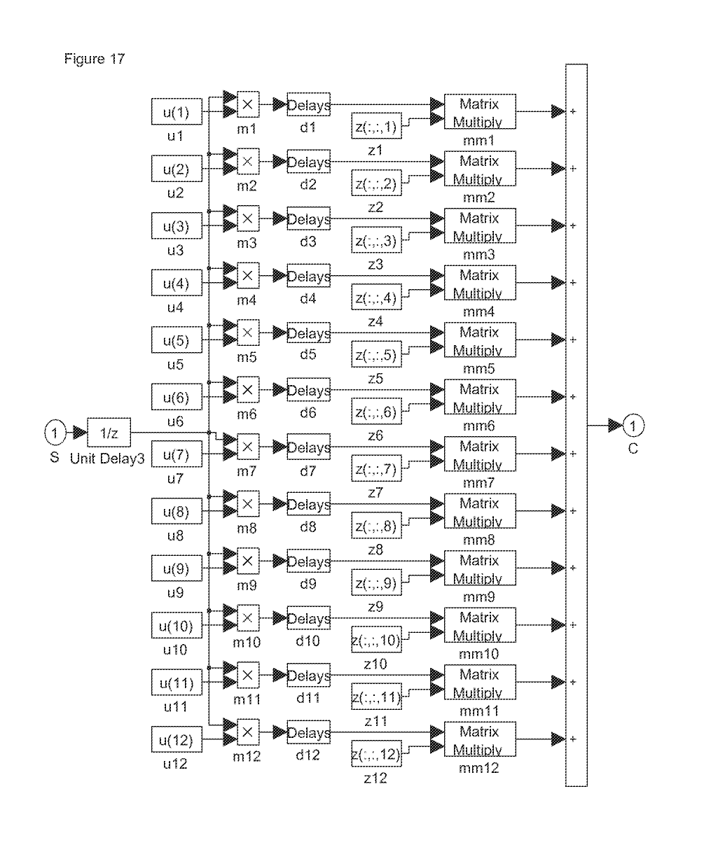

Each block uz1 . . . 12 takes one element of the kernel and a part of the multiplexer associated with the kernel element. Alternative implementation of the system is shown on FIG. 17.

### Example 2

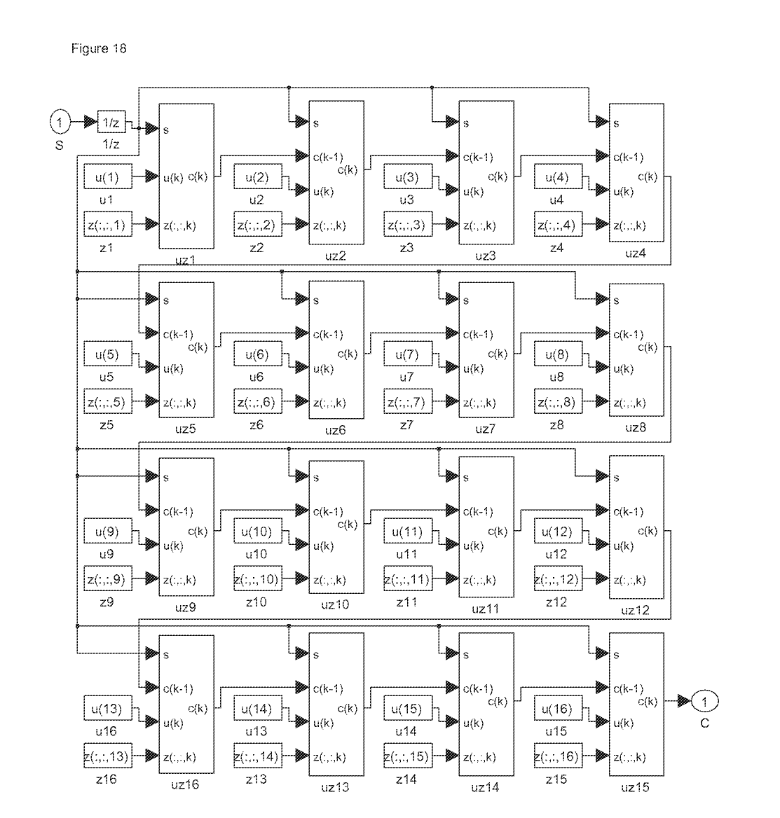

On FIG. 18 a filter bank in the form of a matrix—vector multiplier for 28×128 matrix and 1×28 vector. Uses 16 scalar product units instead of 28×128=3584 multipliers required for conventional implementation.

Input signal samples are supplied to the input S of size 1. Output samples come from multichannel output c of size 128. Each channel of the output s is a corresponding element of the result of the matrix-vector multiplication or, in other words, the filtered signal samples of channel 1 to 128. values Blocks uz1 . . . uz16 perform matrix multiplication according to the kernel-multiplexer matrix decomposition. Blocks uz1 . . . 16 internal structure is the same to the 20×32 matrix multiplier.

### Example 3

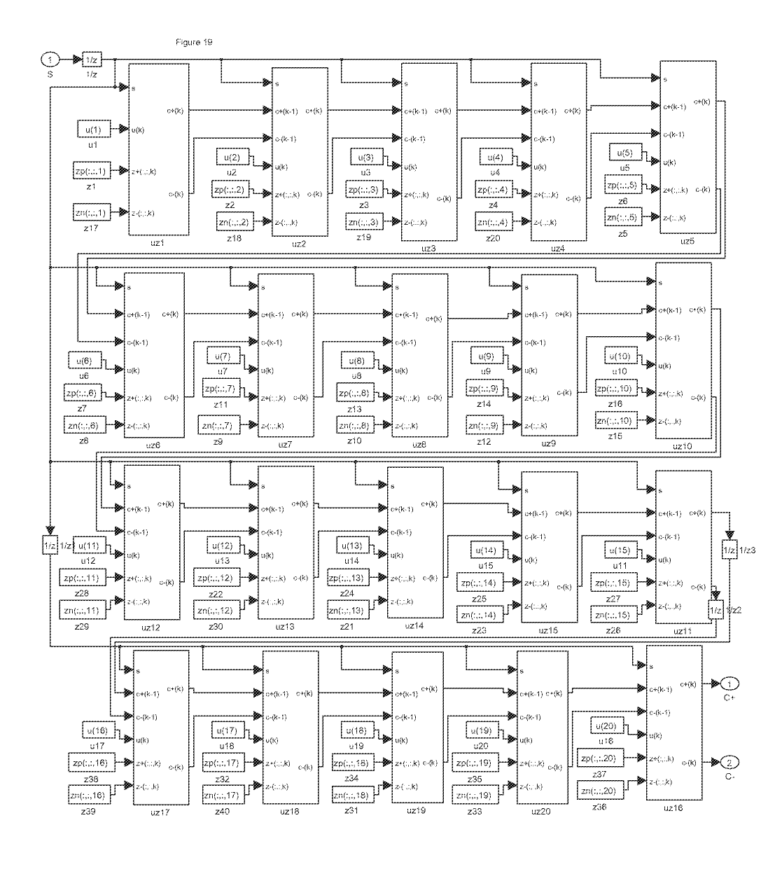

On FIG. 19 A filter bank in the form of a matrix—vector multiplier for 44×2048 matrix and 1×44 vector. Uses 20 scalar product units instead of 44×2048=90112 multipliers required for conventional implementation.

Input signal samples are supplied to the input S of size 1. Output samples come from multichannel outputs c+ and c− each of size 1024. Each channel of the output s is a corresponding element of the result of the matrix-vector multiplication or, in other words, the filtered signal samples of channel 1 to 2048. values Blocks uz1 . . . uz20 perform matrix multiplication according to the kernel-multiplexer matrix decomposition. Blocks uz1 . . . 20 internal structure is the same to the 20×32 and 28×128 matrix multiplier.

The present invention is not limited to the details shown since further modifications and structural changes are possible without departing from the main spirit of the present invention.

What is desired to be protected by Letters Patent is set forth in particular in the appended claims.

I claim:

1. A digital filter comprising a network of modules for implementing a filter transfer function as a fast tensor-vector multiplication, comprising the steps of factoring an original tensor into a kernel and a commutator; multiplying the kernel obtained by the factoring of the original tensor, by the vector and thereby obtaining a matrix; and summating elements and sums of elements of the matrix as defined by the commutator obtained by the factoring of the original tensor, and thereby obtaining a resulting tensor which corresponds to a product of the original tensor and the vector.

2. The digital filter according to claim 1, further comprising rounding elements of the original tensor to a desired precision and obtaining the original tensor with the rounded elements, wherein the factoring includes factoring the original tensor with the rounded elements into the kernel and the commutator.

3. The digital filter according to claim 1, wherein the factoring of the original tensor includes factoring into the kernel which contains kernel elements that are different from one another, and wherein the multiplying includes multiplying the kernel which contains the different kernel elements.

4. The digital filter according to claim 1, further comprising using as the commutator a commutator image in which indices of elements of the kernel are located at positions of corresponding elements of the original tensor.

5. The digital filter according to claim 4, wherein the summating includes summating on a priority basis of those pairs of elements whose indices in the commutator image are encountered most often and thereby producing the sums when the pair is encountered for the first time, and using the obtained sum for all remaining similar pairs of elements.

6. The digital filter according to claim 1, further comprising using a plurality of consecutive vectors shifted in a manner selected from the group consisting of cyclically and linearly; and, for the cyclic shift, carrying out the multiplying by a first of the consecutive vectors and cyclic shift of the matrix for all subsequent shift positions, while, for the linear shift, carrying out the multiplying by a last appeared element of each of the consecutive vectors and linear shift of the matrix.

7. The digital filter according to claim 1, further comprising using as the original tensor a tensor selected from the group consisting of a matrix and a vector.

8. The digital filter according to claim 1, wherein elements of the tensor and the vector are elements selected from the group consisting of single bit values, integer numbers, fixed point numbers, floating point numbers, non-numeric literals, real numbers, imaginary numbers, complex numbers represented by pairs having one real and one imaginary components, complex numbers represented by pairs having one magnitude and one angle components, quaternion numbers, and combinations thereof.

9. The digital filter according to claim 8, where operations with the tensor and the vector with elements being non-numeric literals are string operations selected from the group consisting of concatenation operations, string replacement operations, and combinations thereof.

10. The digital filter according to claim 8, where operations with the tensor and the vector with elements being single bit values are logical operations and their logical inversions selected from the group consisting of logic conjunction operations, logic disjunction operations, modulo two addition operations, and combinations thereof.

11. A system for digital filtering by use of fast tensor-vector multiplication, comprising means for factoring an original tensor into a kernel and a commutator; means for multiplying the kernel obtained by the factoring of the original tensor, by the vector and thereby obtaining a matrix; and means for summating elements and sums of elements of the matrix as defined by the commutator obtained by the factoring of the original tensor, and thereby obtaining a resulting tensor which corresponds to a product of the original tensor and the vector.

12. A system as defined in claim 11, wherein the means for factoring the original tensor into the kernel and the commutator comprise a precision converter converting tensor elements to desired precision and a factorizing unit building the kernel and the commutator; the means for multiplying the kernel by the vector comprise a multiplier set performing all component multiplication operations and a recirculator storing and moving results of the component multiplication operations; and the means for summating the elements and the sums of the elements of the matrix comprise a reducer which builds a pattern set and adjusts pattern delays and number of channels, a summator set which performs all summating operations, an indexer and a positioner which define indices and positions of the elements or the sums of elements utilized in composing the resulting tensor, the recirculator storing and moving results of the summation operations, and a result extractor forming the resulting tensor.

13. A method for digital filtering comprising factoring an original tensor into a kernel and a commutator; multiplying the kernel obtained by the factoring of the original tensor, by the vector and thereby obtaining a matrix; and summating elements and sums of elements of the matrix as defined by the commutator obtained by the factoring of the original tensor, and thereby obtaining a resulting tensor which corresponds to a product of the original tensor and the vector.

14. A method for correlation of signals in electronic system comprising factoring an original tensor into a kernel and a commutator; multiplying the kernel obtained by the factoring of the original tensor, by the vector and thereby obtaining a matrix; and summating elements and sums of elements of the matrix as defined by the commutator obtained by the factoring of the original tensor, and thereby obtaining a resulting tensor which corresponds to a product of the original tensor and the vector.

15. A method for forming control signals in automated control systems comprising factoring an original tensor into a kernel and a commutator multiplying the kernel obtained by the factoring of the original tensor, by the vector and thereby obtaining a matrix; and summating elements and sums of elements of the matrix as defined by the commutator obtained by the factoring of the original tensor, and thereby obtaining a resulting tensor which corresponds to a product of the original tensor and the vector.
